(19) United States
(12) Patent Application Publication
(10) Pub. No.: US 2025/0008760 A1
(43) Pub. Date: Jan. 2, 2025

(54) TETRADENTATE CYCLOMETALATED PLATINUM (II) COMPLEX, ELECTRONIC DEVICE AND APPLICATION THEREOF

(71) Applicants: ZHEJIANG UNIVERSITY OF TECHNOLOGY, Hangzhou (CN); ZHEJIANG HUAXIAN PHOTOELECTRICITY TECHNOLOGY CO., LTD., Jiaxing (CN)

(72) Inventors: Guijie LI, Hangzhou (CN); Qingshan CHU, Hangzhou (CN); Huanhuan YAO, Hangzhou (CN); Jieying TONG, Hangzhou (CN); Yuanbin SHE, Hangzhou (CN); Chunji GAO, Hangzhou (CN)

(21) Appl. No.: 18/590,225

(22) Filed: Feb. 28, 2024

(30) Foreign Application Priority Data
Jun. 26, 2023 (CN) 202310753447.5

(51) Int. Cl. H10K 50/12; H10K 85/30; H10K 85/40; H10K 85/60

(52) U.S. Cl. CPC H10K 50/12; H10K 85/346; H10K 85/40; H10K 85/633; H10K 85/636; H10K 85/6572; H10K 85/658

(57) ABSTRACT

The disclosure belongs to the field of organic electroluminescence, and particularly relates to a tetradentate cyclometalated platinum (II) complex, an electronic device and application thereof. In the disclosure, by introducing 2, 6-di (phenyl) tert-butylphenyl into a proper position of a ligand, a dihedral angle with a pyridine unit is increased and packing between molecules is reduced. Meanwhile, distribution of excited charges can be improved, so that the material has more metal-to-pyridine carbene charge transfer states, thus improving service life of devices. The material has chemical stability and thermal stability, and is easy to prepare vapor-deposited OLED devices. Combined with the fluorescent doping material, transmission of holes and electrons can be balanced and energy transfer between a donor material and an acceptor material can be more efficient. The organic light-emitting device made of the compound according to the disclosure has improved current efficiency and service life, and a reduced lighting voltage.

### CLAIM FOR PRIORITY

This application claims the benefit of priority of Chinese Application Serial No. 202310753447.5, filed Jun. 26, 2023, which is hereby incorporated by reference in its entirety.

### TECHNICAL FIELD

The disclosure belongs to the field of organic electroluminescence, and particularly relates to a tetradentate cyclometalated platinum (II) complex, an electronic device and application thereof.

### BACKGROUND ART

An Organic light-emitting diode (OLED) is a new generation of full-color display and lighting technologies. Compared with shortcomings of a liquid crystal display such as a slow response speed, a small viewing angle, need of backlight and high energy consumption, the OLED, as a self-luminous device, needs no backlight and saves energy. Meanwhile, it has a low driving voltage, a fast response speed, high resolution and contrast, a large viewing angle, and excellent low temperature performance; and an OLED device can be made thinner and in a flexible structure. In addition, it has advantages of low production cost, simple production processes and large-scale production. Therefore, the OLED presents a wide and huge application prospect in high-end electronic products and aerospace. With gradual increase of investment, further development of research and development, and upgrading of production equipment, the OLED has a very wide range of application scenarios and development prospects in the future.

A key of OLED development lies in design and development of luminescent materials. Almost all of light-emitting layers in currently applied OLED devices adopt a donor-acceptor light-emitting system mechanism, that is, a donor material is doped with an acceptor light-emitting material, and an energy gap of the donor material is generally greater than that of the acceptor light-emitting material, and energy is transferred from the donor material to the acceptor material, so that the acceptor material is excited to emit light. Commonly used organic phosphorescent acceptor materials are generally heavy metal atoms such as iridium (III), platinum (II), Pd(II), and so on. Commonly used organic phosphorescent materials mCBP (3,3-bis (9-carbazolyl)-biphenyl) and 2,6-MCPy (2,6-bis (9-carbazolyl)-Pyridine) have efficient and high triplet energy levels. When they are used as organic materials, triplet energy can be effectively transferred from luminescent organic materials to phosphorescent acceptor materials. However, due to characteristics of mCBP in which holes are easy to transport but electrons are difficult to flow, and holes cannot be well transported in 2,6-mCPy, charges in the light-emitting layer are unbalanced, which reduces current efficiency of a device. Meanwhile, currently applied heavy-metal phosphorescent organic complex molecules are cyclometalated iridium (III) complex molecules, with limited types. Content of metallic platinum in the earth's crust and its annual yield worldwide are about ten times that of metallic iridium, and cost of IrCl₃·H₂O for preparing iridium (III) complex phosphorescent materials is also much higher than that of PtCl₂ for preparing platinum (II) complex phosphorescent materials. In addition, the preparation of iridium (III) complex phosphorescent materials involves four-step reactions: iridium (III) dimer, iridium (III) intermediate ligand exchange, synthesis of mer-iridium (III) complex and mer-to-fac-iridium (III) complex isomer conversion, which greatly reduces a total yield, greatly reduces utilization of raw material IrCl₃·H₂O, and increase the preparation cost of the iridium (III) complex phosphorescent materials. In contrast, preparation of platinum (II) complex phosphorescent material only involves reaction of designing of ligand metallization of platinum salt in the last step above, with high utilization of platinum element, which can further reduce the preparation cost of the platinum (II) complex phosphorescent materials. To sum up, preparation cost of platinum (II) complex phosphorescent materials is much lower than that of iridium (III) complex phosphorescent materials. However, there are still some technical difficulties in development of platinum complex-based materials and devices, and it is an important research problem to improve efficiency and service life of devices. Therefore, it is urgent to develop new phosphorescent platinum (II) complexes.

### SUMMARY

In view of this, an object of the present disclosure is to provide a tetradentate cyclometalated platinum (II) complex, an electronic device and applications thereof. The tetradentate cyclometalated platinum (II) complex according to the disclosure can be used as a phosphorescent acceptor material of a light-emitting layer so as to cause a device to be with excellent performance. Furthermore, when it is combined with a specific donor material, current efficiency and service life of device of an electronic device, especially an organic electroluminescent device, can be improved, and an operating voltage of an element can be reduced.

A tetradentate cyclometalated platinum (II) complex is provided in this disclosure, which is selected from ones with any one of the following chemical structures, in which “D” represents deuterium and “Ph” represents a phenyl group:

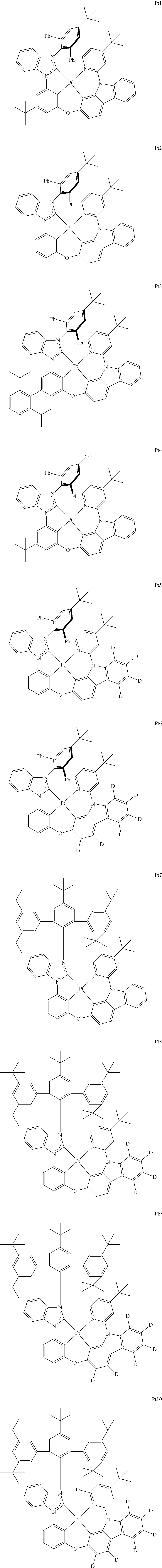

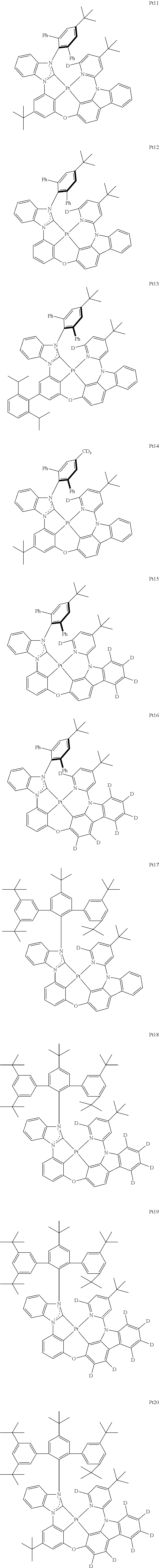

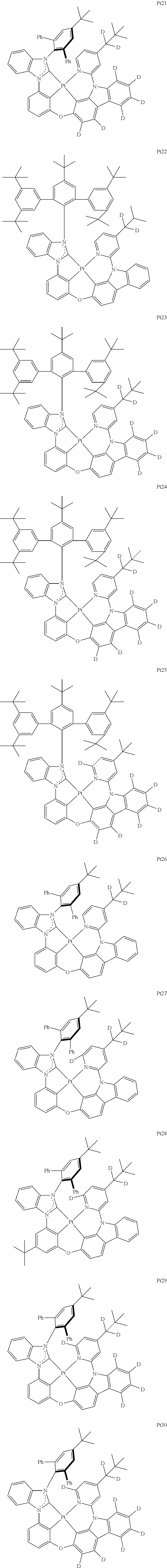

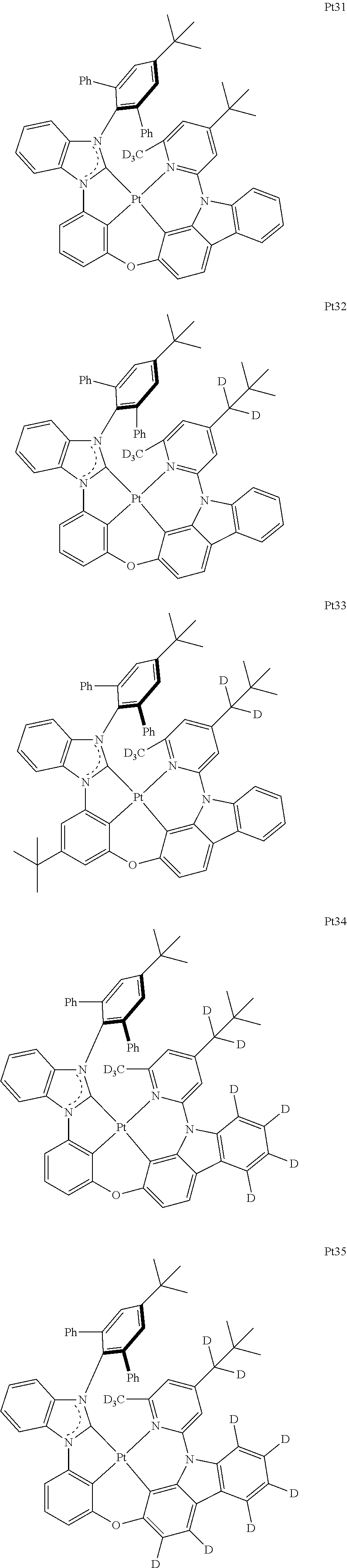

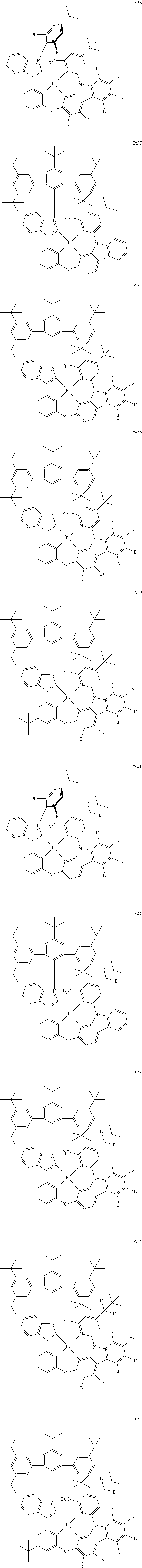

Further, application of the tetradentate cyclometalated platinum (II) complex with structures shown in Pt1 to Pt45 in an electronic device is further provided in this disclosure.

Further, the electronic device includes an organic light-emitting device (OLED), an organic integrated circuit (O-IC), an organic field effect transistor (O-FET), an organic thin film transistor (O-TFT), an organic light emitting transistor (O-LET), an organic solar cell (O-SC), an organic optical detector, an organic field quenching device (O-FQD), a light-emitting electrochemical cell (LEC) and an organic laser diode (O-laser).

In another aspect, an organic light-emitting device is further provided in this disclosure, which includes the tetradentate cyclometalated platinum (II) complex with a structure shown in Pt1 to Pt45.

Further, the organic light-emitting device includes a cathode, an anode and an organic functional layer therebetween. The organic functional layer includes the tetradentate cyclometalated platinum (II) complex with a structure shown in formula (I) or formula (II) as described above.

Preferably, the organic functional layer includes a light-emitting layer, and the light-emitting layer includes the tetradentate cyclometalated platinum (II) complex with a structure shown in formulas Pt1 to Pt45 described above.

Further, the light-emitting layer further includes a fluorescent doping material. The fluorescent doping material is selected from any one or more compound represented by formulas (BN1) to (BN5):

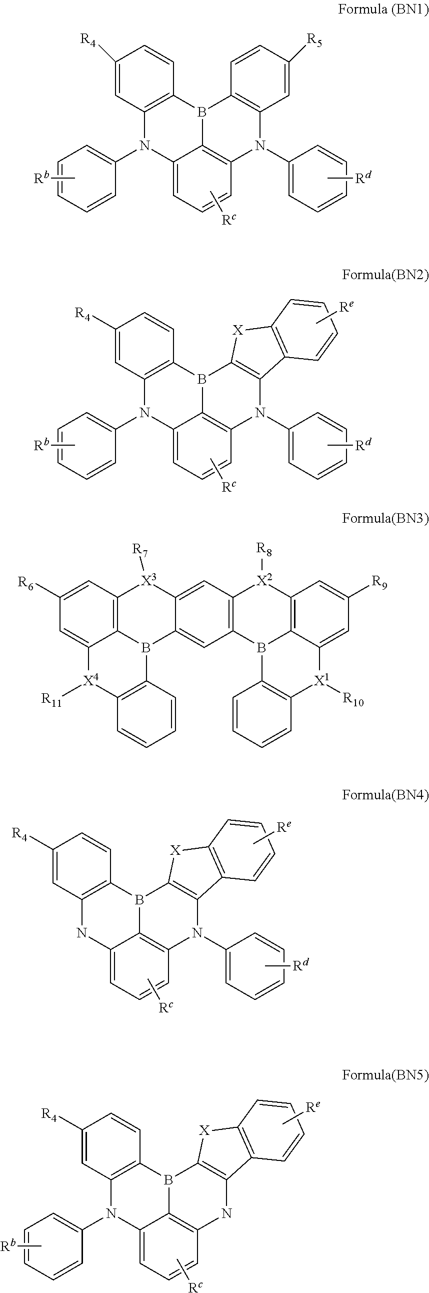

where X is O, S, Se or NR³⁰⁰;
X¹, X², X³, X⁴ reach independently represent O, S, Se or N.
R^{b} to R^{e} are each independently represented as monosubstituted, disubstituted, trisubstituted, tetrasubstituted or unsubstituted; R^{b} to R^{e} are independently selected from a group consisting of hydrogen, deuterium, N, C1-C30 alkyl and C6-C60 aryl; R₄ to R₁₁ are each independently selected from a group consisting of a group consisting of hydrogen, deuterium, n, C1-C30 alkyl and C6-C60 aryl.

Preferably, R₄, R₅, R₆ and R₉ are independently selected from substituted or unsubstituted diphenylamine groups, or substituted or unsubstituted carbazole groups; substitution can be multiple substitutions, and when a substituent is contained, the substituent is selected from deuterium, C1-C30 alkyl, and C6-C30 aryl.

Preferably, R₇ to R₈ and R₁₀ to R₁₁ are independently selected from a group consisting of hydrogen, C1-C30 alkyl and C6-C60 aryl.

Further preferably, at least one hydrogen in R₄ to R₁₁ can be substituted by deuterium.

Further, the fluorescent doping material is selected from any one of following chemical structures, in which Ph represents a phenyl group, and D4 and D5 respectively refers to be substituted by 4 and 5 deuterium atoms:

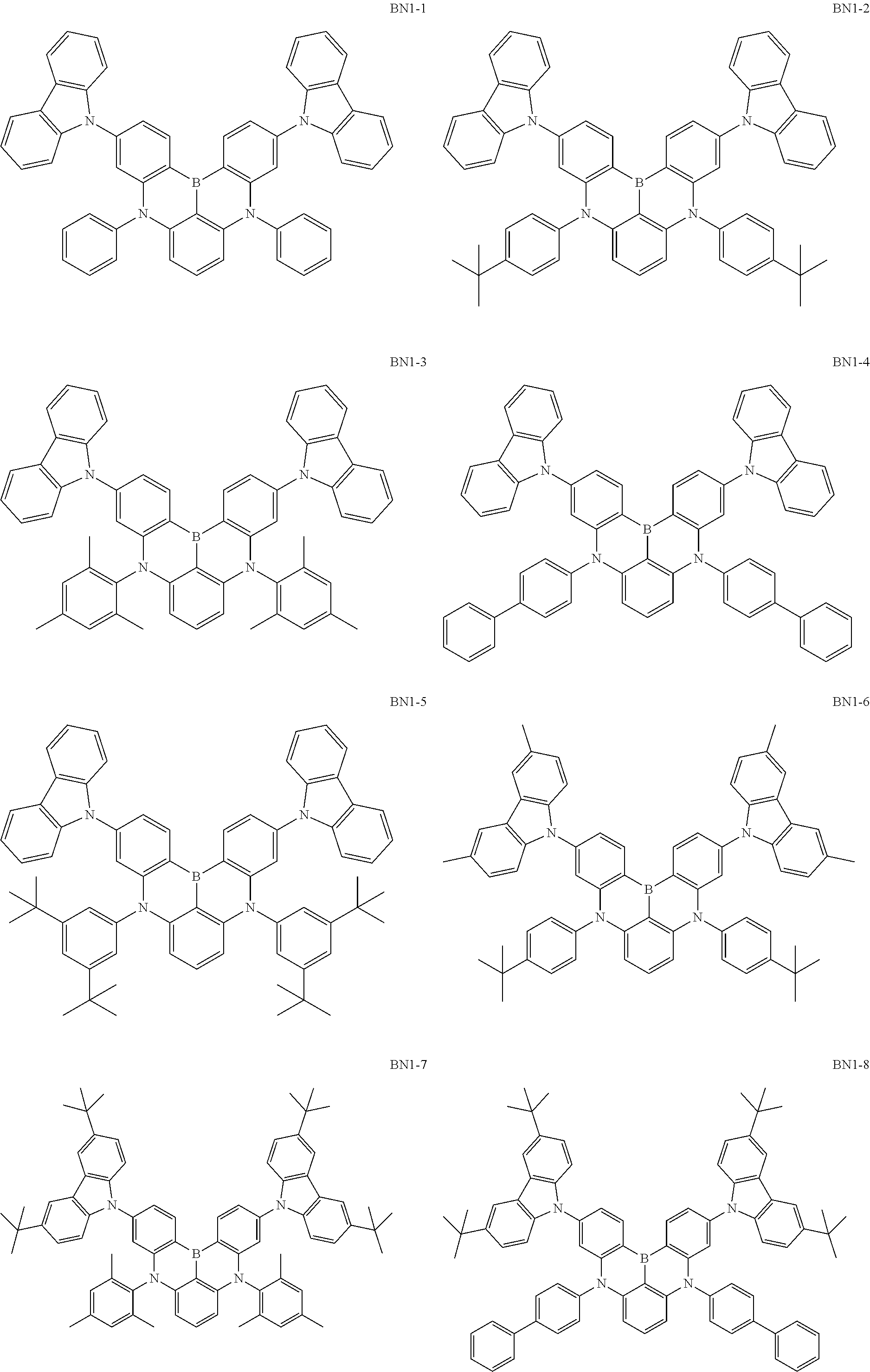

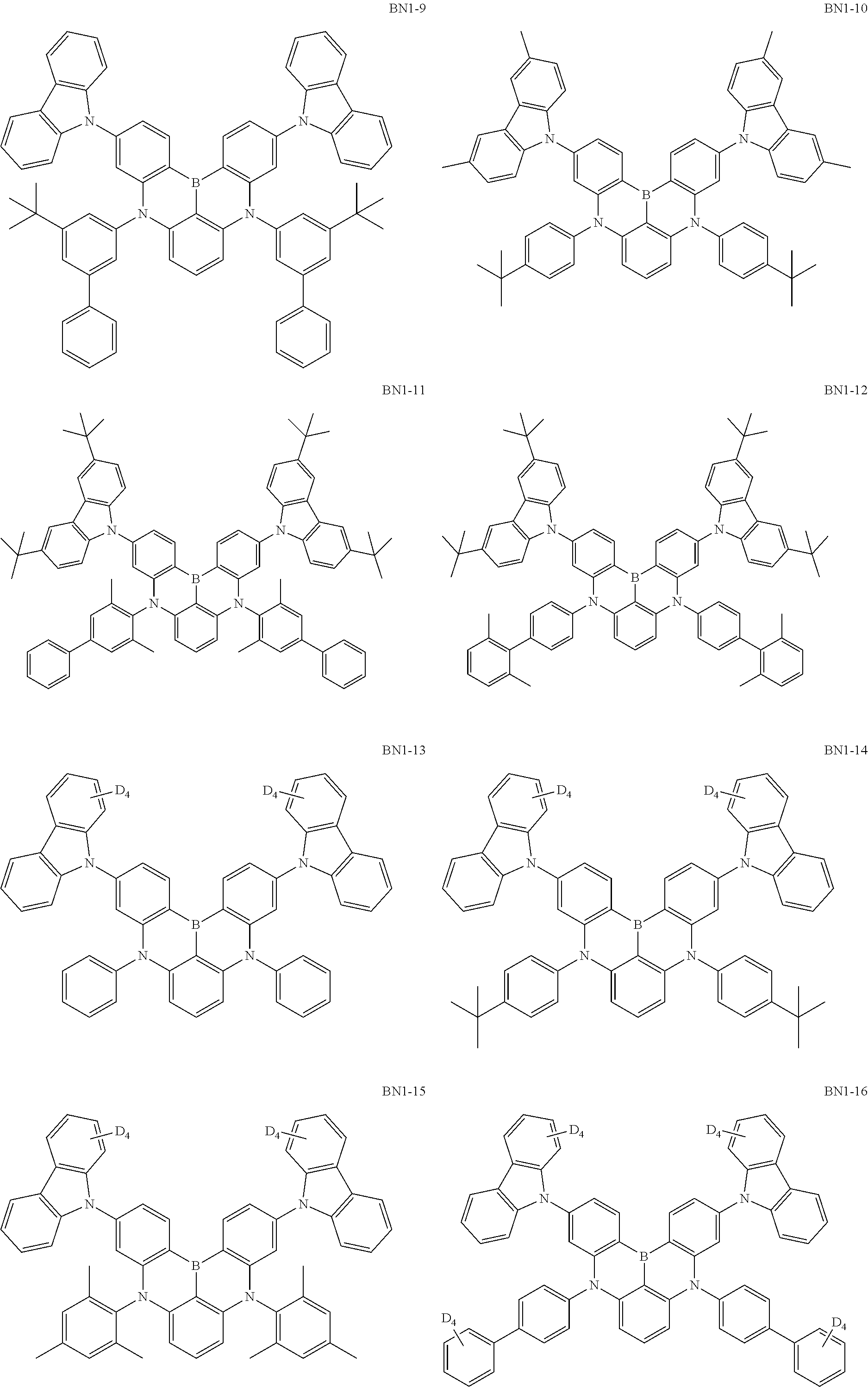

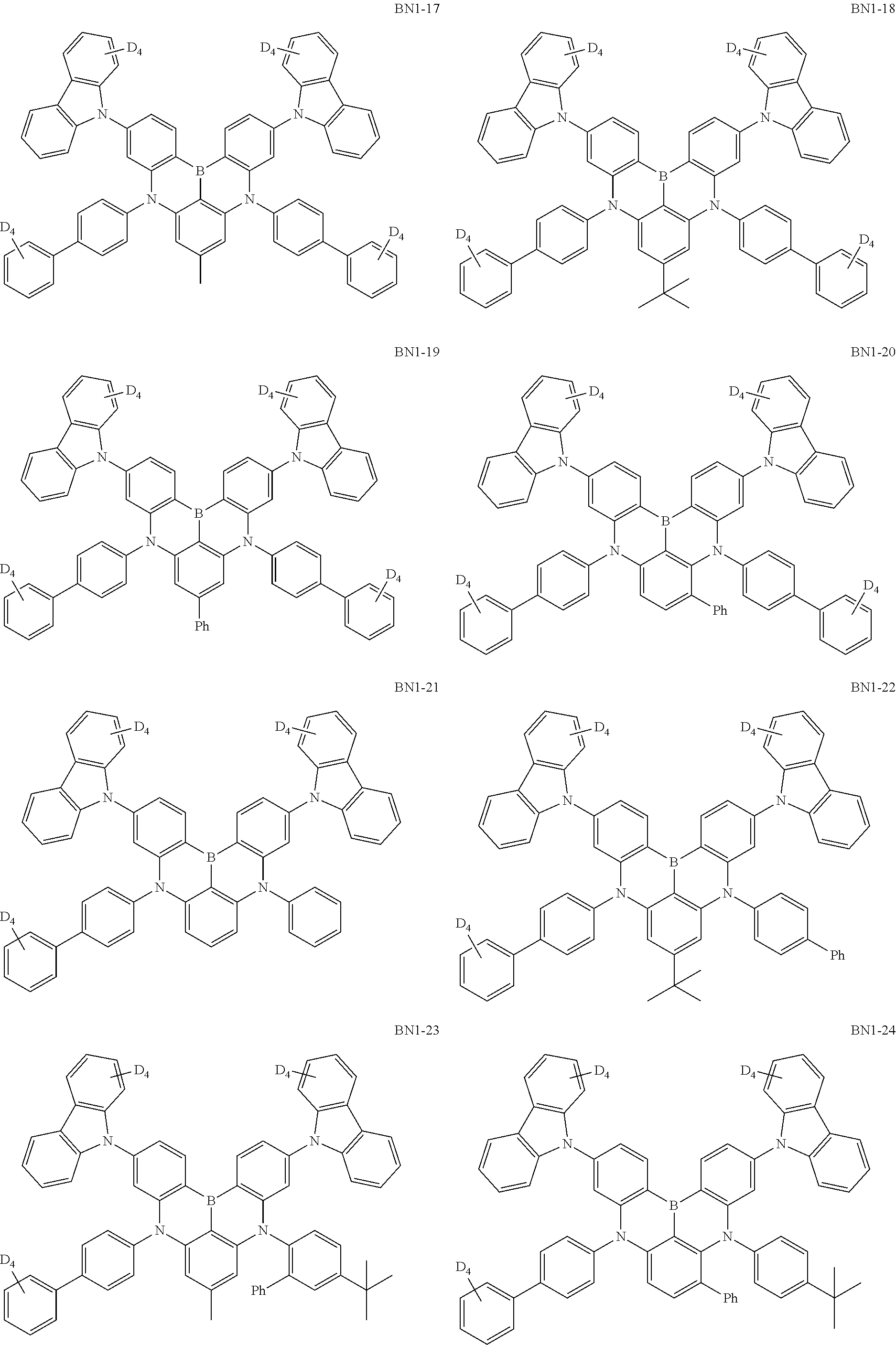

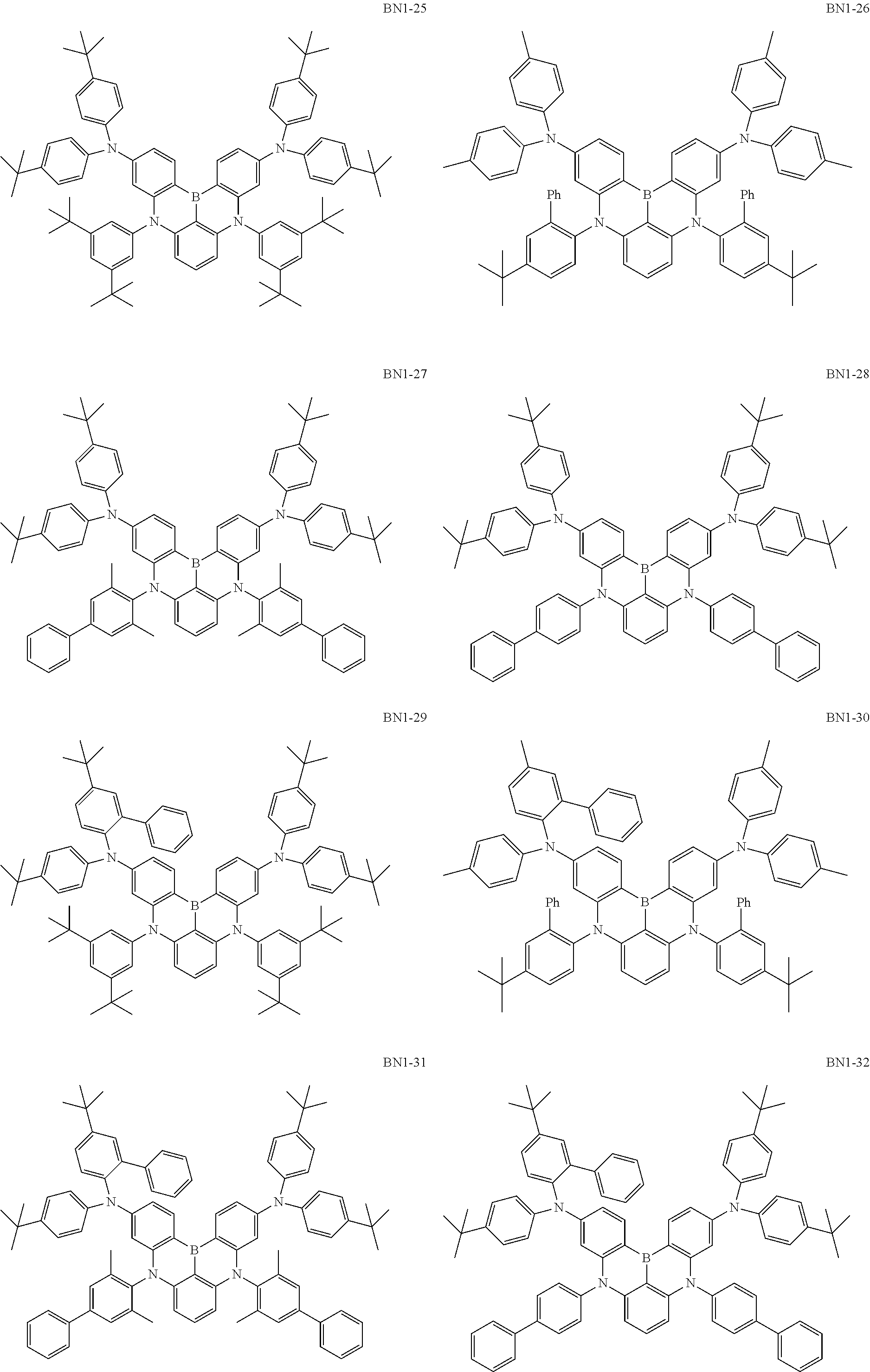

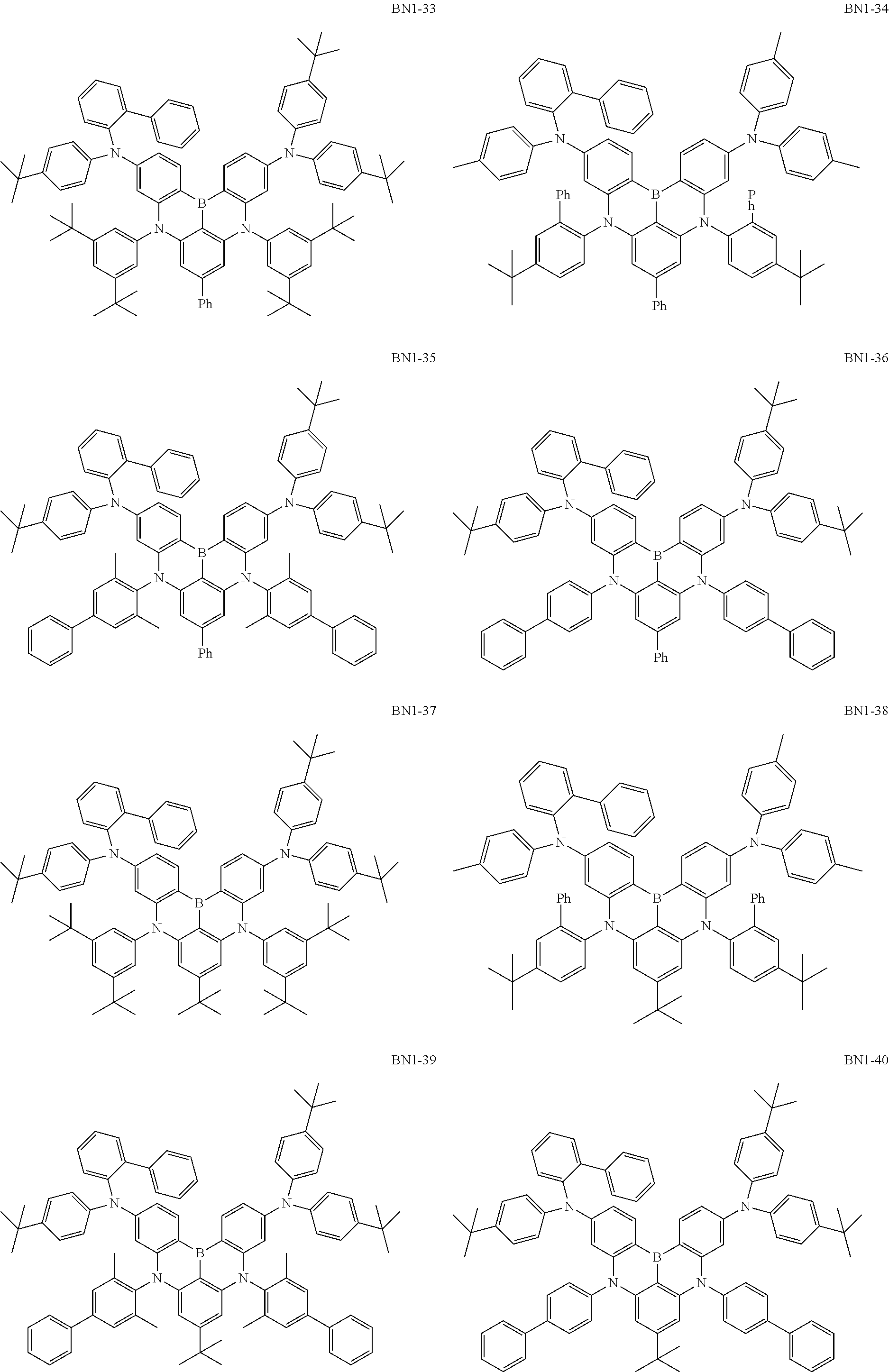

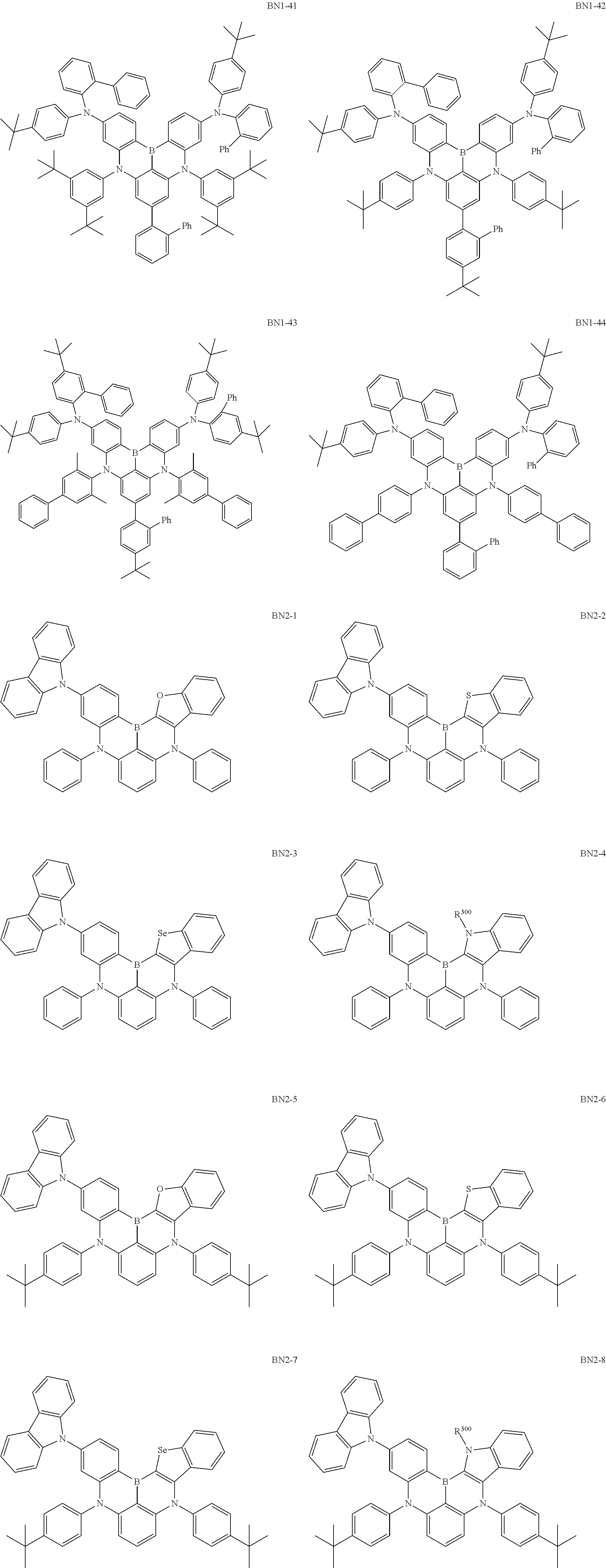

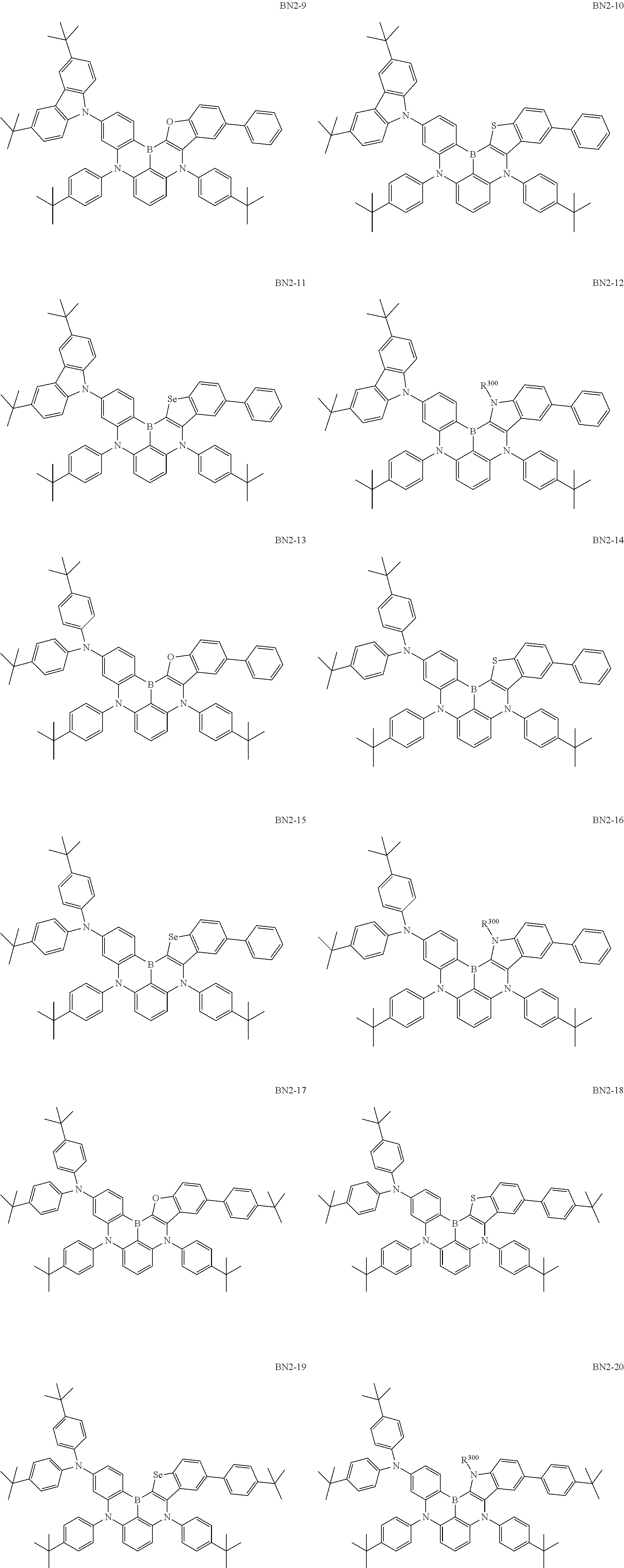

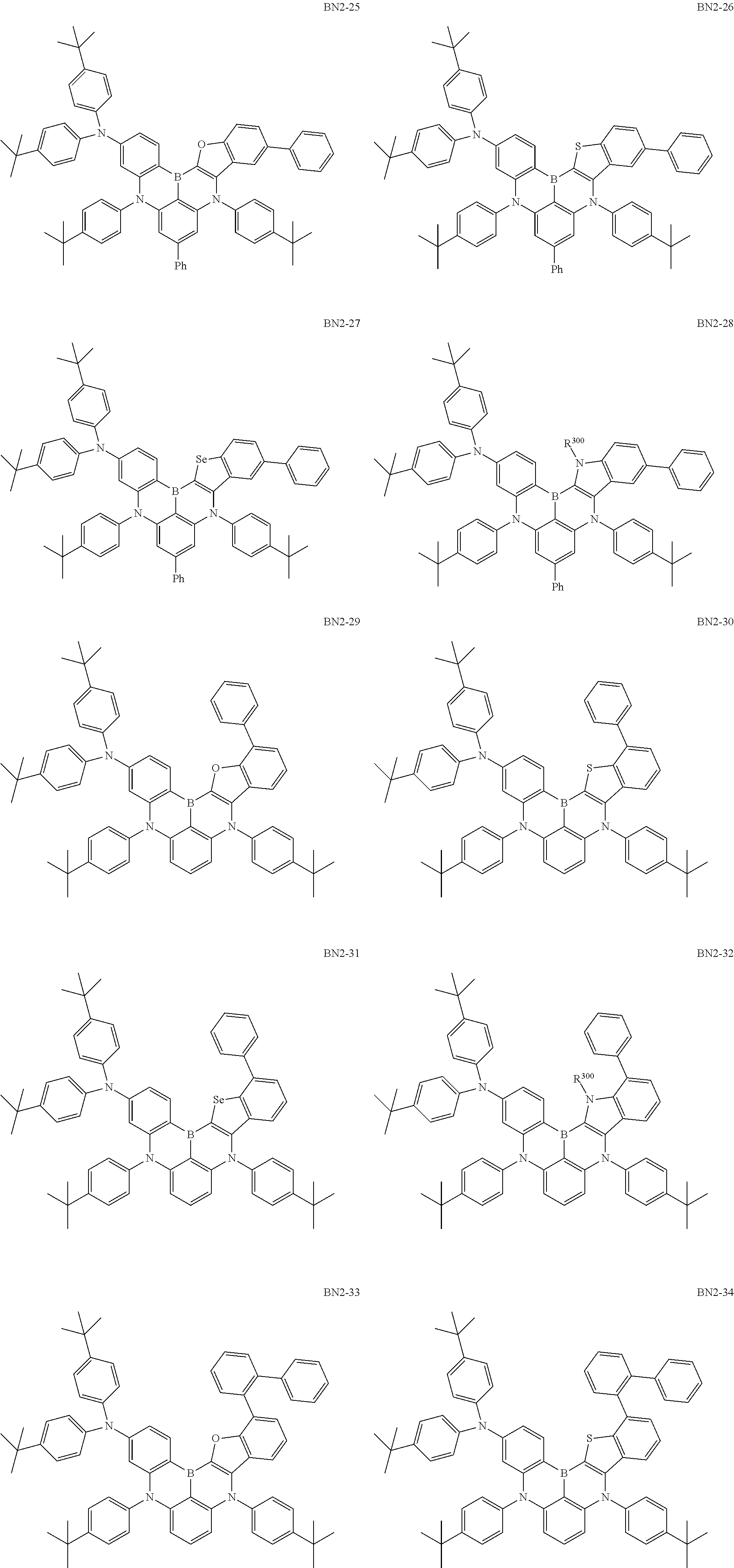

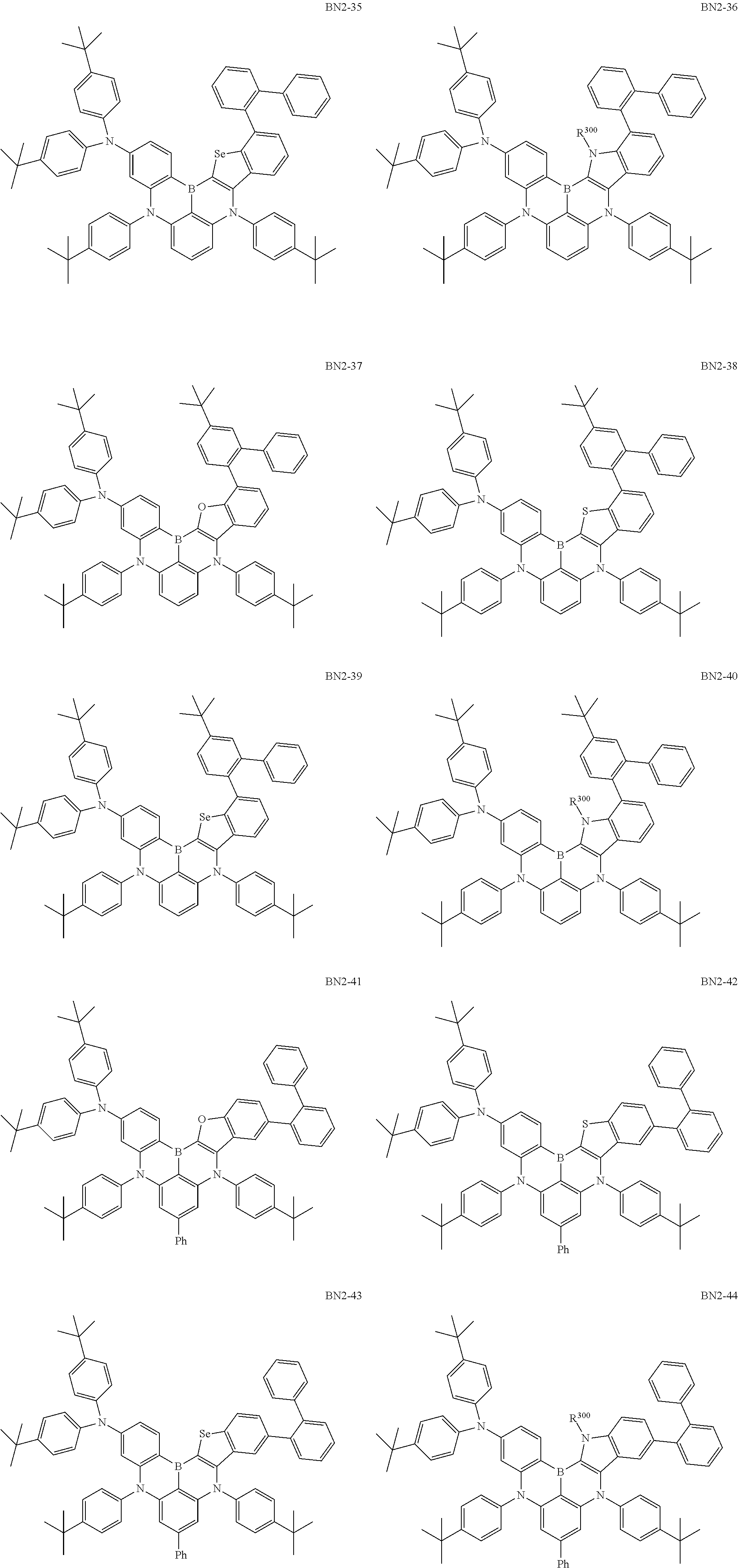

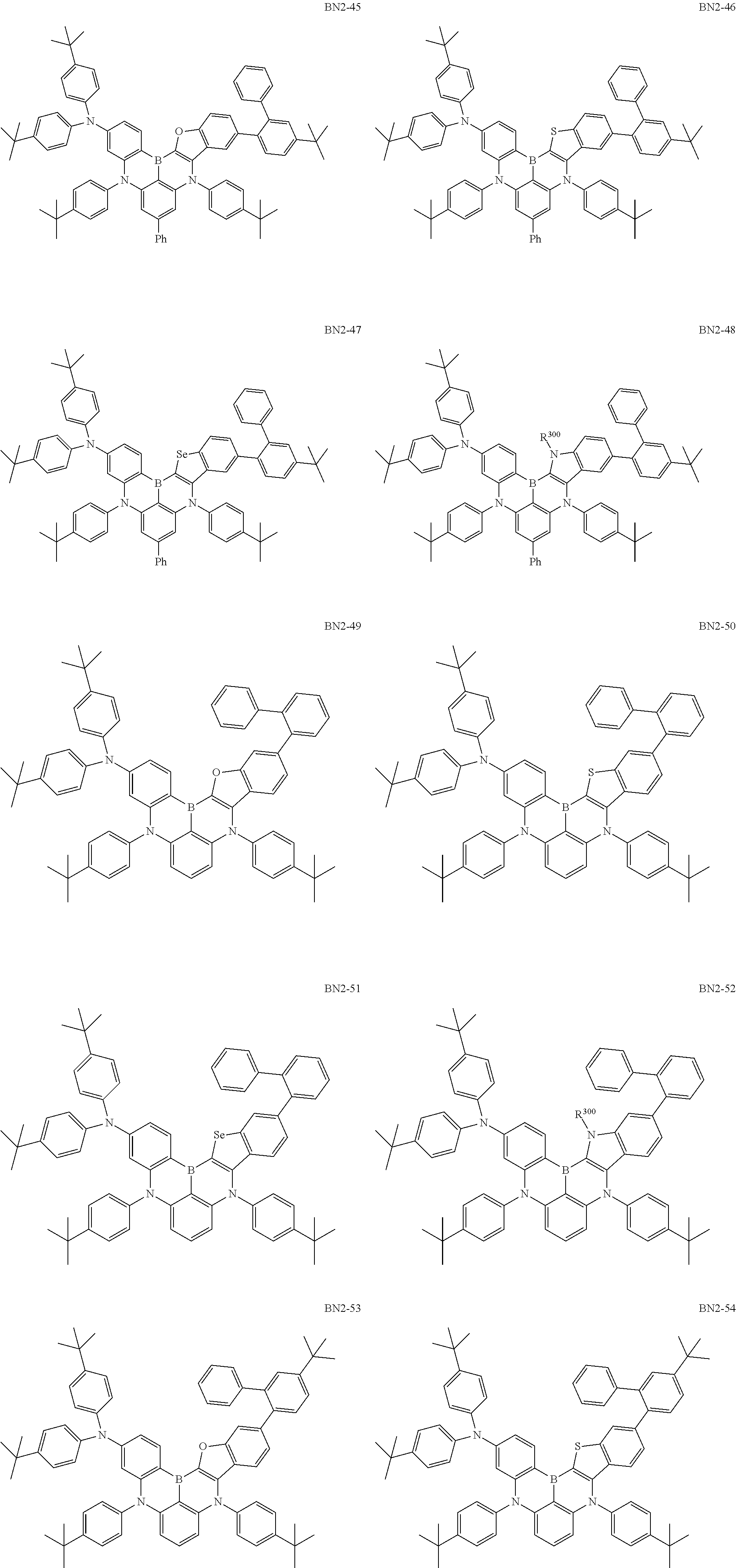

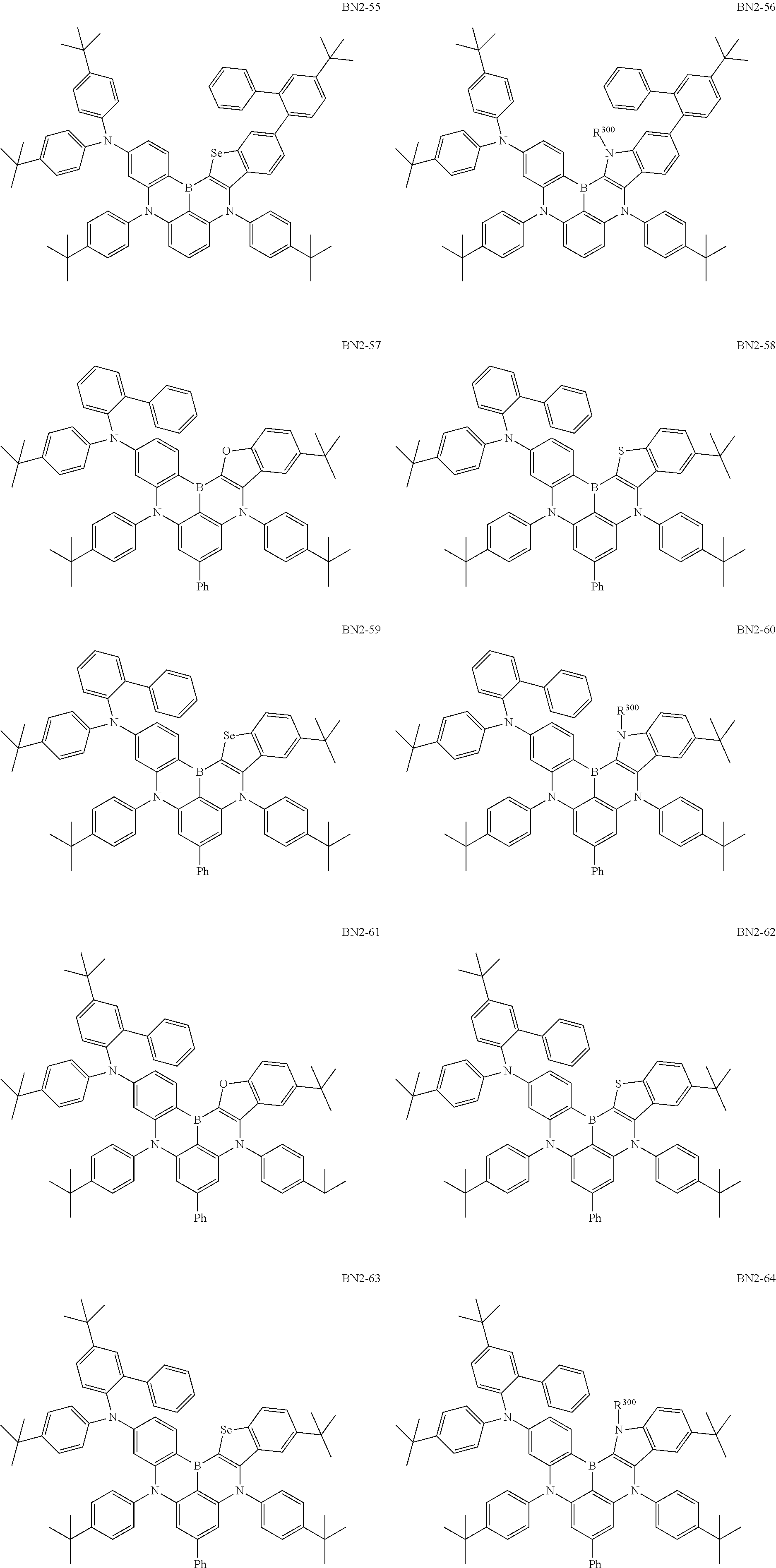

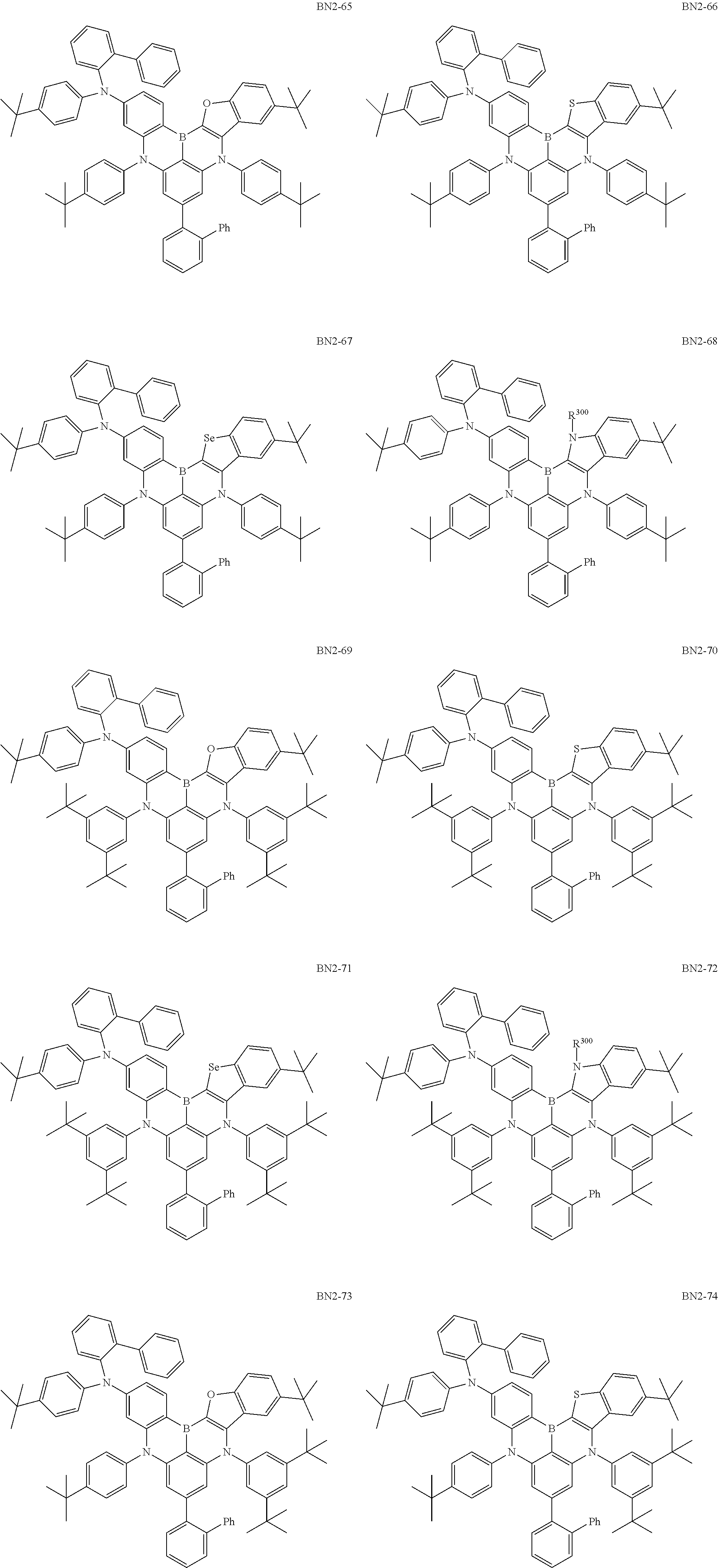

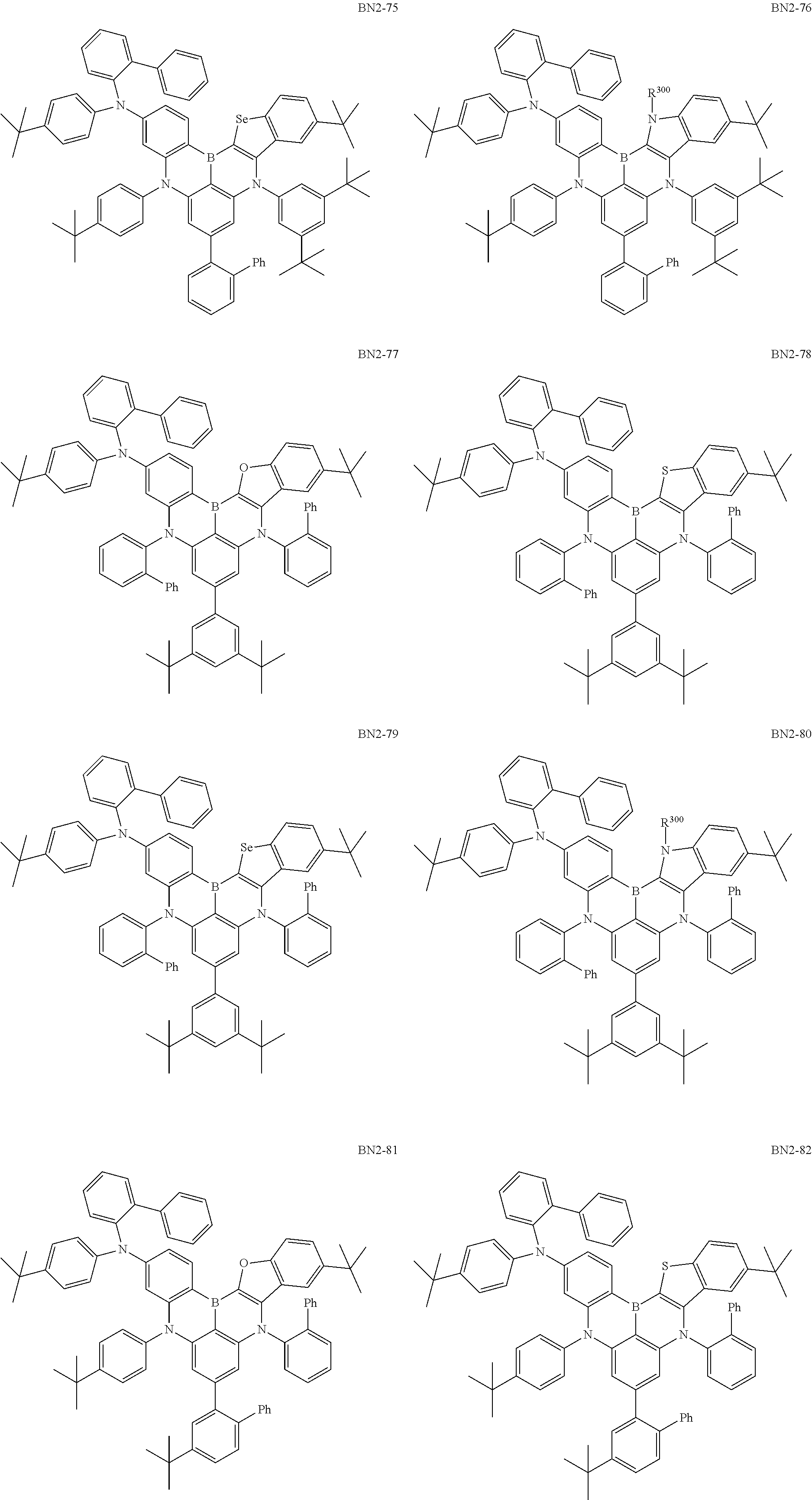

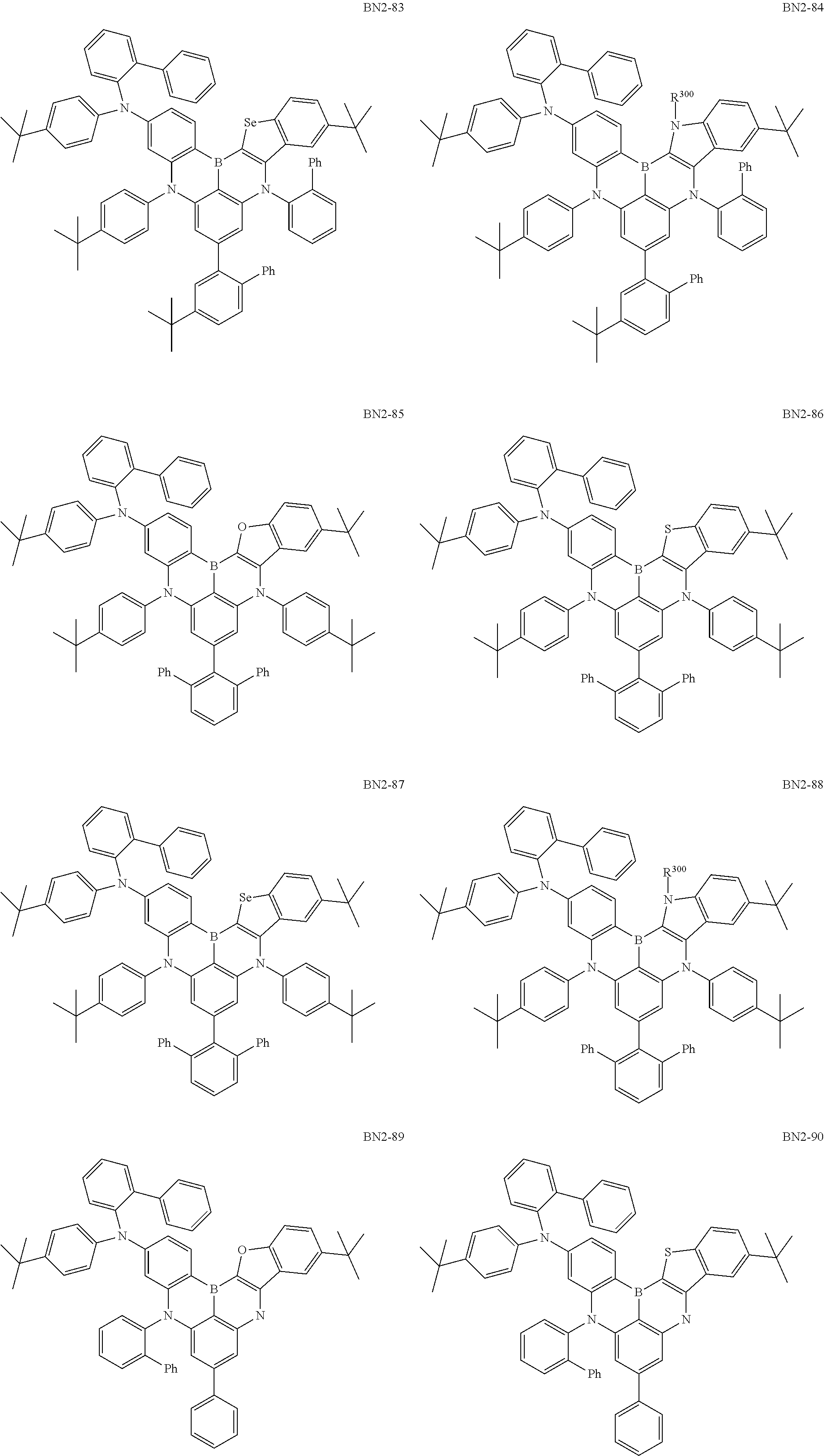

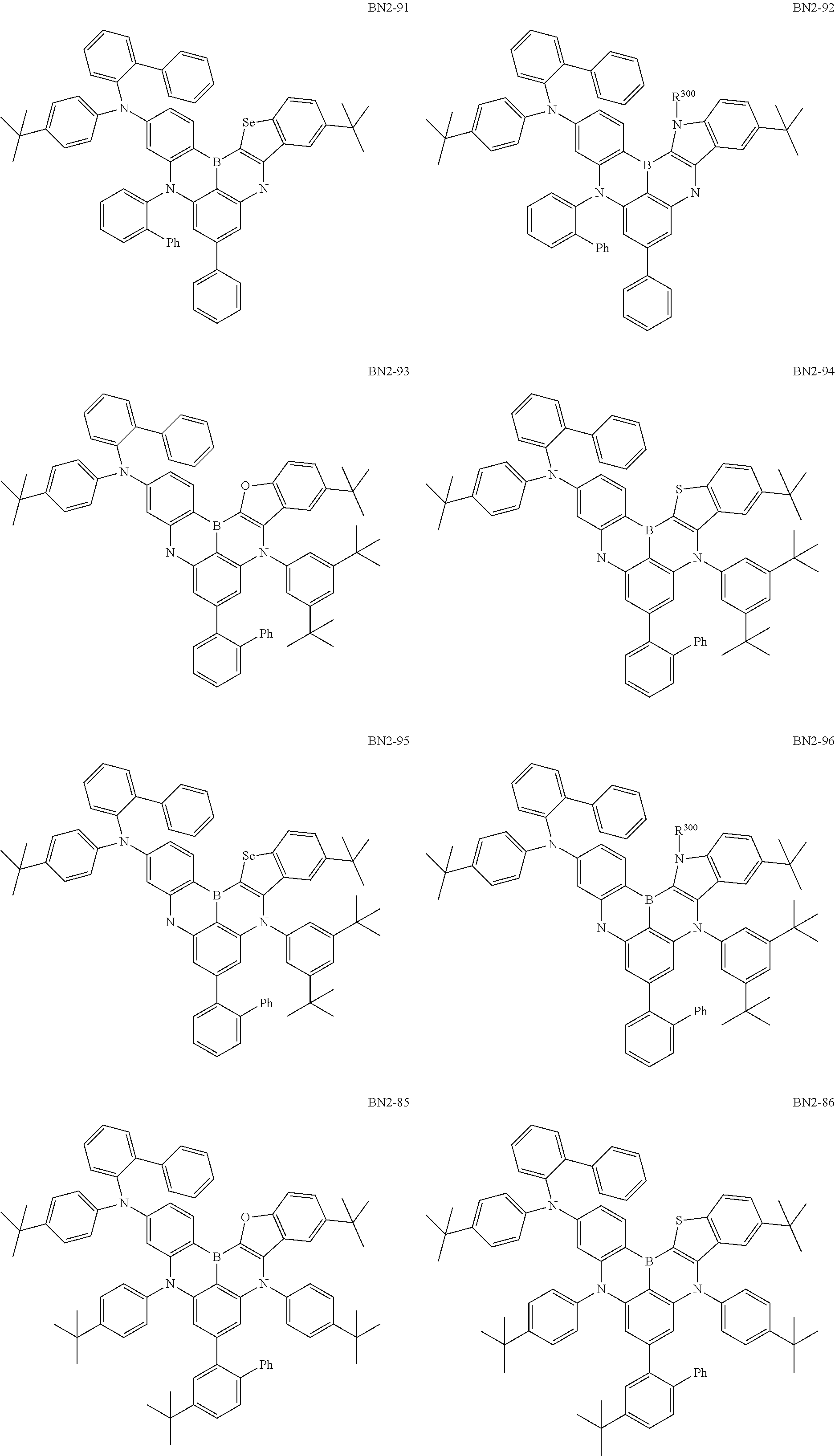

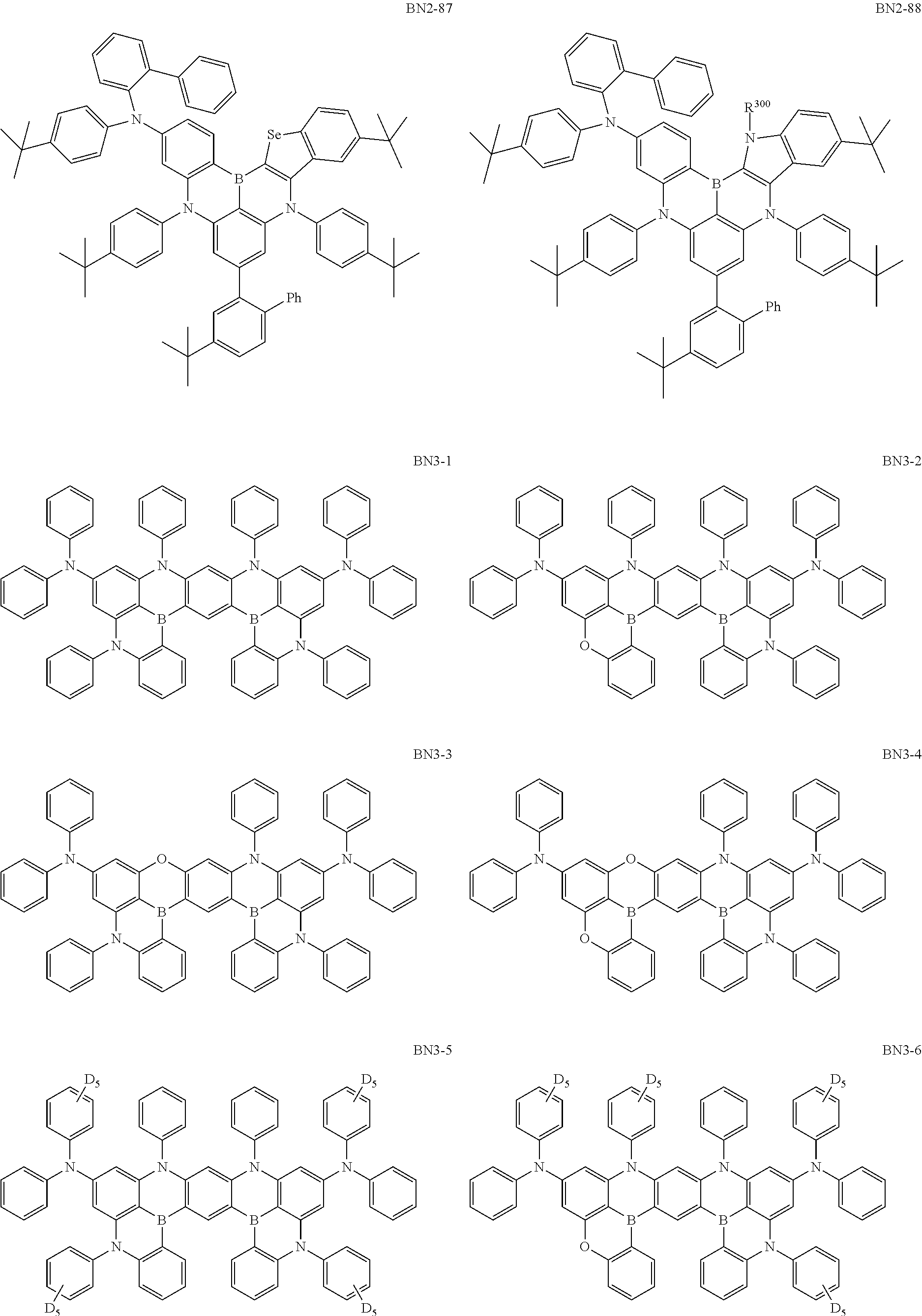

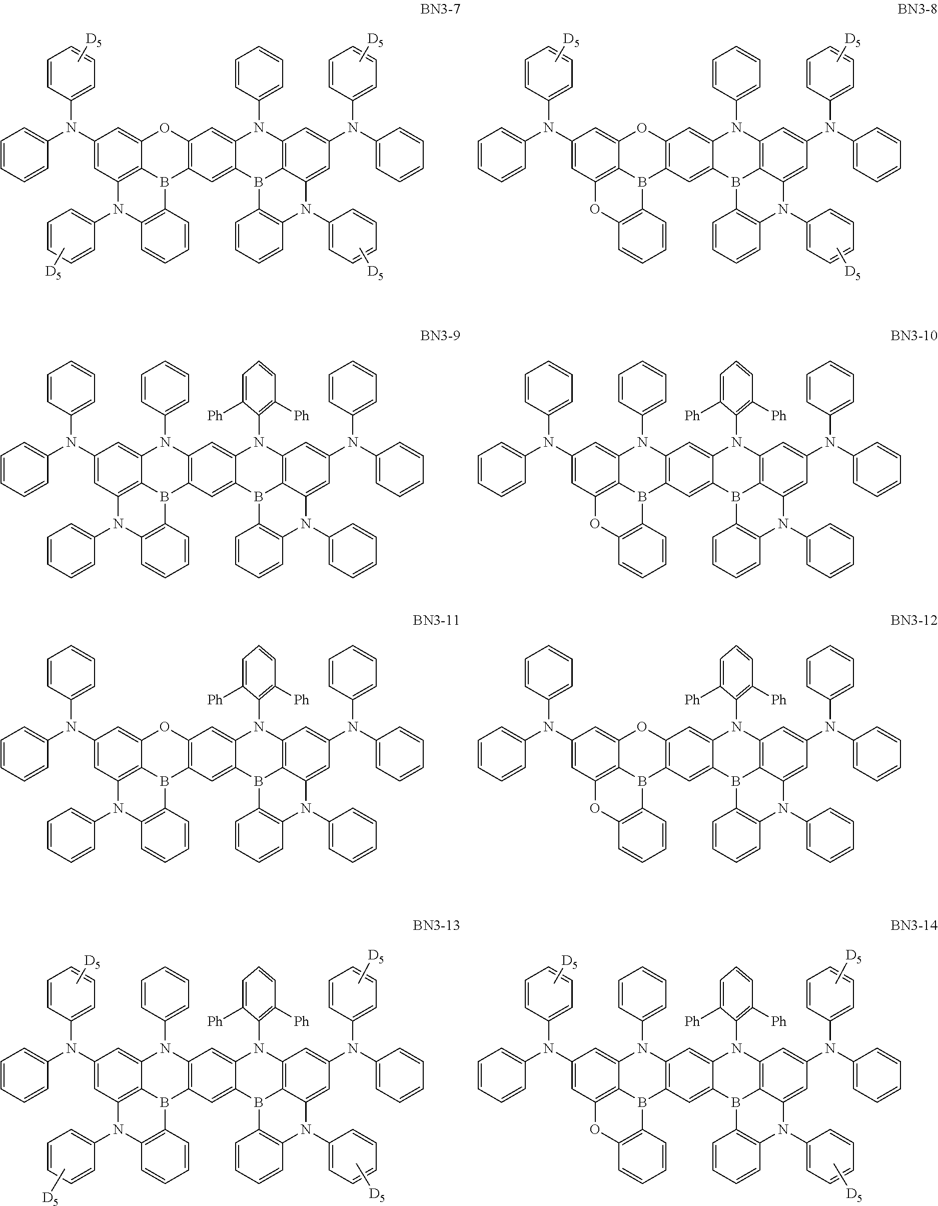

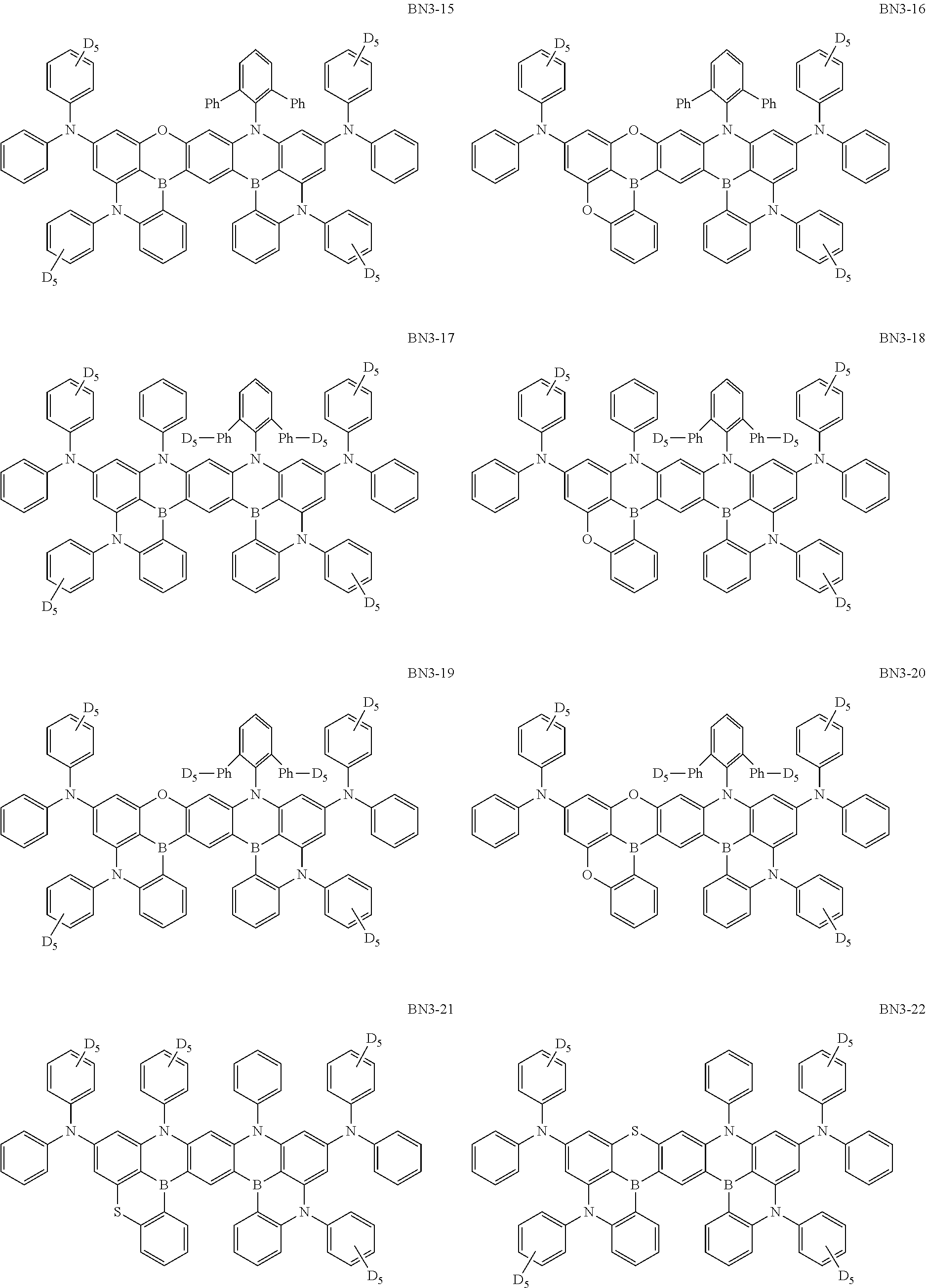

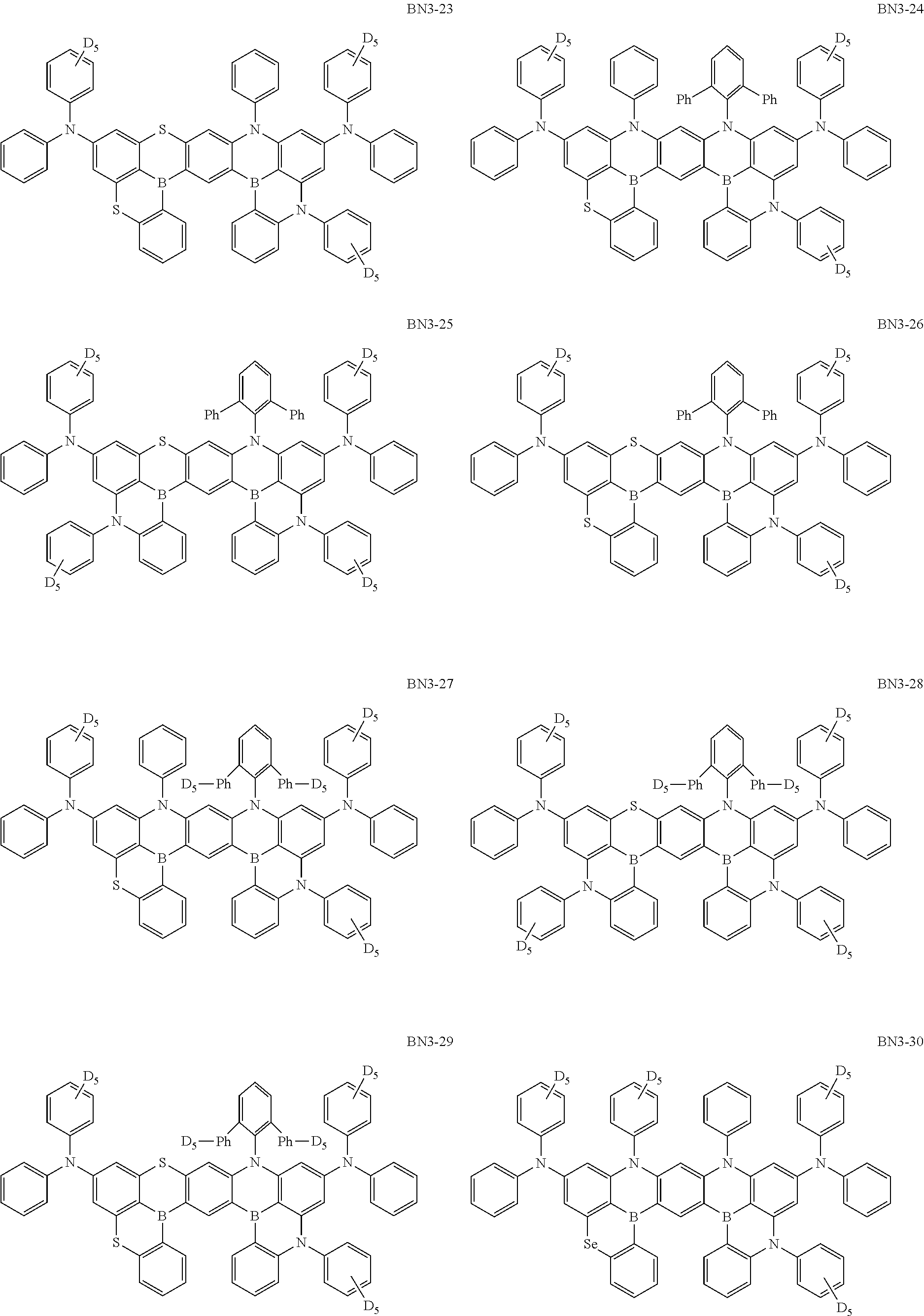

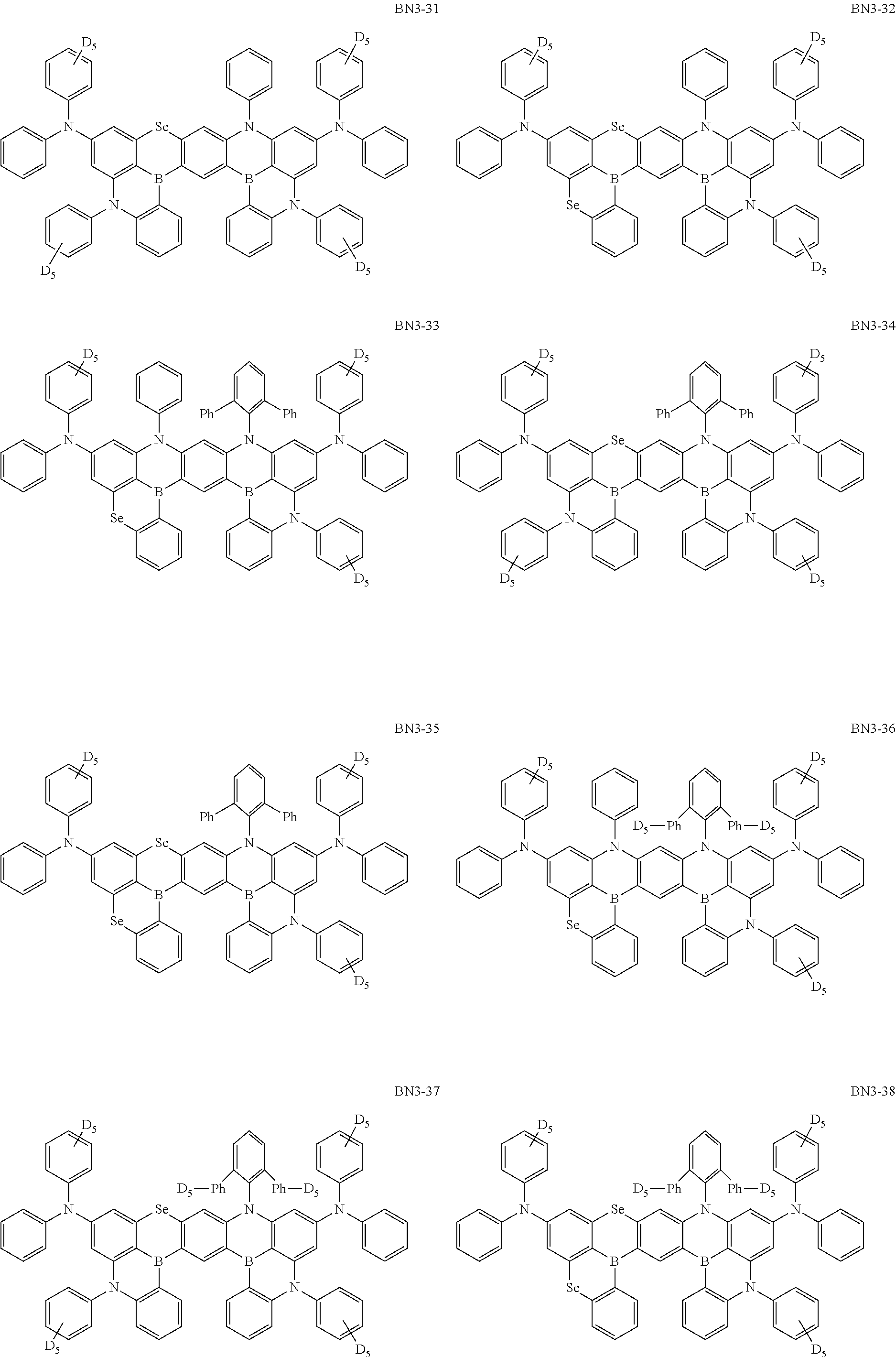

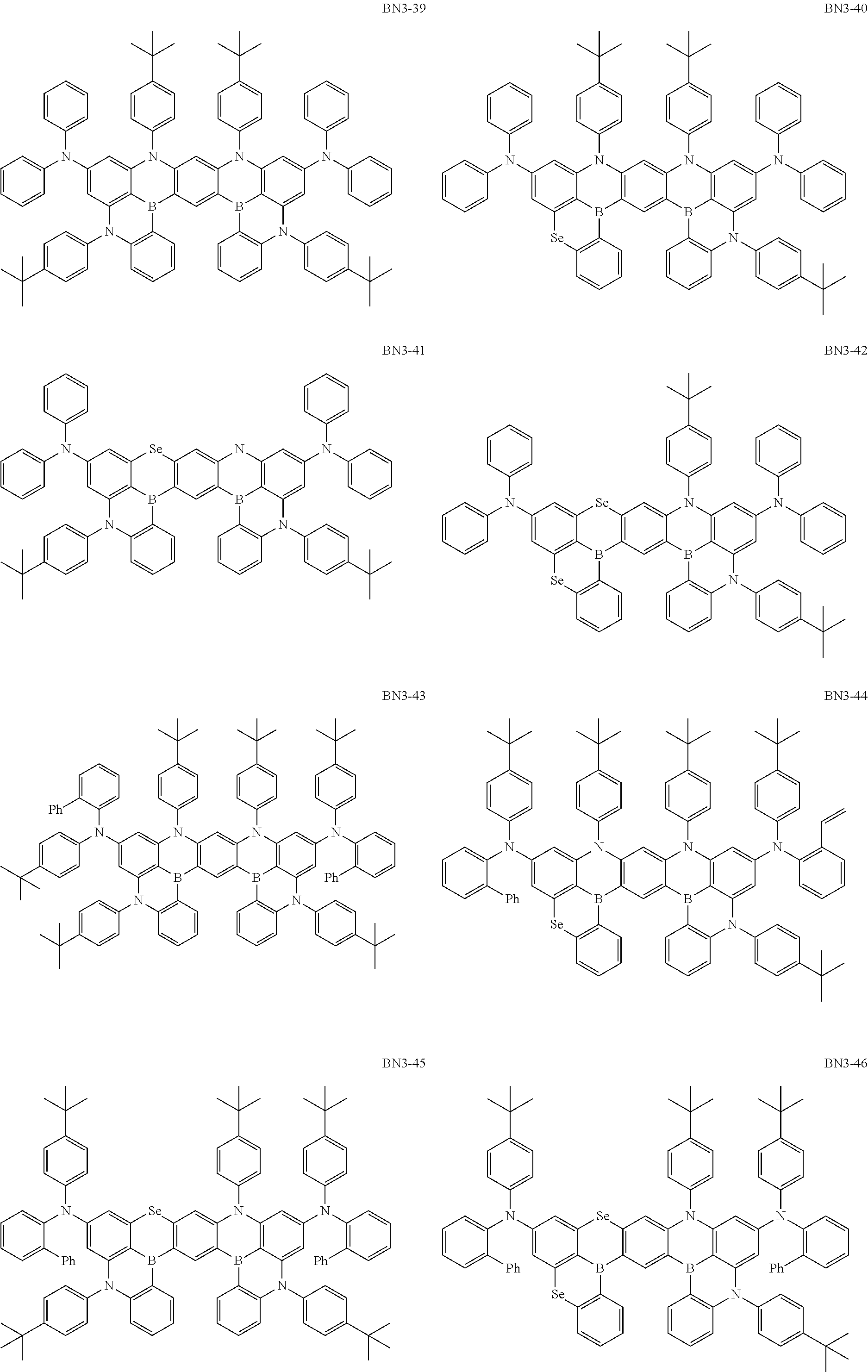

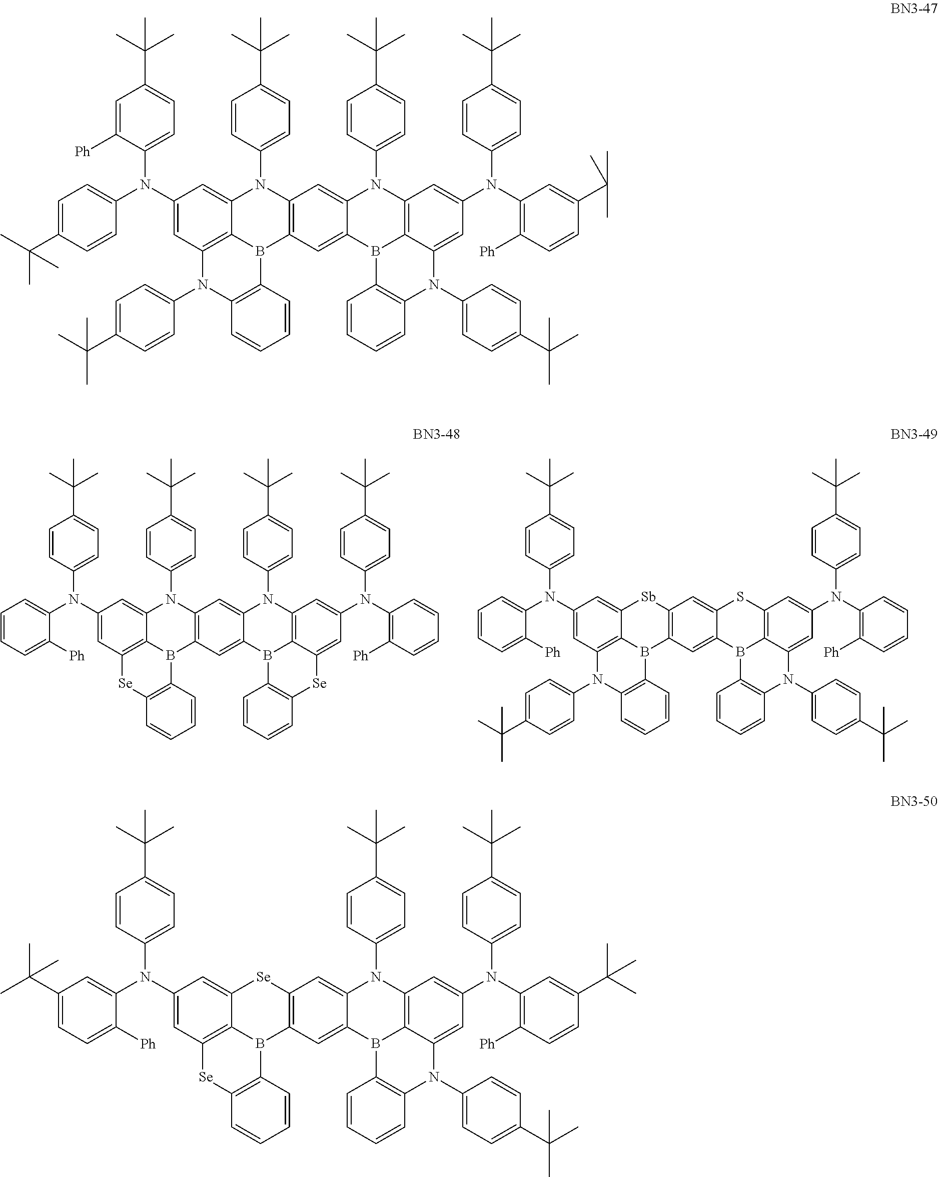

In another aspect, an organic photoelectric device is further provided in this disclosure, which includes a substrate layer; a first electrode on the substrate; an organic light-emitting functional layer on the first electrode; a second electrode on the organic light emitting functional layer. The organic light-emitting functional layer includes the tetradentate cyclometalated platinum (II) complex with a structure shown in formulas Pt1 to Pt45 described above. For example, the platinum (II) complex can be included as a luminescent material in the organic light-emitting functional layer.

Further, the organic light-emitting functional layer further includes a fluorescent doping material, which is any one or more of compounds represented by formulas (BN1) to (BN5).

A composition is further provided in the disclosure, which includes the tetradentate cyclometalated platinum (II) complex with a structure shown in formulas Pt1 to Pt45 described above. Preferably, the composition further includes a fluorescent doping material, which is any one or more of compounds represented by formulas (BN1) to (BN5).

A preparation is further provided in the disclosure, which includes the tetradentate cyclometalated platinum (II) complex with a structure shown in formulas Pt1 to Pt45 described above or the composition as described above and at least one solvent. The solvent is not particularly limited, and unsaturated hydrocarbon solvents such as toluene, xylene, mesitylene, tetralin, decalin, dicyclohexane, n-butylbenzene, sec-butylbenzene and tert-butylbenzene, saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane and bromocyclohexane, halogenated unsaturated hydrocarbon solvents such as chlorobenzene, dichlorobenzene and trichlorobenzene, ether solvents such as tetrahydrofuran and tetrahydropyran, and ester solvents such as benzoic acid alkyl ester, which are well known to those skilled in the art can be used.

Preferably, the composition further includes a fluorescent doping material, which is any one or more of compounds represented by formulas (BN1) to (BN5).

A display or lighting apparatus is further provided in the disclosure, which includes one or more of organic photoelectric devices as described above.

Compared with Related Art, the Disclosure has Following Beneficial Effects:

A phosphorescent material of tetradentate cyclometalated platinum (II) complex is provided in this disclosure. By introducing 2, 6-di (phenyl) tert-butylphenyl into a proper position of its ligand, a dihedral angle with a pyridine unit is increased and packing between molecules is reduced. Meanwhile, distribution of excited charges can be improved, so that the material has more metal-to-pyridine carbene charge transfer states (³MLCT), which facilitates improvement of a radiation rate and thus improvement of service life of devices. Materials involved in the disclosure have good chemical stability and thermal stability, and are easy to prepare vapor-deposited OLED devices. Combined with the fluorescent doping material, transmission of holes and electrons can be balanced and energy transfer between a donor material and an acceptor material can be more efficient. The organic light-emitting device with a light-emitting layer made of the compound according to the disclosure has obviously improved current efficiency and service life, and an obviously reduced lighting voltage. Especially, photochromatic purity of the device can be improved when it is used in combination with boron-containing phosphorescent sensitized compounds.

### DETAILED DESCRIPTION

Contents of the present disclosure are described in detail below. Following description of constituent elements described below is sometimes based on representative embodiments or specific examples of the present disclosure, but the present disclosure is not limited to such embodiments or specific examples.

A term “substituted” as used herein is intended to include all permissible substituents of an organic compound. In a broad aspect, permissible substituents include acyclic and cyclic, branched and unbranched, carbocyclic and heterocyclic, and aromatic and nonaromatic substituents of organic compounds. Illustrative substituents include, for example, those described below. For suitable organic compounds, the permissible substituents may be one or more, the same or different. For a purposes of the present disclosure, heteroatom (e. g., nitrogen) can have a hydrogen substituent and/or any permissible substituent of the organic compound of the present disclosure satisfying valence bonds of the heteroatom. The present disclosure is not intended to be limiting in any way with the permissible substituents of the organic compound. As such, a term “substituted” or “substituted with” encompasses an implicit condition that such a substitution conforms to permissible valence bonds of a substituted atom and the substituent, and that the substitution results in stable compounds (e. g., compounds that do not spontaneously undergo conversion (e. g., by rearrangement, cyclization, elimination, etc.)). It is also contemplated that in certain aspects, individual substituents can be further optionally substituted (i.e., further substituted or unsubstituted) unless explicitly indicated to the contrary.

In defining various terms, “R₁” to “R₁₁” are used in the present disclosure as general symbols to denote various specific substituents. These symbols can be any substituent, not limited to those disclosed in the present disclosure, and when they are defined as some substituents in one case, they can be defined as some other substituents in other cases.

“R₁”, “R₂”, “R₃”, “Rₙ” (where n is an integer) as used herein may independently have one or more of groups listed above. For example, if R¹ is linear alkyl, one hydrogen atom of the alkyl may be optionally substituted with hydroxy, alkoxy, alkyl, halogen or the like. Depending on a selected group, a first group may be incorporated within a second group, or alternatively, the first group may be suspended, i.e., linked to the second group. For example, for a phrase “an alkyl including amino”, the amino may be incorporated within a main chain of the alkyl. Alternatively, the amino may be linked to the main chain of the alkyl. Nature of the selected group may determine whether the first group is embedded in or linked to the second group.

A term “alkyl” as used herein is a branched or unbranched saturated hydrocarbon group with 1 to 60 carbon atoms, such as methyl, ethyl, n-propyl, isopropyl, n-butyl, isobutyl, sec-butyl, tert-butyl, n-pentyl, isopentyl, sec-pentyl, neopentyl, hexyl, heptyl, octyl, nonyl, decyl, dodecyl, tetradecyl, hexadecyl, eicosyl, tetracosyl and the like. The alkyl may be cyclic or acyclic. The alkyl group may be branched or unbranched. The alkyl may also be substituted or unsubstituted. For example, the alkyl may be substituted with one or more group including, but not limit to, optionally substituted alkyl, cycloalkyl, alkoxy, amino, ether, halogen, hydroxy, nitro, silyl, sulfo-oxo and thiol as described herein.

A term “aryl” as used herein is a group containing any carbon-based aromatic group with 5 to 60 carbon atoms, including but not limited to phenyl, naphthyl, biphenyl, phenoxyphenyl, anthracenyl, phenanthrenyl, and the like. A term “aryl” also includes “heteroaryl”, which is defined as a group containing an aromatic group having at least one heteroatom introduced into a ring of the aromatic group. Examples of heteroatoms include, but are not limited to, a nitrogen, oxygen, sulfur, and phosphorus atom. Likewise, a term “non-heteroaryl” (which is also included in the term “aryl”) defines an aromatic-containing group that is free of heteroatoms. The aryl may be substituted or unsubstituted. The aryl may be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxyl, ester, ether, halogen, hydroxy, carbonyl, azido, nitro, silyl, sulfo-oxo or thiol as described herein.

A term “amine” or “amino” as used herein is represented by the formula —NR¹R², where R¹ and R₂ may independently be selected from hydrogen, alkyl, cycloalkyl, alkenyl, cycloalkenyl, alkynyl, cycloalkynyl, aryl or heteroaryl.

The compound of that present disclosure may contain an “optionally substituted” moiety. In general, a term “substituted” (whether or not a term “optionally” exists before it) means that one or more hydrogen atoms of a given moiety are substituted with a suitable substituent. Unless otherwise stated, an “optionally substituted” group may have suitable substituents at each of substitutable positions of the group, and when more than one position in any given structure may be substituted with more than one substituent selected from groups designated, the substituents at each position may be the same or different. Combinations of substituents contemplated in the present disclosure are preferably those that form stable or chemically feasible compounds. It is also included that in certain aspects, respective substituents may be further optionally substituted (i. e., further substituted or unsubstituted) unless explicitly stated to the contrary.

A structure of the compound may be represented by a following formula:

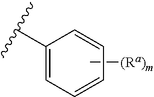

which is understood as equivalent to a following formula:

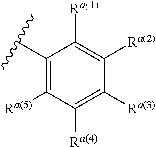

where n is typically an integer. That is, Rₙ is understood to represent five individual substituents, namely, R^{a(1)}, R^{a(2)}, R^{a(3)}, R^{a(4)} and R^{a(5)}. “individual substituents” means that each R substituent may be defined independently. For example, if R^{a(m)} is halogen in one case, R^{a(n)} is not necessarily halogen in this case.

The compound disclosed herein can exhibit desirable properties and have emission and/or absorption spectra that can be adjusted by selecting appropriate ligands. On the other hand, any one or more compounds, structures or parts thereof specifically described herein can be excluded in the disclosure.

The compound according to the present disclosure can be prepared in various methods, including but not limited to those described in examples provided herein.

It should be noted that both the above general description and the following detailed description are exemplary and explanatory only, but not limiting.

The present disclosure may be more readily understood by reference to the following detailed description and examples included therein.

Before compounds, devices, and/or methods of the present disclosure are disclosed and described, it should be understood that they are not limited to specific synthetic methods (unless otherwise specified) or specific reagents (unless otherwise specified), as these may vary. It should also be understood that terminologies used in the present disclosure is for a purpose of describing specific aspects only and is not intended to be limiting. While any method and material similar or equivalent to those described herein may be used in this practice or test, example methods and materials are described below. All of raw materials and solvents in synthesis embodiments can be available commercially unless otherwise specified, and the solvents are used directly without further treatment.

The substrate of the present disclosure can be any substrate used in typical organic photoelectric devices. It can be a glass substrate or transparent plastic substrate, a substrate of an opaque material such as silicon or stainless steel, or a flexible PI film. Different substrates have different mechanical strength, thermal stability, transparency, surface smoothness and waterproofness, with different use according to properties of the substrates. As materials of a hole injection layer, a hole transport layer and an electron injection layer, any material can be selected from known related materials used for OLED devices, which is not specifically limited in the present disclosure.

### Synthetic Example

Following examples about compound synthesis, components, devices or methods are only to provide a general method for the industry, and are not intended to limit a protection scope of the disclosure. Data mentioned in the disclosure (number, temperature, etc.) are as accurate as possible, but there may be some errors. Unless otherwise specified, weighing is made separately, the temperature is in ° C., or a normal temperature, and a pressure is close to a normal pressure.

A preparation method of a new compound is provided in following examples, but the preparation of such compounds is not limited thereto. In this technical field, because the claimed compound in this disclosure is easy to be modified and prepared, following methods or other methods can be adopted in its preparation. The following examples are only embodiments and are not intended to limit the protection scope of this disclosure. Temperature, catalyst, concentration, reactants and reaction processes can all be changed so as to select different conditions for different reactants for preparing the compound.

¹H NMR (500 MHz), ¹H NMR (400 MHz) and ¹³C NMR (126 MHz) spectra were measured on an ANANCE III (500 m) nuclear magnetic resonance spectrometer, in which, unless otherwise specified, DMSO-d₆ or CDCl₃ containing 0.1% TMS is used as a solvent, and when CDCl₃ is used as a solvent for a ¹H NMR spectrum, TMS (δ=0.00 ppm) is used as an internal standard; and when DMSO-d₆ is used as the solvent, TMS (δ=0.00 ppm) or a residual DMSO peak (δ=2.50 ppm) or a residual water peak (δ=3.33 ppm) is used as the internal standard. In a ¹³C NMR spectrum, CDCl₃ (δ=77.00 ppm) or DMSO-d₆ (δ=39.52 ppm) was used as the internal standard. It is measured on a HPLC-MS Agilent 6210 TOF LC/MS mass spectrometer; and a HRMS spectrum is measured on an Agilent 6210 TOF LC/MS liquid chromatography-time-of-flight mass spectrometer. In ¹H NMR spectrogram data, s means singlet, d means doublet, t means triplet, q means quart, p means quintet, m means multiplet, and br means broad.

### Embodiment 1 Synthetic Route of Intermediate (dPh-tBuNH₂) is as Follows

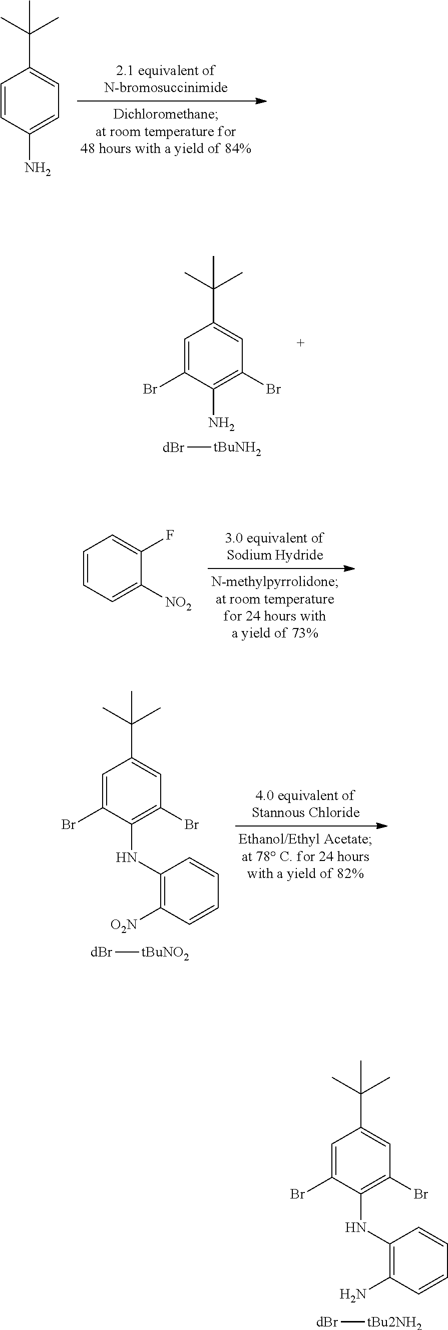

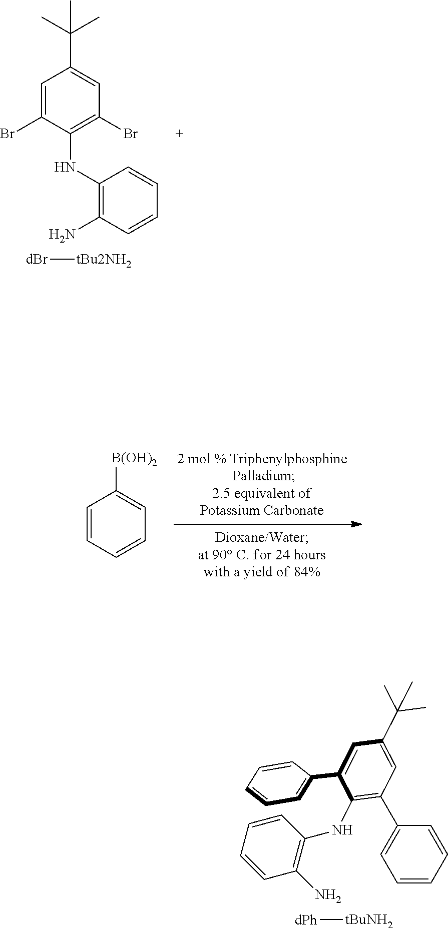

Synthesis of intermediate (dBr-tBuNH₂); P-tert-butylaniline (15.0 g, 100 mmol, 1.0 equivalent), dichloromethane (150 mL) and N-bromosuccinimide (37.7 g, 210 mmol, 2.1 equivalent) were added to a reaction bottle for dissolution, and reacted at room temperature for 48 hours and then reaction was stopped. Organic phases were separated, concentrated and subjected to silica gel column chromatography to obtain 25.6 g of red liquid, with a yield of 84%. The liquid was directly used in a next step without structural characterization.

Synthesis of intermediate (dBr-tBuNO₂); dBr-tBuNH₂(5 g, 16.3 mmol, 1.0 equivalent) was added to a reaction bottle, which was dissolved with N-methylpyrrolidone (50 mL), sodium hydride (1.96 g, 49 mmol, 3.0 equivalent) was added, o-fluoronitrobenzene (3.45 g, 24.5 mmol, 1.5 equivalent) was added, for reaction at room temperature for 48 hours and then reaction was stopped. Organic phases were separated, concentrated and subjected to silica gel column chromatography to obtain 5.08 g of yellow solid, with a yield of 73%. The liquid was directly used in a next step without structural characterization.

Synthesis of intermediate (dBr-tBu2NH₂); dBr-tBuNO₂(4.8 g, 11.2 mmol, 1.0 equivalent), stannous chloride (10.1 g, 44.8 mmol, 4.0 equivalent), and ethyl acetate (50 mL) and ethanol (50 mL) were added. Reaction was carried out in oil at 78° C. for 24 hours and then reaction was stopped, which was cooled to the room temperature. Organic phases were separated, concentrated and subjected to silica gel column chromatography to obtain 3.43 g of white solid, with a yield of 82%. The liquid was directly used in a next step without structural characterization.

Synthesis of intermediate (dPh-tBuNH₂); dBr-tBu2NH₂(3.2 g, 8 mmol, 1.0 equivalent), phenylboronic acid (2.93 g, 24 mmol, 3.0 equivalent), triphenylphosphine palladium (185 mg, 0.16 mmol, 0.02 equivalent), potassium carbonate (2.8 g, 20 mmol, 2.5 equivalent), dioxane (40 mL) and water (15 mL) were added to a reaction bottle. Reaction was carried out at 90° C. for 24 hours and then reaction was stopped, which was cooled to the room temperature. Organic phases were separated, concentrated and subjected to silica gel column chromatography to obtain 2.66 g of white solid, with a yield of 84%. ¹H NMR (500 MHz, DMSO) δ 1.35 (s, 9H), 4.44 (s, 2H), 5.57 (s, 1H), 6.05 (dd, J=8.0, 1.5 Hz, 1H), 6.12 (td, J=7.5, 1.5 Hz, 1H), 6.25 (td, J=7.5, 1.5 Hz, 1H), 6.31 (dd, J=7.5, 1.5 Hz, 1H), 7.16-7.20 (m, 2H), 7.23-7.26 (m, 4H), 7.28 (s, 2H), 7.41-7.43 (m, 4H).

### Embodiment 2 Synthetic Route of Pt1 is as Follows

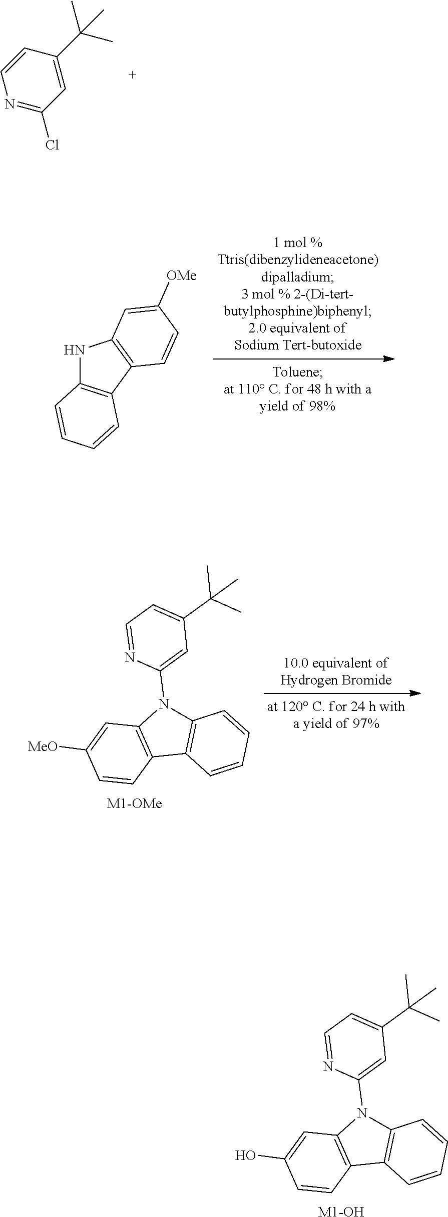

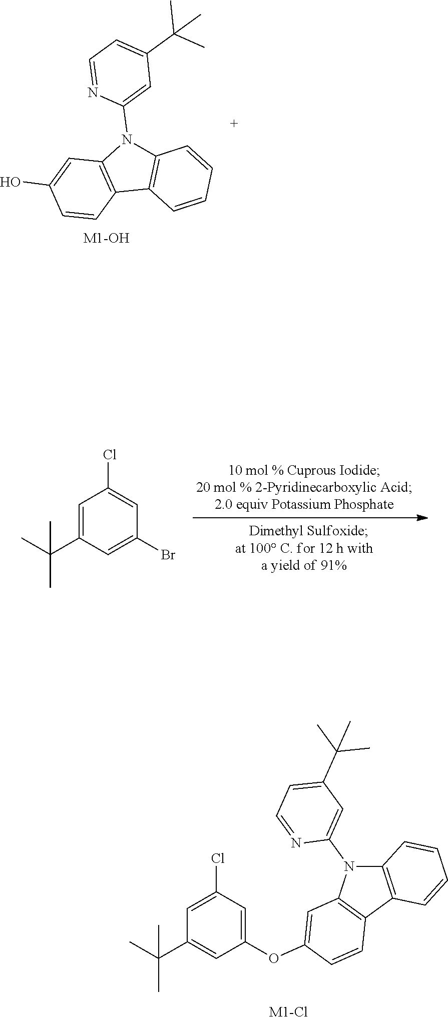

Synthesis of intermediate (M1-OMe); 4-(tert-butyl)-2-chloropyridine (20.6 g, 121.2 mmol, 1.2 equivalent), 2-methoxycarbazole (20 g, 101 mmol, 1.0 equivalent), tris(dibenzylideneacetone)dipalladium (925 mg, 1.01 mmol, 3 mol %), 2-(di-tert-butylphosphine) biphenyl (904 mg, 3.03 mmol, 3 mol %), and sodium tert-butoxide (19.41 g, 202 mmol, 2.0 equivalent) were added to a reaction bottle. Toluene (200 mL) was added. Reaction was carried out at 110° C. for 48 hours and then reaction was stopped, which was cooled to the room temperature. Organic phases were separated, concentrated and subjected to silica gel column chromatography to obtain 32.71 g of white solid, with a yield of 98%. The liquid was directly used in a next step without structural characterization.

Synthesis of intermediate (M1-OH); M1-OMe and hydrogen bromide (80.91 g, 990 mmol, 10.0 equivalent) were added to a reaction bottle. Reaction was carried out at 120° C. for 24 hours and then reaction was stopped, which was cooled to the room temperature. Organic phases were separated, concentrated and subjected to silica gel column chromatography to obtain 30.6 g of white solid, with a yield of 97%. The liquid was directly used in a next step without structural characterization.

Synthesis of intermediate (M1-Cl); M1-OH (5 g, 15.8 mmol, 1.0 equivalent), 3-chloro-5-bromo-tert-butylbenzene (4.3 g, 17.4 mmol, 1.1 equivalent), 2-pyridinecarboxylic acid (390 mg, 3.16 mmol, 20 mmol %), cuprous iodide (301 mg, 1.58 mmol, 10 mmol %) and potassium phosphate (522 mg, 2.46 mmol, 2.0 equivalent) and then dimethyl sulfoxide (50 mL) were added to a reaction bottle. Reaction was carried out at 100° C. for 12 hours and then reaction was stopped, which was cooled to the room temperature. Organic phases were separated, concentrated and subjected to silica gel column chromatography to obtain 6.94 g of white solid, with a yield of 91%.

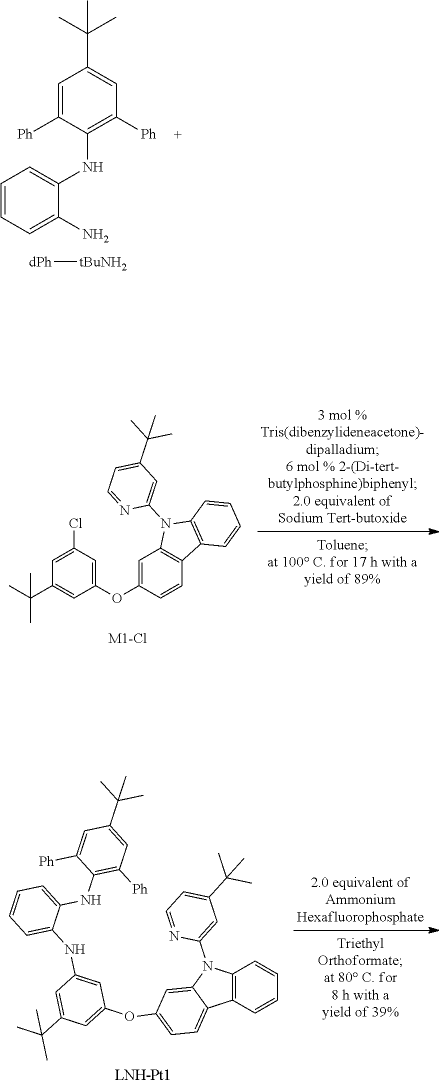

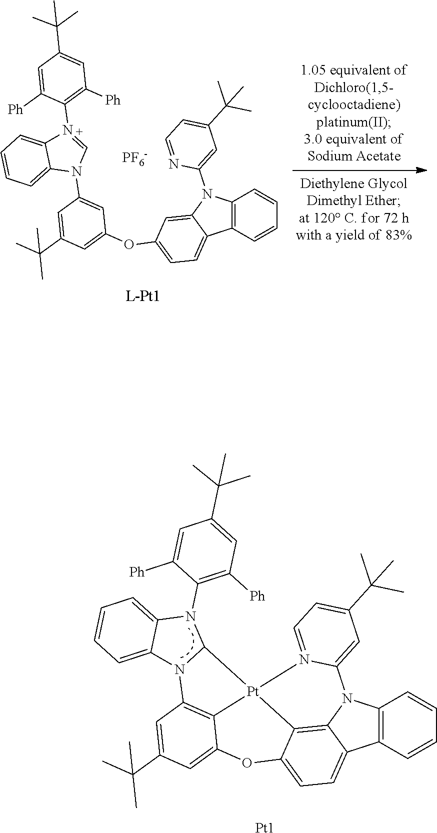

Synthesis of intermediate (LNH-Pt1); dPh-tBuNH₂ (400 mg, 1.02 mmol, 1.0 equivalent), M1-Cl (492 mg, 1.02 mmol, 1.0 equivalent), tris(dibenzylideneacetone)dipalladium (28 mg, 0.03 mmol, 3 mol %), 2-(di-tert-butylphosphine) biphenyl (19 mg, 0.06 mmol, 6 mol %) and sodium tert-butoxide (167 mg, 1.74 mmol, 2.0 equivalent) were added to a reaction bottle. Toluene (5 mL) was added. Reaction was carried out at 100° C. for 17 hours and then reaction was stopped, which was cooled to the room temperature. Organic phases were separated, concentrated and subjected to silica gel column chromatography to obtain 760 mg of white solid, with a yield of 89%. The liquid was directly used in a next step without structural characterization.

Synthesis of ligand (L-Pt1): LNH-Pt1(730 mg, 0.87 mmol, 1.0 equivalent), then ammonium hexafluorophosphate (284 mg, 1.74 mmol, 2.0 equivalent) and triethyl orthoformate (5 mL) were added to a reation bottle. Reaction was carried out at 80° C. for 8 hours and then reaction was stopped, which was cooled to the room temperature. Organic phases were separated, concentrated and subjected to silica gel column chromatography to obtain 320 mg of white solid, with a yield of 39%. ¹H NMR (500 MHz, CDCl₃) δ 1.27 (s, 9H), 1.29 (s, 9H), 1.43 (s, 9H), 6.81 (t, J=2.0 Hz, 1H), 6.95 (t, J=1.5 Hz, 1H), 7.08-7.13 (m, 6H), 7.13-7.16 (m, 5H), 7.34-7.35 (m, 1H), 7.45-7.49 (m, 5H), 7.51-7.57 (m, 2H), 7.65-7.69 (m, 2H), 7.72 (s, 2H), 7.76 (d, J=7.5 Hz, 1H), 8.27 (d, J=7.5 Hz, 1H), 8.35 (d, J=8.5 Hz, 1H), 8.58 (d, J=6.0 Hz, 1H), 10.24 (s, 1H).

Synthesis of Pt1: L-Pt1 (200 mg, 0.2 mmol, 1.0 equivalent), dichloro(1,5-cyclooctadiene)platinum(II) (79 mg, 0.21 mmol, 1.05 equivalent) and sodium acetate (50 mg, 0.60 mmol, 3.0 equivalent) and then diethylene glycol dimethyl ether (10 mL) were added to a reaction bottle. Reaction was carried out at 120° C. for 72 hours and then reaction was stopped, which was cooled to the room temperature, concentrated and subjected to silica gel column chromatography to obtain 172 mg of pale yellow solid, with a yield of 83%. ¹H NMR (500 MHz, DMSO) δ 1.22 (s, 9H), 1.41 (s, 9H), 1.42 (s, 9H), 6.51-6.68 (m, 3H), 6.85-7.23 (m, 9H), 7.31-7.69 (m, 9H), 7.82 (d, J=8.0 Hz, 1H), 7.91 (d, J=2.0 Hz, 1H), 8.04 (d, J=8.0 Hz, 1H), 8.12 (d, J=8.5 Hz, 1H), 8.19 (d, J=3.5 Hz, 1H), 8.93 (d, J=6.5 Hz, 1H).

### Embodiment 3 Synthetic Route of Pt2 is as Follows

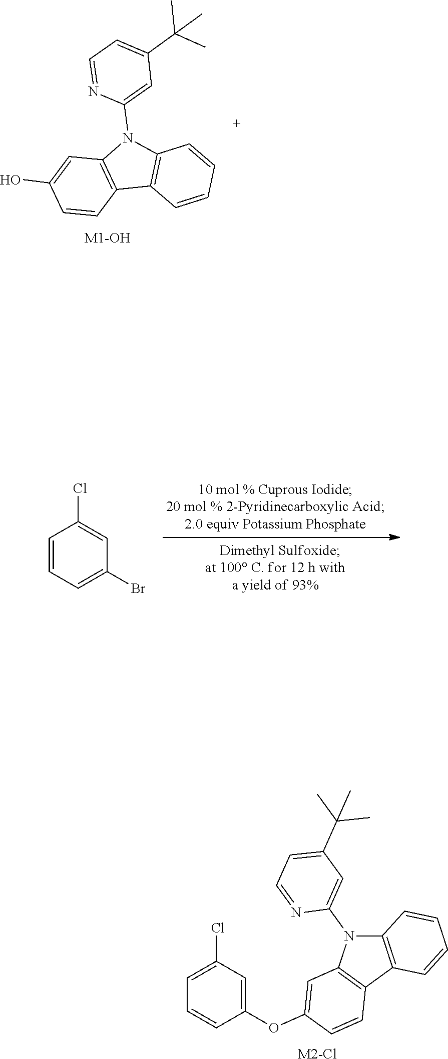

Synthesis of intermediate (M2-Cl); M1-OH (8.0 g, 25.3 mmol, 1.0 equivalent), 3-bromochlorobenzene (5.34 g, 27.8 mmol, 1.1 equivalent), 2-pyridinecarboxylic acid (623 mg, 5.06 mmol, 20 mmol %), cuprous iodide (481 mg, 2.53 mmol, 10 mmol %) and potassium phosphate (10.74 g, 50.6 mmol, 2.0 equivalent) and then dimethyl sulfoxide (80 mL) were added to a reaction bottle. Reaction was carried out at 100° C. for 12 hours and then reaction was stopped, which was cooled to the room temperature, concentrated and subjected to silica gel column chromatography to obtain 6.94 g of white solid, with a yield of 93%. The liquid was directly used in a next step without structural characterization.

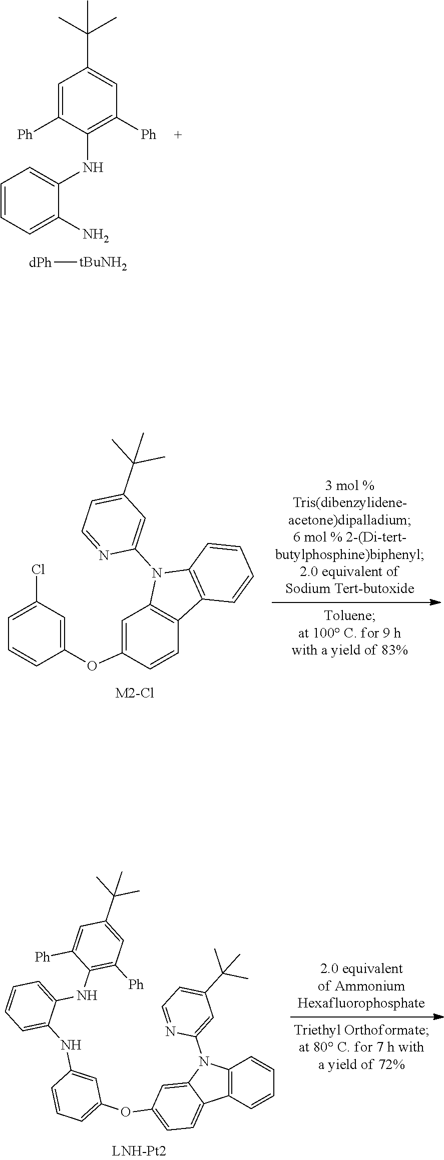

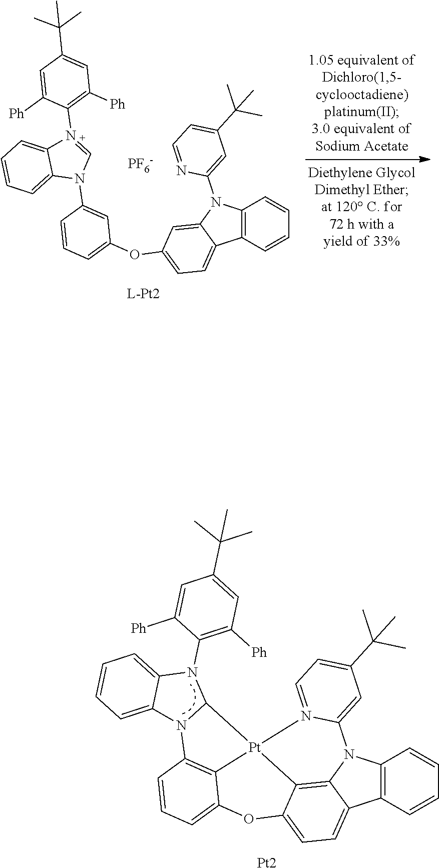

Synthesis of intermediate (LNH-Pt2); dPh-tBuNH₂ (5 g, 12.7 mmol, 1.0 equivalent), M2-Cl (5.43 mg, 12.7 mmol, 1.0 equivalent), tris(dibenzylideneacetone)dipalladium (349 mg, 0.38 mmol, 3 mol %), 2-(di-tert-butylphosphine) biphenyl (230 mg, 0.76 mmol, 6 mol %) and sodium tert-butoxide (2.44 g, 25.4 mmol, 2.0 equivalent) were added to a reaction bottle. Toluene (50 mL) was added. Reaction was carried out at 100° C. for 9 hours and then reaction was stopped, which was cooled to the room temperature. Organic phases were separated, concentrated and subjected to silica gel column chromatography to obtain 8.85 g of white solid, with a yield of 87%. The liquid was directly used in a next step without structural characterization.

Synthesis of ligand (L-Pt2): LNH-Pt2(4.19 g, 5.4 mmol, 1.0 equivalent), then ammonium hexafluorophosphate (1.76 g, 10.8 mmol, 2.0 equivalent) and triethyl orthoformate (20 mL) were added to a reation bottle. Reaction was carried out at 80° C. for 7 hours and then reaction was stopped, which was cooled to the room temperature. Organic phases were separated, concentrated and subjected to silica gel column chromatography to obtain 3.67 g of white solid, with a yield of 72%. ¹H NMR (500 MHz, DMSO) δ 1.30 (s, 9H), 1.45 (s, 9H), 6.98 (t, J=2.5 Hz, 1H), 7.11-7.19 (m, 12H), 7.36-7.42 (m, 2H), 7.47-7.59 (m, 6H), 7.69-7.79 (m, 6H), 8.29 (d, J=7.5 Hz, 1H), 8.37 (d, J=8.5 Hz, 1H), 8.60 (d, J=5.0 Hz, 1H), 10.27 (s, 1H).

Synthesis of Pt2: L-Pt2 (500 mg, 0.53 mmol, 1.0 equivalent), dichloro(1,5-cyclooctadiene)platinum(II) (194 mg, 0.56 mmol, 1.05 equivalent) and sodium acetate (130 mg, 1.59 mmol, 3.0 equivalent) and then diethylene glycol dimethyl ether (10 mL) were added to a reaction bottle. Reaction was carried out at 120° C. for 72 hours and then reaction was stopped, which was cooled to the room temperature, concentrated and subjected to silica gel column chromatography to obtain 173 mg of pale yellow solid, with a yield of 33%. ¹H NMR (500 MHz, CDCl₃) δ 1.20 (s, 9H), 1.41 (s, 9H), 6.29 (d, J=8.5 Hz, 1H), 6.35-7.19 (m, 11H), 7.21-7.25 (m, 2H), 7.31 (d, J=8.5 Hz, 2H), 7.39-7.65 (m, 6H), 7.80 (d, J=8.5 Hz, 1H), 7.89-7.92 (m, 2H), 7.99 (d, J=8.0 Hz, 1H), 8.12 (d, J=7.0 Hz, 1H), 9.09 (d, J=6.0 Hz, 1H).

### Embodiment 4 Synthetic Route of Pt3 is as Follows

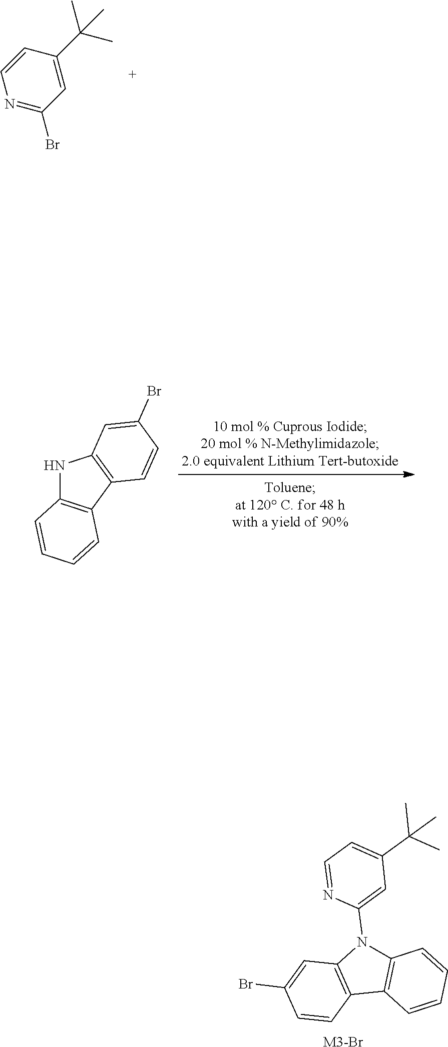

Synthesis of intermediate (M3-OH); 4-(tert-butyl)-2-bromopyridine (20.6 g, 46.7 mmol, 1.1 equivalent), 2-bromocarbazole (10.43 g, 42.4 mmol, 1.0 equivalent), cuprous iodide (807 mg, 4.24 mmol, 10 mmol %) and 1-methylimidazole (696 mg, 8.48 mmol, 2.0 equivalent) and lithium tert-butoxide (6.78 g, 84.8 mmol, 2.0 equivalent) were added to a reaction bottle. Toluene (80 mL) was added. Reaction was carried out at 120° C. for 48 hours and then reaction was stopped, which was cooled to the room temperature. Organic phases were separated, concentrated and subjected to silica gel column chromatography to obtain 14.5 g of white solid, with a yield of 90%. The liquid was directly used in a next step without structural characterization.

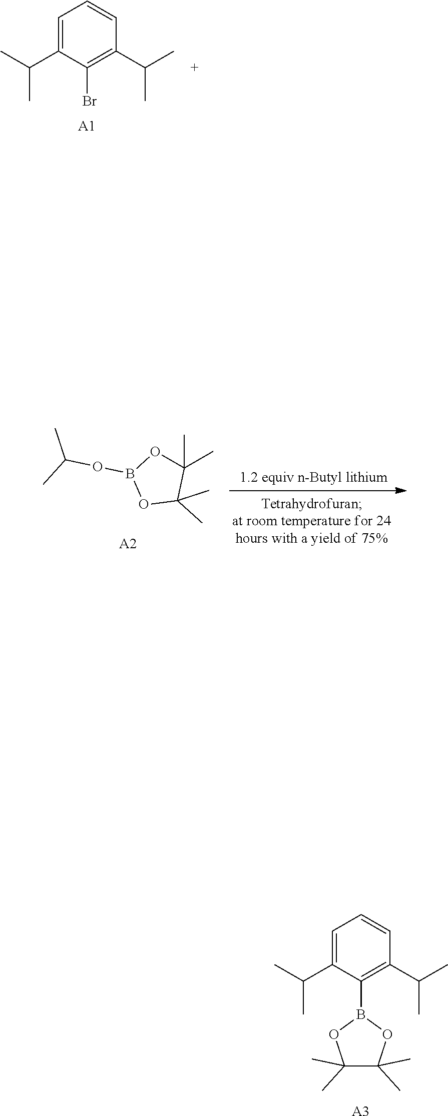

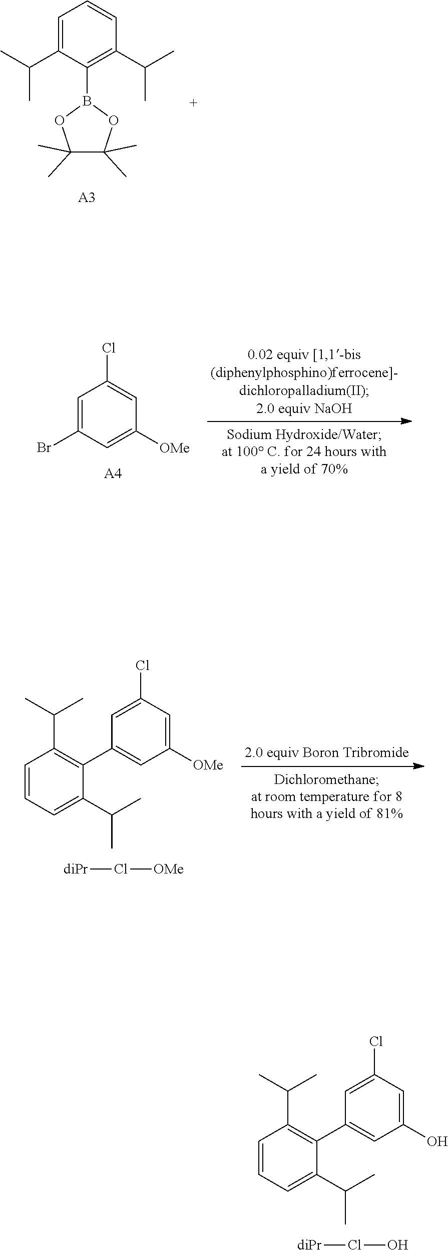

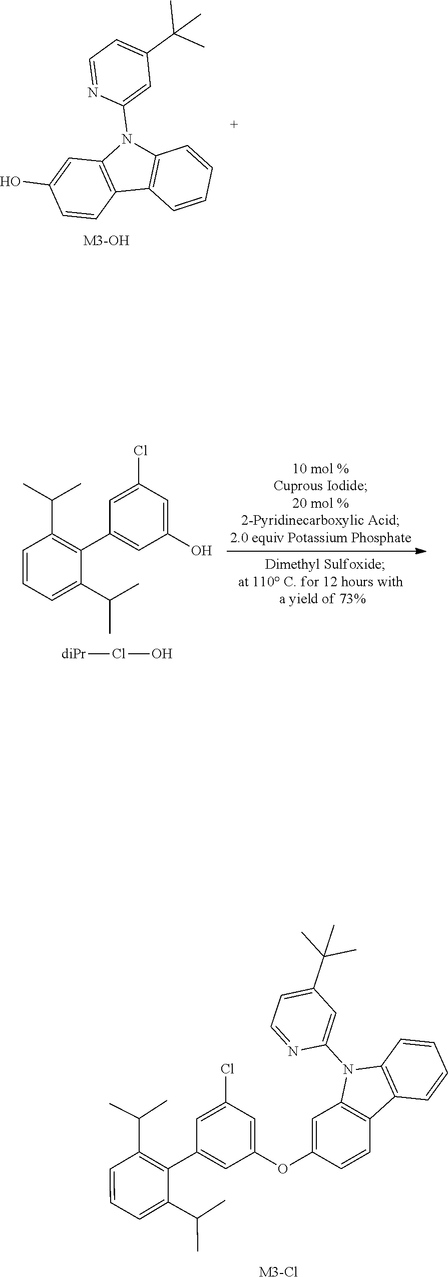

Synthesis of intermediate (A3); A1 (20 g, 82.9 mmol, 1.0 equivalent), A2 (24.7 g, 133 mmol, 1.6 equivalent), n-butyl lithium (40 mL, 99.48 mmol, 1.2 equivalent), 1-methylimidazole (696 mg, 8.48 mmol, 20 mol %) and lithium tert-butoxide (6.78 g, 84.8 mmol, 2.0 equivalent) were added to a reaction bottle. Tetrahydrofuran (200 mL) was added. Reaction was carried out at room temperature for 24 hours and then reaction was stopped, which was cooled to the room temperature. Organic phases were separated, concentrated and subjected to silica gel column chromatography to obtain 13.4 g of white solid A3, with a yield of 75%. The solid was directly used in a next step without structural characterization.

Synthesis of intermediate (diPr—Cl—OMe); A3(7.81 g, 27.1 mmol, 1.2 equivalent), A4 (5.0 g, 22.6 mmol, 1.0 equivalent), [1,1′-bis(diphenylphosphino)ferrocene]dichloropalladium(II) (330 mg, 0.45 mmol, 2 mol %) and sodium hydroxide (1.81 g, 45.2 mmol, 2.0 equivalent) were added to a reaction bottle. Dioxane (50 mL) and water (10 mL) were added. Reaction was carried out at 100° C. for 24 hours and then reaction was stopped, which was cooled to the room temperature. Organic phases were separated, concentrated and subjected to silica gel column chromatography to obtain 4.79 g of white solid diPr—Cl—OMe, with a yield of 70%. The solid was directly used in a next step without structural characterization.

Synthesis of intermediate (diPr—Cl—OH); diPr—Cl—OMe (6.93 g, 22.9 mmol, 1.0 equivalent) and boron tribromide (11.48 g, 45.8 mmol, 2.0 equivalent) were added to a reaction bottle. Dichloromethane (10 mL) was added. Reaction was carried out at room temperature for 8 hours and then reaction was stopped, which was cooled to the room temperature. Organic phases were separated, concentrated and subjected to silica gel column chromatography to obtain 4.5 g of white solid diPr—Cl—OH, with a yield of 81%. The solid was directly used in a next step without structural characterization.

Synthesis of intermediate (M3-Cl); diPr—Cl—OH (4.5 g, 15.6 mmol, 1.5 equivalent), M3-Br (3.94 g, 10.4 mmol, 1.0 equivalent), 2-pyridinecarboxylic acid (256 mg, 2.08 mmol, 20 mmol %), cuprous iodide (198 mg, 1.04 mmol, 10 mmol %) and potassium phosphate (4.42 g, 20.8 mmol, 2.0 equivalent) and then dimethyl sulfoxide (50 mL) were added to a reaction bottle. Reaction was carried out at 110° C. for 12 hours and then reaction was stopped, which was cooled to the room temperature. Organic phases were separated, concentrated and subjected to silica gel column chromatography to obtain 4.45 g of white solid M3-C1, with a yield of 73%. The solid was directly used in a next step without structural characterization.

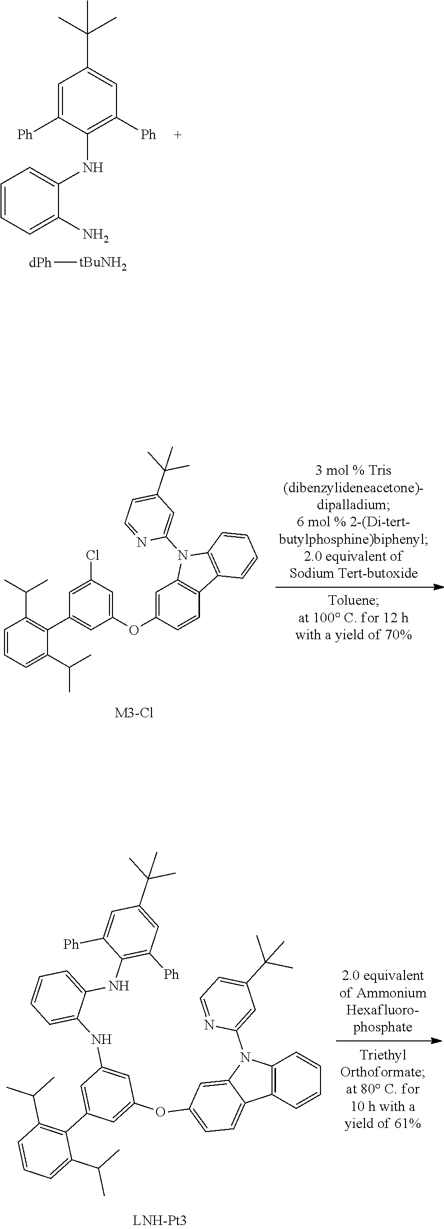

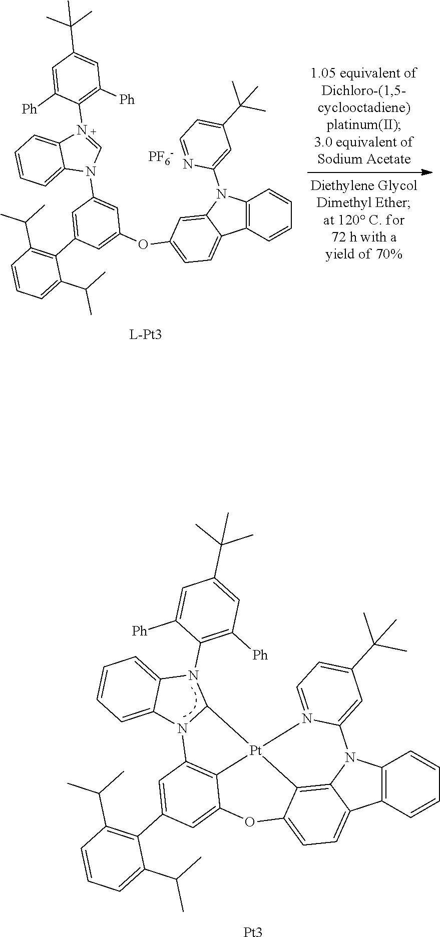

Synthesis of intermediate (LNH-Pt3); dPh-tBuNH₂ (5.5 g, 1.4 mmol, 1.0 equivalent), M3-Cl (8.22 mg, 14 mmol, 1.0 equivalent), tris(dibenzylideneacetone)dipalladium (384 mg, 0.42 mmol, 3 mol %), 2-(di-tert-butylphosphine) biphenyl (250 mg, 0.84 mmol, 6 mol %) and sodium tert-butoxide (2.7 g, 28 mmol, 2.0 equivalent) were added to a reaction bottle. Toluene (100 mL) was added. Reaction was carried out at 100° C. for 12 hours and then reaction was stopped, which was cooled to the room temperature. Organic phases were separated, concentrated and subjected to silica gel column chromatography to obtain 9.24 g of white solid, with a yield of 70%. The liquid was directly used in a next step without structural characterization.

Synthesis of ligand (L-Pt3): LNH-Pt3(13.6 g, 14.4 mmol, 1.0 equivalent), then ammonium hexafluorophosphate (4.7 g, 28.8 mmol, 2.0 equivalent) and triethyl orthoformate (50 mL) were added to a reation bottle. Reaction was carried out at 80° C. for 10 hours and then reaction was stopped, which was cooled to the room temperature. Organic phases were separated, concentrated and subjected to silica gel column chromatography to obtain 8.42 g of white solid, with a yield of 61%. ¹H NMR (500 MHz, DMSO) δ 0.87 (d, J=6.9 Hz, 6H), 1.06 (d, J=6.9 Hz, 6H), 1.28 (s, 9H), 1.44 (s, 9H), 2.39-2.45 (m, 2H), 7.02 (dd, J=2.5, 1.5 Hz, 1H), 7.04-7.07 (m, 2H), 7.10-7.14 (m, 4H), 7.18-7.23 (m, 8H), 7.32-7.36 (m, 2H), 7.42 (t, J=2.0 Hz, 1H), 7.43-7.46 (m, 2H), 7.48-7.50 (m, 2H), 7.53-7.57 (m, 1H), 7.59-7.62 (m, 1H), 7.69 (d, J=2.5 Hz, 1H), 7.73-7.76 (m, 4H), 8.25 (d, J=7.5 Hz, 1H), 8.34 (d, J=8.5 Hz, 1H), 8.55 (d, J=5.5 Hz, 1H), 10.28 (s, 1H).

Synthesis of Pt3: L-Pt3 (5.0 g, 4.5 mmol, 1.0 equivalent), dichloro(1,5-cyclooctadiene)platinum(II) (1.64 g, 4.72 mmol, 1.05 equivalent) and sodium acetate (1.11 g, 13.5 mmol, 3.0 equivalent) and then diethylene glycol dimethyl ether (50 mL) were added to a reaction bottle. Reaction was carried out at 120° C. for 72 hours and then reaction was stopped, which was cooled to the room temperature, concentrated and subjected to silica gel column chromatography to obtain 3.61 g of pale yellow solid Pt3, with a yield of 70%. The pale yellow solid was confirmed as product by NMR.

### Embodiment 5 Synthetic Route of Pt4 is as Follows

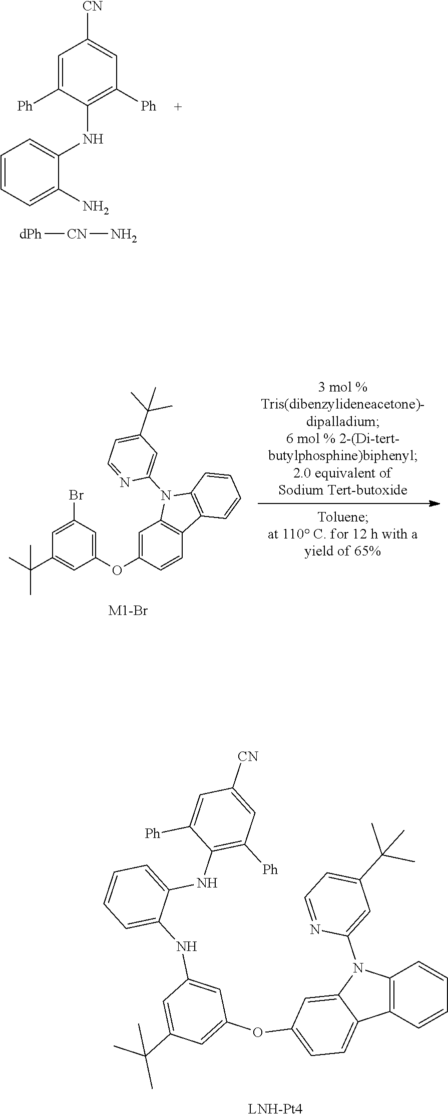

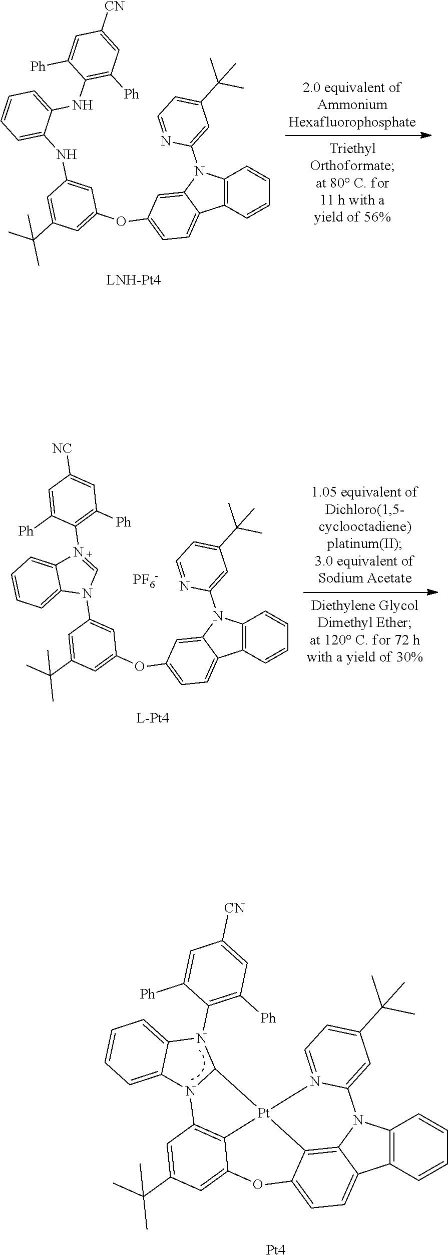

Synthesis of intermediate (LNH-Pt4); dPh-tBuNH₂ (500 mg, 1.38 mmol, 1.2 equivalent), M1-Br (861 mg, 1.38 mmol, 1.0 equivalent), tris(dibenzylideneacetone)dipalladium (37 mg, 0.04 mmol, 3 mol %), 2-(di-tert-butylphosphine) biphenyl (33 mg, 0.08 mmol, 6 mol %) and sodium tert-butoxide (265 mg, 2.76 mmol, 2.0 equivalent) were added to a reaction bottle. Toluene (5 mL) was added. Reaction was carried out at 110° C. for 12 hours and then reaction was stopped, which was cooled to the room temperature. Organic phases were separated, concentrated and subjected to silica gel column chromatography to obtain 726 mg of white solid, with a yield of 65%. The liquid was directly used in a next step without structural characterization.

Synthesis of ligand (L-Pt4): LNH-Pt4(726 mg, 0.90 mmol, 1.0 equivalent), then ammonium hexafluorophosphate (293 mg, 1.80 mmol, 2.0 equivalent) and triethyl orthoformate (5 mL) were added to a reation bottle. Reaction was carried out at 80° C. for 11 hours and then reaction was stopped, which was cooled to the room temperature. Organic phases were separated, concentrated and subjected to silica gel column chromatography to obtain 342 mg of white solid, with a yield of 56%. ¹H NMR (500 MHz, DMSO) δ 1.28 (s, 9H), 1.30 (s, 9H), 6.85 (t, J=2.0 Hz, 1H), 6.93 (t, J=2.0 Hz, 1H), 7.14-7.19 (m, 11H), 7.36 (t, J=8.0 Hz, 1H), 7.46-7.49 (m, 4H), 7.54-7.58 (m, 3H), 7.66-7.70 (m, 2H), 7.75 (d, J=9.0 Hz, 1H), 8.27 (d, J=8.0 Hz, 1H), 8.34-8.36 (m, 3H), 8.58 (d, J=6.0 Hz, 1H), 10.31 (s, 1H).

Synthesis of Pt4: L-Pt4 (150 mg, 0.16 mmol, 1.0 equivalent), dichloro(1,5-cyclooctadiene)platinum(II) (59 mg, 0.17 mmol, 1.05 equivalent) and sodium acetate (40 mg, 0.48 mmol, 3.0 equivalent) and then diethylene glycol dimethyl ether (10 mL) were added to a reaction bottle. Reaction was carried out at 120° C. for 72 hours and then reaction was stopped, which was cooled to the room temperature, concentrated and subjected to silica gel column chromatography to obtain 96 mg of pale yellow solid, with a yield of 60%. ¹H NMR (500 MHz, DMSO) δ 1.34 (s, 9H), 1.42 (s, 9H), 5.99-6.83 (m, 6H), 6.87-7.70 (m, 14H), 7.80 (d, J=8.2 Hz, 1H), 8.08 (d, J=2.0 Hz, 1H), 8.12-8.34 (m, 3H), 8.40 (d, J=8.0 Hz, 1H), 8.80 (d, J=6.0 Hz, 1H).

### Embodiment 6 Synthetic Route of Pt5 is as Follows

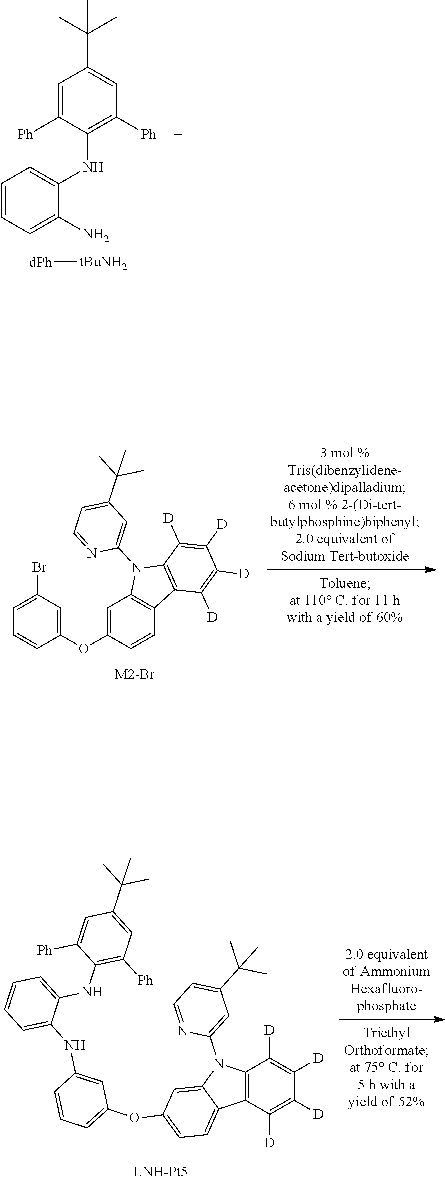

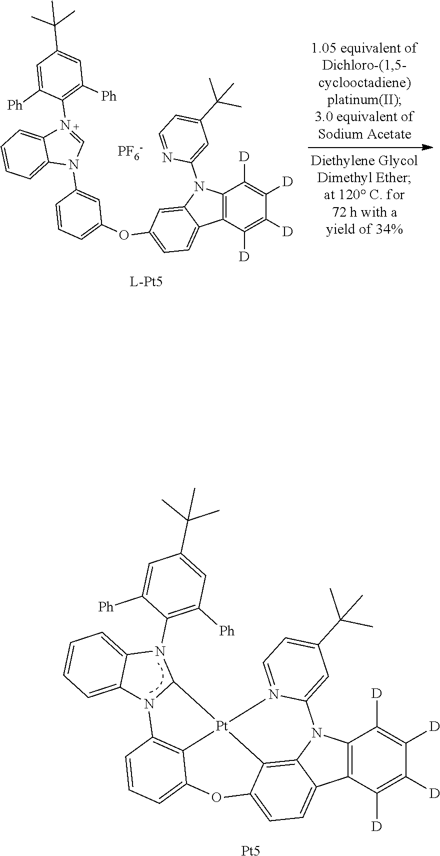

Synthesis of intermediate (LNH-Pt5); dPh-tBuNH₂ (5.0 g, 12.7 mmol, 1.2 equivalent), M2-Br (6.0 g, 12.7 mmol, 1.0 equivalent), tris(dibenzylideneacetone)dipalladium (349 mg, 0.40 mmol, 3 mol %), 2-(di-tert-butylphosphine) biphenyl (230 mg, 0.80 mmol, 6 mol %) and sodium tert-butoxide (2.44 mg, 25.4 mmol, 2.0 equivalent) were added to a reaction bottle. Toluene (5 mL) was added. Reaction was carried out at 110° C. for 11 hours and then reaction was stopped, which was cooled to the room temperature. Organic phases were separated, concentrated and subjected to silica gel column chromatography to obtain 5.97 g of white solid, with a yield of 60%. The liquid was directly used in a next step without structural characterization.

Synthesis of ligand (L-Pt5): LNH-Pt5(7.84 g, 10.0 mmol, 1.0 equivalent), then ammonium hexafluorophosphate (3.26 mg, 20.0 mmol, 2.0 equivalent) and triethyl orthoformate (20 mL) were added to a reation bottle. Reaction was carried out at 75° C. for 5 hours and then reaction was stopped, which was cooled to the room temperature. Organic phases were separated, concentrated and subjected to silica gel column chromatography to obtain 3.08 mg of white solid, with a yield of 52%. ¹H NMR (500 MHz, DMSO) δ 1.30 (s, 9H), 1.45 (s, 9H), 6.97 (t, J=2.0 Hz, 1H), 7.10-7.19 (m, 13H), 7.41 (dd, J=8.5, 3.5 Hz, 1H), 7.46-7.51 (m, 3H), 7.52-7.59 (m, 2H), 7.67-7.71 (m, 2H), 7.72-7.74 (m, 3H), 8.37 (d, J=8.5 Hz, 1H), 8.59 (d, J=4.5 Hz, 1H), 10.26 (s, 1H).

Synthesis of Pt5: L-Pt5 (5.64 g, 6.0 mmol, 1.0 equivalent), dichloro(1,5-cyclooctadiene)platinum(II) (1.96 g, 6.3 mmol, 1.05 equivalent) and sodium acetate (1.48 mg, 18 mmol, 3.0 equivalent) and then diethylene glycol dimethyl ether (10 mL) were added to a reaction bottle. Reaction was carried out at 120° C. for 72 hours and then reaction was stopped, which was cooled to the room temperature, concentrated and subjected to silica gel column chromatography to obtain 1.30 g of pale yellow solid, with a yield of 34%. ¹H NMR (500 MHz, CDCl₃) δ 1.20 (s, 9H), 1.41 (s, 9H), 6.19-7.18 (m, 15H), 7.22-7.24 (m, 2H), 7.31 (d, J=8.5 Hz, 1H), 7.48 (d, J=8.5 Hz, 2H), 7.80 (d, J=8.0 Hz, 1H), 7.92 (d, J=2.0 Hz, 1H), 7.99 (d, J=8.5 Hz, 1H), 9.09 (d, J=6.0 Hz, 1H).

### Embodiment 7: Synthesis of Pt6

Referring to synthesis steps and reaction conditions of compound Pt1, Pt6 was synthesized. A target product was 562 mg of yellow solid with a yield of 75% and a molecular weight [M+H]⁺ of 994.1.

### Embodiment 8: Synthesis of Pt7

Referring to synthesis steps and reaction conditions of compound Pt1, Pt7 was synthesized. A target product was 624 mg of yellow solid with a yield of 58% and a molecular weight [M+H]⁺ of 1212.5.

### Embodiment 9: Synthesis of Pt8

Referring to synthesis steps and reaction conditions of compound Pt1, Pt8 was synthesized. A target product was 661 mg of yellow solid with a yield of 72% and a molecular weight [M+H]⁺ of 1216.5.

### Embodiment 10: Synthesis of Pt9

Referring to synthesis steps and reaction conditions of compound Pt1, Pt9 was synthesized. A target product was 484 mg of yellow solid with a yield of 66% and a molecular weight [M+H]⁺ of 1218.5.

### Embodiment 11: Synthesis of Pt10

Referring to synthesis steps and reaction conditions of compound Pt1, Pt10 was synthesized. A target product was 455 mg of yellow solid with a yield of 69% and a molecular weight [M+H]⁺ of 1219.5.

### Embodiment 12: Synthesis of Pt11

Referring to synthesis steps and reaction conditions of compound Pt1, Pt11 was synthesized. A target product was 410 mg of yellow solid with a yield of 67% and a molecular weight [M+H]⁺ of 1045.2.

### Embodiment 13: Synthesis of Pt12

Referring to synthesis steps and reaction conditions of compound Pt1, Pt12 was synthesized. A target product was 369 mg of yellow solid with a yield of 58% and a molecular weight [M+H]⁺ of 989.1.

### Embodiment 14: Synthesis of Pt13

Referring to synthesis steps and reaction conditions of compound Pt1, Pt13 was synthesized. A target product was 492 mg of yellow solid with a yield of 82% and a molecular weight [M+H]⁺ of 1149.4.

### Embodiment 15: Synthesis of Pt14

Referring to synthesis steps and reaction conditions of compound Pt1, Pt14 was synthesized. A target product was 471 mg of yellow solid with a yield of 80% and a molecular weight [M+H]⁺ of 1006.1.

### Embodiment 16: Synthesis of Pt15

Referring to synthesis steps and reaction conditions of compound Pt1, Pt15 was synthesized. A target product was 596 mg of yellow solid with a yield of 74% and a molecular weight [M+H]⁺ of 993.1.

### Embodiment 17: Synthesis of Pt16

Referring to synthesis steps and reaction conditions of compound Pt1, Pt16 was synthesized. A target product was 615 mg of yellow solid with a yield of 68% and a molecular weight [M+H]⁺ of 995.1.

### Embodiment 18: Synthesis of Pt17

Referring to synthesis steps and reaction conditions of compound Pt1, Pt17 was synthesized. A target product was 582 mg of yellow solid with a yield of 66% and a molecular weight [M+H]⁺ of 1213.5.

### Embodiment 19: Synthesis of Pt18

Referring to synthesis steps and reaction conditions of compound Pt1, Pt18 was synthesized. A target product was 471 mg of yellow solid with a yield of 76% and a molecular weight [M+H]⁺ of 1217.6.

### Embodiment 20: Synthesis of Pt19

Referring to synthesis steps and reaction conditions of compound Pt1, Pt19 was synthesized. A target product was 596 mg of yellow solid with a yield of 78% and a molecular weight [M+H]⁺ of 1218.6.

### Embodiment 21: Synthesis of Pt20

Referring to synthesis steps and reaction conditions of compound Pt1, Pt20 was synthesized. A target product was 597 mg of yellow solid with a yield of 72% and a molecular weight [M+H]⁺ of 1275.7.

### Embodiment 22: Synthesis of Pt21

Referring to synthesis steps and reaction conditions of compound Pt1, Pt21 was synthesized. A target product was 576 mg of yellow solid with a yield of 74% and a molecular weight [M+H]⁺ of 1010.1.

### Embodiment 23: Synthesis of Pt22

Referring to synthesis steps and reaction conditions of compound Pt1, Pt22 was synthesized. A target product was 615 mg of yellow solid with a yield of 68% and a molecular weight [M+H]⁺ of 1228.6.

### Embodiment 24: Synthesis of Pt23

Referring to synthesis steps and reaction conditions of compound Pt1, Pt23 was synthesized. A target product was 592 mg of yellow solid with a yield of 66% and a molecular weight [M+H]⁺ of 1232.6.

### Embodiment 25: Synthesis of Pt24

Referring to synthesis steps and reaction conditions of compound Pt1, Pt24 was synthesized. A target product was 571 mg of yellow solid with a yield of 76% and a molecular weight [M+H]⁺ of 1234.6.

### Embodiment 26: Synthesis of Pt25

Referring to synthesis steps and reaction conditions of compound Pt1, Pt25 was synthesized. A target product was 596 mg of yellow solid with a yield of 78% and a molecular weight [M+H]⁺ of 1235.6.

### Embodiment 27: Synthesis of Pt26

Referring to synthesis steps and reaction conditions of compound Pt1, Pt26 was synthesized. A target product was 597 mg of yellow solid with a yield of 72% and a molecular weight [M+H]⁺ of 1003.1.

### Embodiment 28: Synthesis of Pt27

Referring to synthesis steps and reaction conditions of compound Pt1, Pt27 was synthesized. A target product was 696 mg of yellow solid with a yield of 74% and a molecular weight [M+H]⁺ of 1005.1.

### Embodiment 29: Synthesis of Pt28

Referring to synthesis steps and reaction conditions of compound Pt1, Pt28 was synthesized. A target product was 615 mg of yellow solid with a yield of 68% and a molecular weight [M+H]⁺ of 1061.3.

### Embodiment 30: Synthesis of Pt34

Referring to synthesis steps and reaction conditions of compound Pt1, Pt34 was synthesized. A target product was 582 mg of yellow solid with a yield of 66% and a molecular weight [M+H]⁺ of 1025.4.

### Embodiment 31: Synthesis of Pt39

Referring to synthesis steps and reaction conditions of compound Pt1, Pt39 was synthesized. A target product was 471 mg of yellow solid with a yield of 76% and a molecular weight [M+H]⁺ of 1235.6.

### Photophysical Properties:

TABLE 1
Photophysical property data of part of metal complexes
in dichloromethane solution

| Complex | Maximum emission wavelength | Half width |
|---|---|---|
| Pt1 | 461 nm | 25 nm |
| Pt7 | 455.6 nm | 20 nm |
| Pt13 | 461.6 nm | 22.8 nm |
| Pt19 | 479.6 nm | 34.2 nm |
| Pt23 | 456 nm | 21.2 nm |

As can be seen from Table 1, the metal complexes according to the disclosure are all in blue light and dark blue light emitting regions, and have narrow half-peak widths, which shows that they are good blue phosphorescent materials.

### Manufacturing of OLED Devices:

As a reference preparation method of an embodiment of a device, in this disclosure, a hole injection layer (HIL) of 5 to 100 nm and a hole transport layer (HTL) of 5 to 200 nm were formed by evaporating a p-doped material on a surface or anode of ITO glass with a light-emitting area of 2 mm×2 mm or by co-evaporating a p-doped material with a hole injection material at a concentration of 1% to 50%, and then a light-emitting layer (EML) (which may contain the compound according to the disclosure) of 10 to 100 nm was formed on the hole transport layer. An electron transport layer (ETL) with a thickness of 20 to 200 nm and a cathode with a thickness of 50 to 200 nm were formed; an electron blocking layer (EBL) was added between the HTL and the EML layer, and an Electron Injection Layer (EIL) is added between the ETL and the cathode ifnecessary, so as to fabricate an OLED device. Then the OLED device is tested with a standard method. Unless otherwise specified, device materials involved in the present disclosure can be obtained by known synthesis methods.

In a preferred embodiment, a structure of Device Example 1 according to the disclosure is ITO/P-4 (10 nm)/NPD (60 nm)/HTH-85 (5 nm)/platinum (II) complex: HTH-85: ETH-45 (25 nm) (with a mass ratio of Pt1: HTH-85: ETH-45 of 10:60:30)/ETH-5 (5 nm)/ET-14 (40 nm)/LiQ (1 nm)/A1 (100 nm).

Device Example 2 to Device Example 30 and Comparative Example 1 were prepared by using a structure similar to that of Device Example 1, with only difference in that Pt1 in Device Example 1 was replaced with Pt2, Pt3, Pt4, Pt5, Pt-6, Pt7, Pt8, Pt9, Pt10, Pt11, Pt12, Pt13, Pt14, Pt15, Pt16, Pt17, Pt18, Pt19, Pt20, Pt21, Pt22, Pt23, Pt24, Pt25, Pt26, Pt27, Pt28, Pt34, Pt39 and R1 respectively. Luminescent characteristics of Comparative Examples and each Device Example prepared above were tested by standard methods, with data shown in Table 2. Structures of the devices involved are as follows in which P-4 indicates HATCN and ET-14 indicates BPyTP.

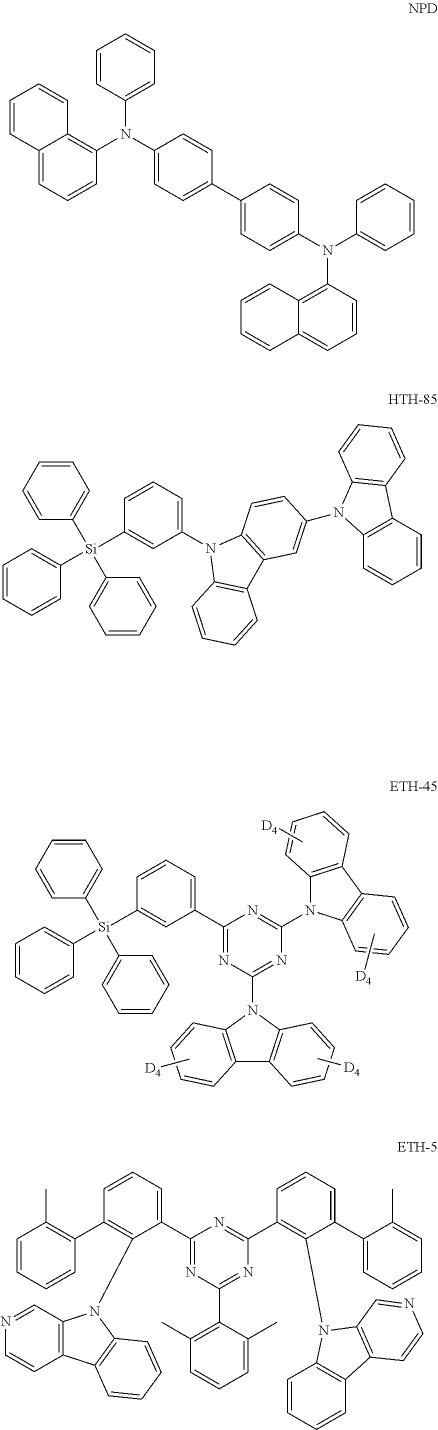

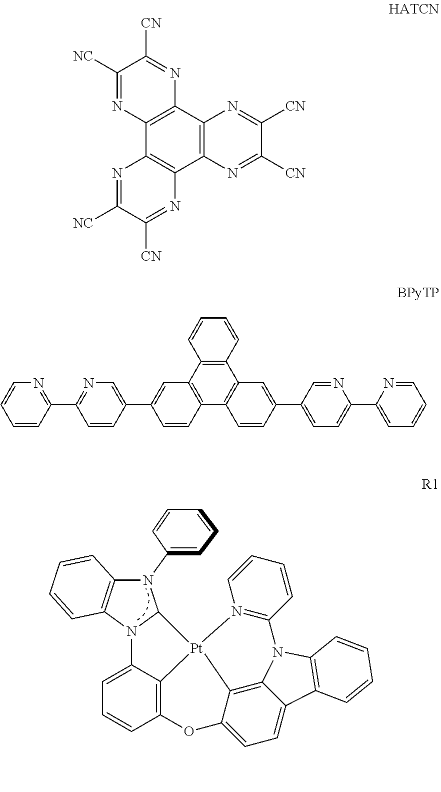

TABLE 2
Data sheet of luminescence characteristics of devices

| | Driving | Current | |
|---|---|---|---|
| | voltage | efficiency | Service |
| | (volt) | (cd/A) | life (h) |
| | @10 mA/cm² | @1000 cd/m² | @1000 cd/m² |
| | (Relative | (Relative | (Relative |
| Examples | value, %) | value, %) | value, %) |
| Comparative | 100 | 100 | 100 |
| Example 1 | | | |
| Device Example 1 | 95 | 131 | 130 |
| Device Example 2 | 96 | 124 | 139 |
| Device Example 3 | 97 | 130 | 144 |
| Device Example 4 | 96 | 131 | 148 |
| Device Example 5 | 97 | 126 | 150 |
| Device Example 6 | 96 | 131 | 146 |
| Device Example 7 | 95 | 129 | 149 |
| Device Example 8 | 97 | 128 | 144 |
| Device Example 9 | 95 | 135 | 152 |
| Device Example 10 | 97 | 134 | 150 |
| Device Example 11 | 94 | 128 | 141 |
| Device Example 12 | 96 | 126 | 133 |
| Device Example 13 | 95 | 128 | 135 |
| Device Example 14 | 95 | 132 | 142 |
| Device Example 15 | 97 | 137 | 148 |
| Device Example 16 | 96 | 125 | 144 |
| Device Example 17 | 97 | 131 | 148 |
| Device Example 18 | 96 | 129 | 151 |
| Device Example 19 | 95 | 132 | 146 |
| Device Example 20 | 97 | 134 | 135 |
| Device Example 21 | 96 | 135 | 142 |
| Device Example 22 | 97 | 129 | 138 |
| Device Example 23 | 95 | 130 | 140 |
| Device Example 24 | 97 | 129 | 147 |
| Device Example 25 | 96 | 134 | 149 |
| Device Example 26 | 97 | 131 | 133 |
| Device Example 27 | 96 | 129 | 140 |
| Device Example 28 | 95 | 132 | 143 |
| Device Example 29 | 97 | 131 | 139 |
| Device Example 30 | 96 | 129 | 146 |

It can be seen from Table 2 that, compared with Comparative Example 1, Device Example 1 to Device Example 30 prepared in this disclosure show good device performance in driving voltage, current efficiency and service life. Performance improvement of respective device examples is based on a fact that a specific compound material according to the disclosure has belier electron transport ability. Therefore, it can be seen that the electronic device with the compound material as a light-emitting layer material has higher current efficiency and longer service life as well as with a reduced driving voltage. In addition, devices prepared in the disclosure are all dark blue devices, with all of CIEy values less than 0.20. It shows that the compound according to the disclosure has certain commercial application value.

In a preferred embodiment, a structure of Device Example 31 according to the disclosure is ITO/P-4 (10 nm)/NPD (60 nm)/HTH-85 (5 nm)/platinum (11) complex:boron-containing compound:HTH-85:ETH-45 (25 nm) (with a mass ratio of Pt1:BN1-8:HTH-85:ETH-45 of 10:1:59:30)/ETH-5 (5 nm)/ET-14 (40 nm)/LiQ (1 nm)/A1 (100 nm).

Device Example 32 to Device Example 38 were prepared by using structures similar to that of Device Example 31, with only difference in that the platinum (II) complex and boron-containing compound in Device Example 23 were replaced with compounds listed in Table 3. Device structures and luminous characteristics are shown in Table 3.

TABLE 3
Data sheet of device structure and luminescence characteristics

| | | Driving | Current | |
|---|---|---|---|---|
| | Platinum (II) | voltage | efficiency | Service |
| | Complex: | (volt) | (cd/A) | life (h) |
| | boron- | @10 mA/cm² | @1000 cd/m² | @1000 cd/m² |
| | containing | (Relative | (Relative | (Relative |
| Examples | compound | value, %) | value, %) | value, %) |
| Comparative | R1 | 100 | 100 | 100 |
| Example 1 | | | | |
| Device | Pt1: BN1-8 | 95 | 123 | 130 |
| Example 31 | | | | |
| Device | Pt2: BN1-23 | 96 | 127 | 140 |
| Example 32 | | | | |
| Device | Pt-3: BN2-1 | 95 | 123 | 139 |
| Example 33 | | | | |
| Device | Pt4: BN2-26 | 97 | 121 | 145 |
| Example 34 | | | | |
| Device | Pt5: BN2-63 | 97 | 125 | 145 |
| Example 35 | | | | |
| Device | Pt25: BN2-80 | 95 | 127 | 147 |
| Example 36 | | | | |
| Device | Pt34: BN3-1 | 95 | 128 | 138 |
| Example 37 | | | | |
| Device | Pt39: BN3-10 | 96 | 125 | 139 |
| Example 38 | | | | |

It can be seen from Table 3 that when the compound according to the present disclosure was used as a sensitizing material and applied as a luminescent material together with the boron-containing compound in the devices, performance of respective devices was also significantly improved. It further shows that the compound according to the disclosure has certain commercial application value. In addition, the structure of the device is sensitized by adding the boron-containing compound, which can further reduce a CIEy value and further improve purity of the luminescent color of the device.

It is declared that the above is only specific implementations of the present disclosure, but the protection scope of the present disclosure is not limited to this. It should be clear to those skilled in the art that any change or substitution that can easily occur to those skilled in the art within the technical scope disclosed by the present application should within the protection scope of the present disclosure.

What is claimed:

1. A tetradentate cyclometalated platinum (II) complex, wherein the tetradentate cyclometalated platinum (II) complex is selected from ones with any one of the following chemical structures, wherein “D” represents deuterium and “Ph” represents a phenyl group:

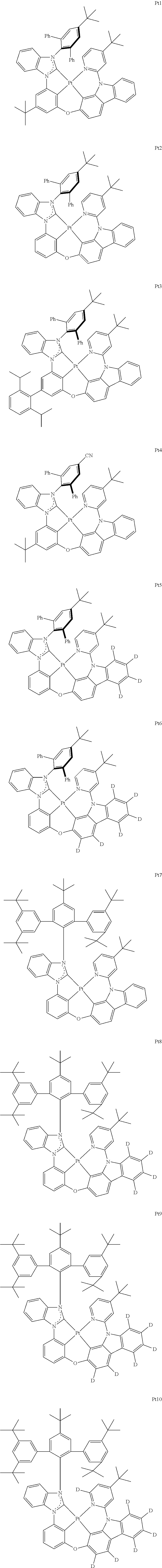

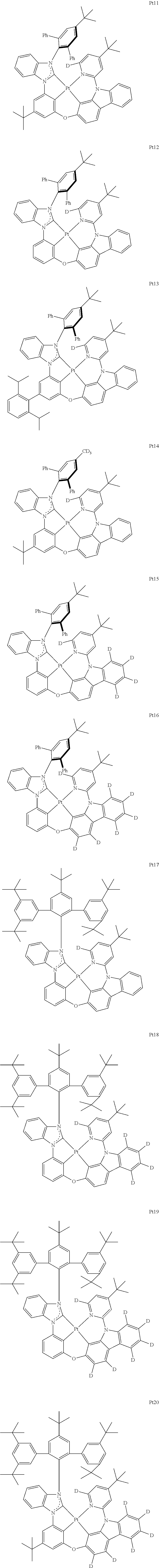

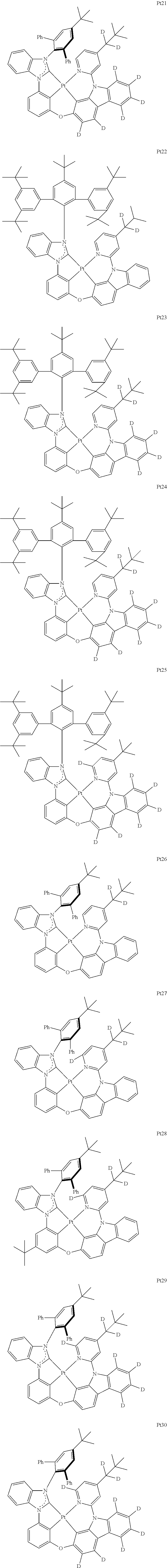

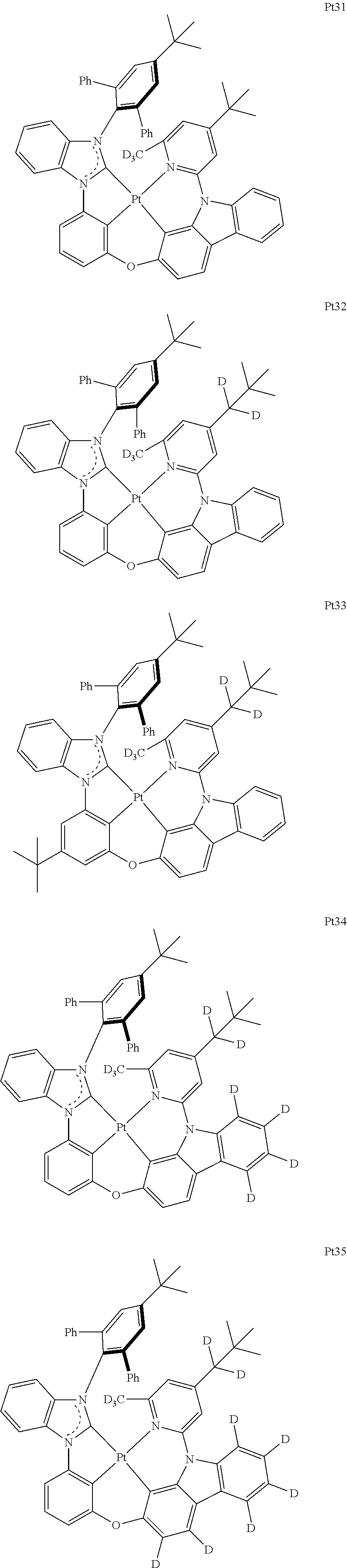

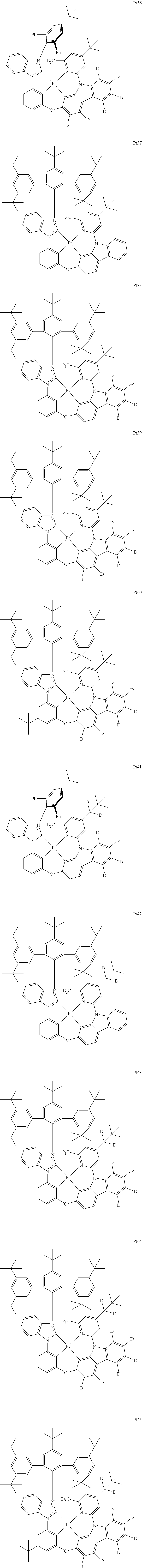

2. An electronic device, comprising the tetradentate cyclometalated platinum (II) complex according to claim 1.

3. The electronic device according to claim 2, wherein the electronic device comprises an organic light-emitting device, an organic integrated circuit, an organic field effect transistor, an organic thin film transistor, an organic light emitting transistor, an organic solar cell, an organic optical detector, an organic field quenching device, a light-emitting electrochemical cell and an organic laser diode.

4. An organic light-emitting device, comprising a cathode, an anode, and an organic functional layer therebetween, wherein the organic functional layer comprises the tetradentate cyclometalated platinum (II) complex according to claim 1.

5. An organic light-emitting device, comprising a light-emitting layer, wherein the light-emitting layer comprises the tetradentate cyclometalated platinum (II) complex according to claim 1.

6. The organic light-emitting device according to claim 5, wherein the light-emitting layer further comprises a fluorescent doping material, the fluorescent doping material being selected from any one or more compound represented by formulas (BN1) to (BN5): 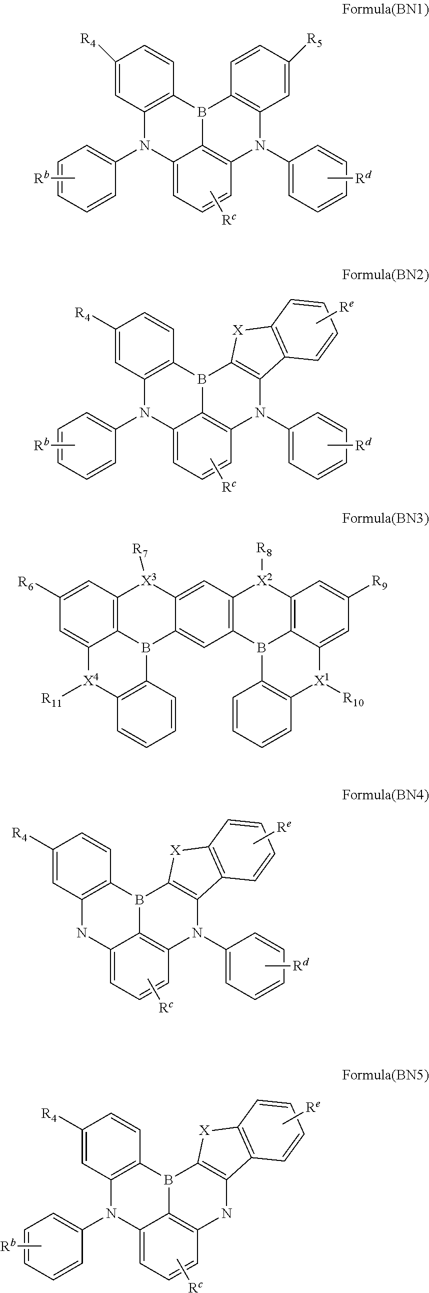
wherein X is O, S, Se or NR³⁰⁰;
X¹, X², X³, X^{4r} each independently represent O, S, Se or N; and
R^{b} to R^{e} are each independently represented as monosubstituted, disubstituted, trisubstituted, tetrasubstituted or unsubstituted; R^{b} to R^{e} are independently selected from a group consisting of hydrogen, deuterium, N, C1-C30 alkyl and C6-C60 aryl; R₄ to R₁₁ are each independently selected from a group consisting of a group consisting of hydrogen, deuterium, n, C1-C30 alkyl and C6-C60 aryl.

7. The organic light-emitting device according to claim 6, wherein R₄ to R₆ and R₉ are independently selected from substituted or unsubstituted diphenylamine groups, or substituted or unsubstituted carbazole groups; substitution can be multiple substitutions, and when a substituent is contained, the substituent is selected from deuterium, C1-C30 alkyl, and C6-C30 aryl.

8. The organic light-emitting device according to claim 6, wherein R₇ to R₈ and R₁₀ to R₁₁ are independently selected from a group consisting of hydrogen, C1-C30 alkyl and C6-C60 aryl.

9. The organic light-emitting device according to claim 6, wherein the fluorescent doping material is selected from any one of following chemical structures, wherein Ph represents a phenyl group, and D4 and D5 respectively refers to be substituted by 4 and 5 deuterium atoms:

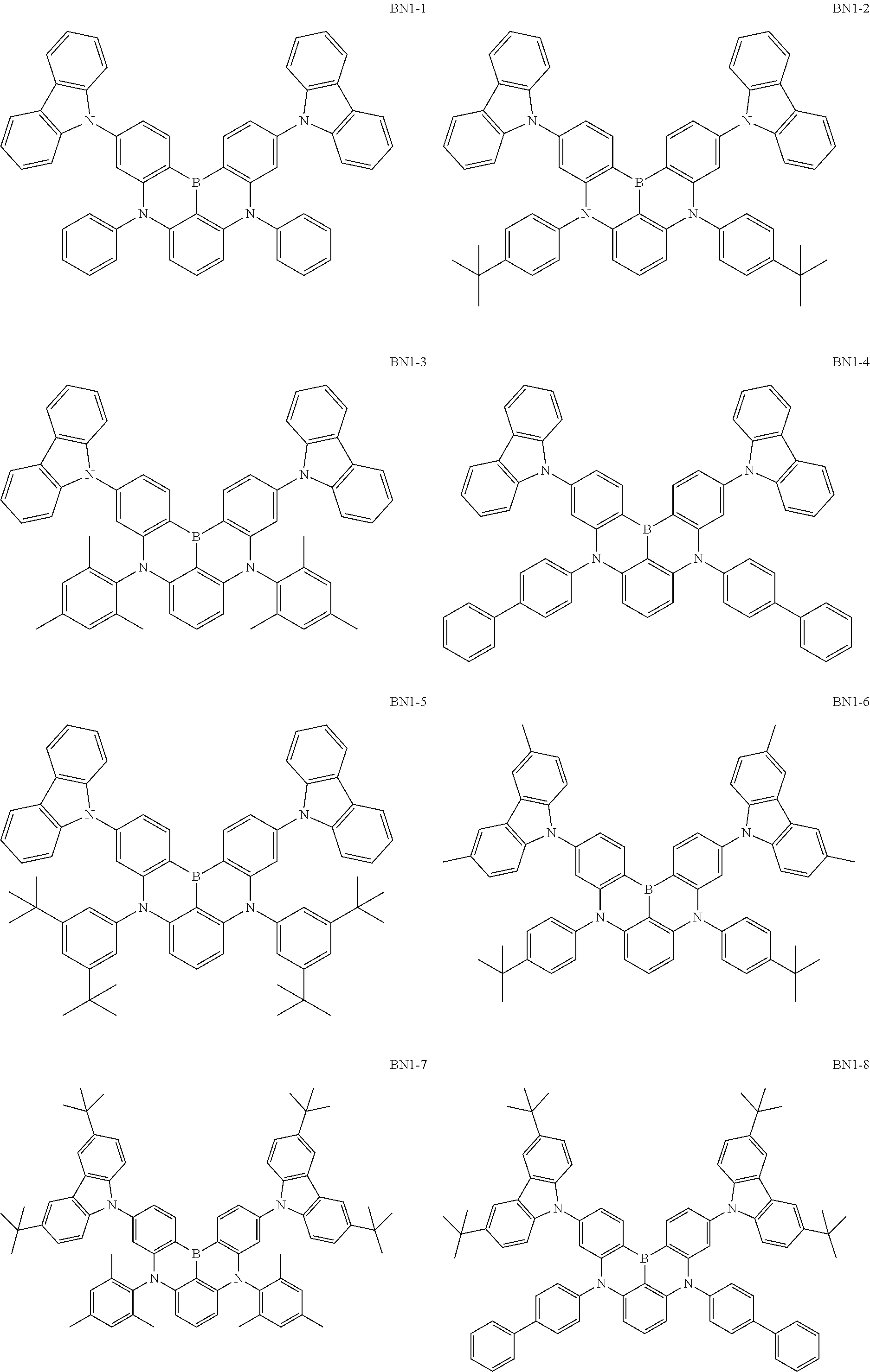

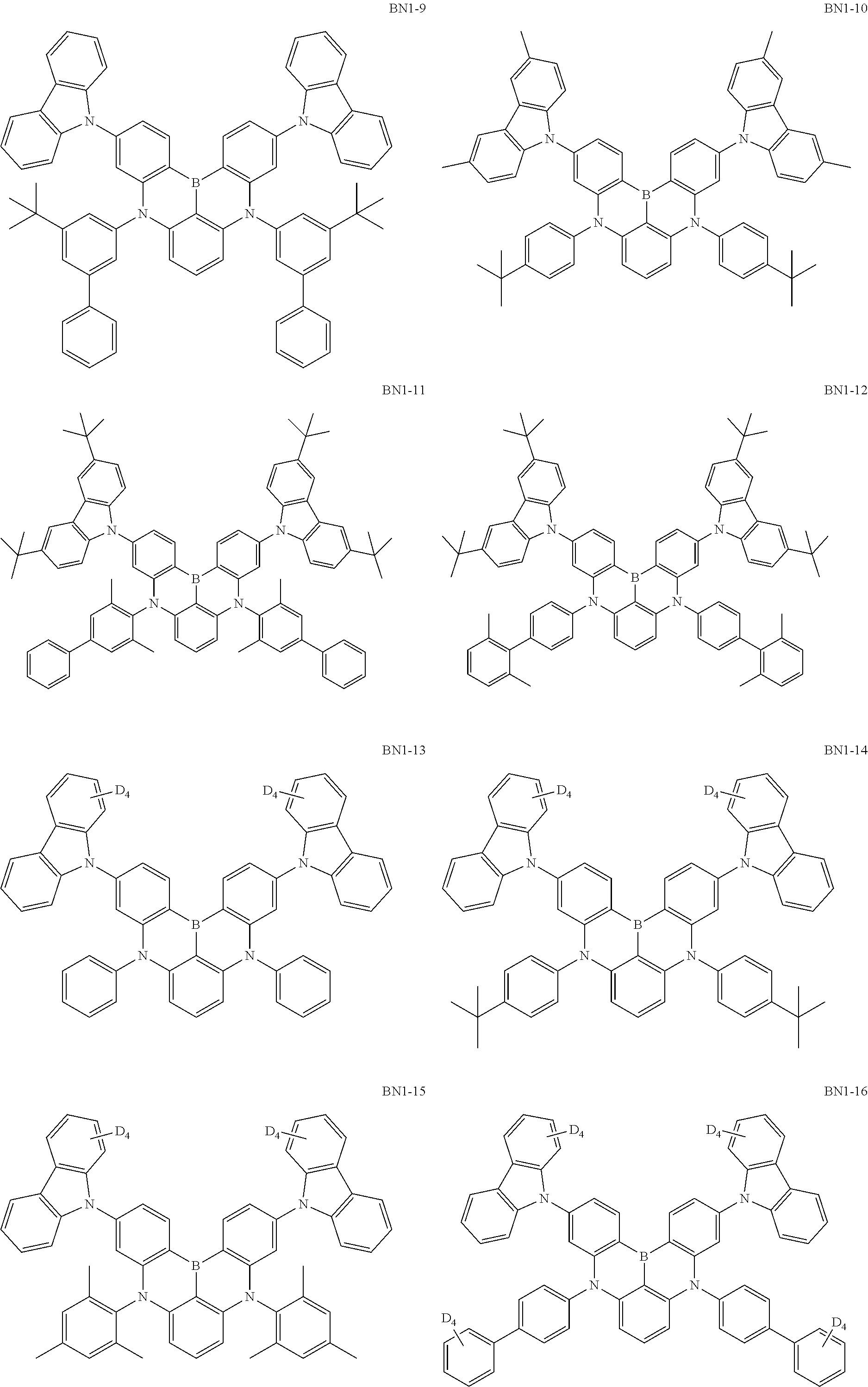

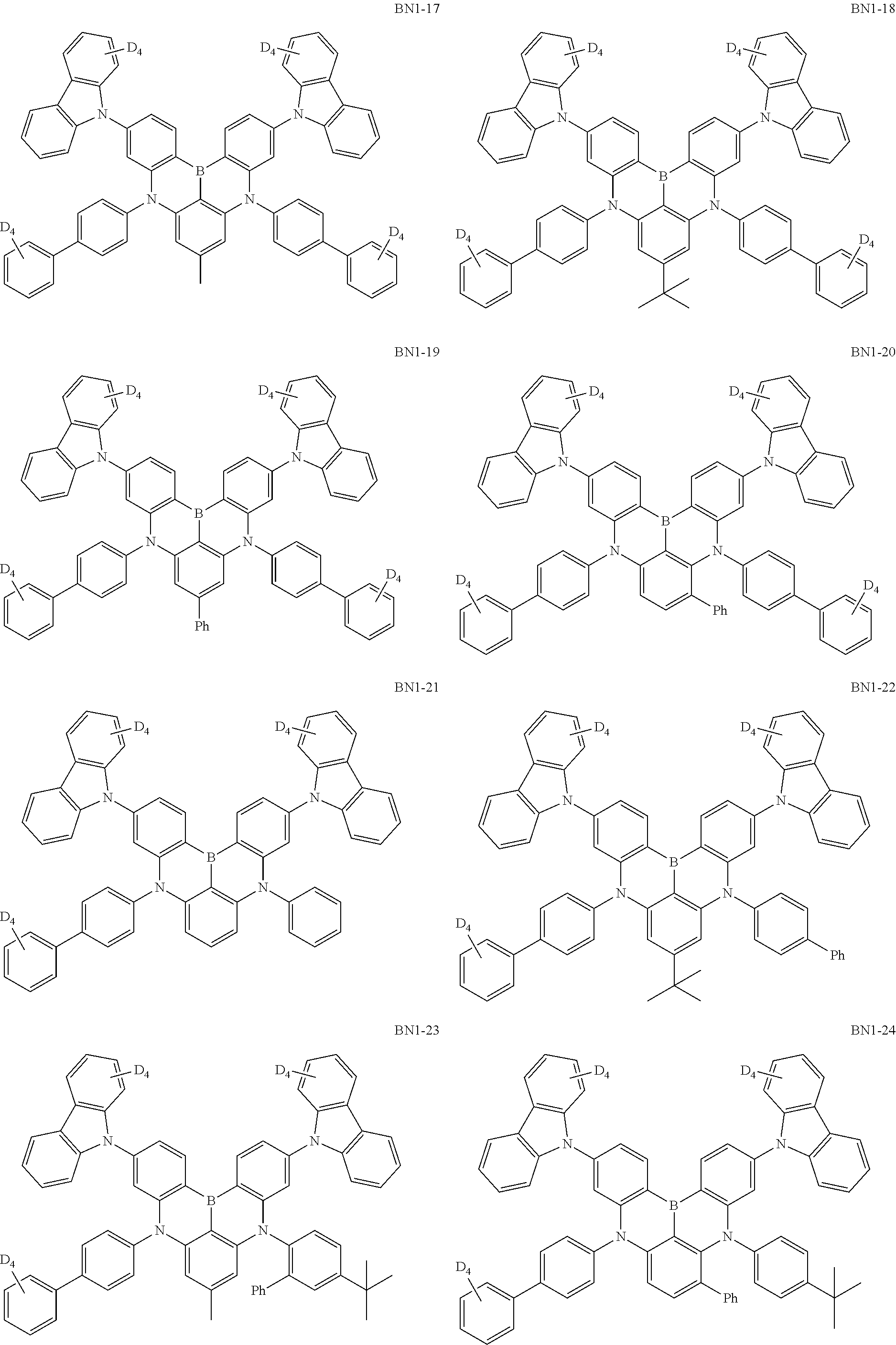

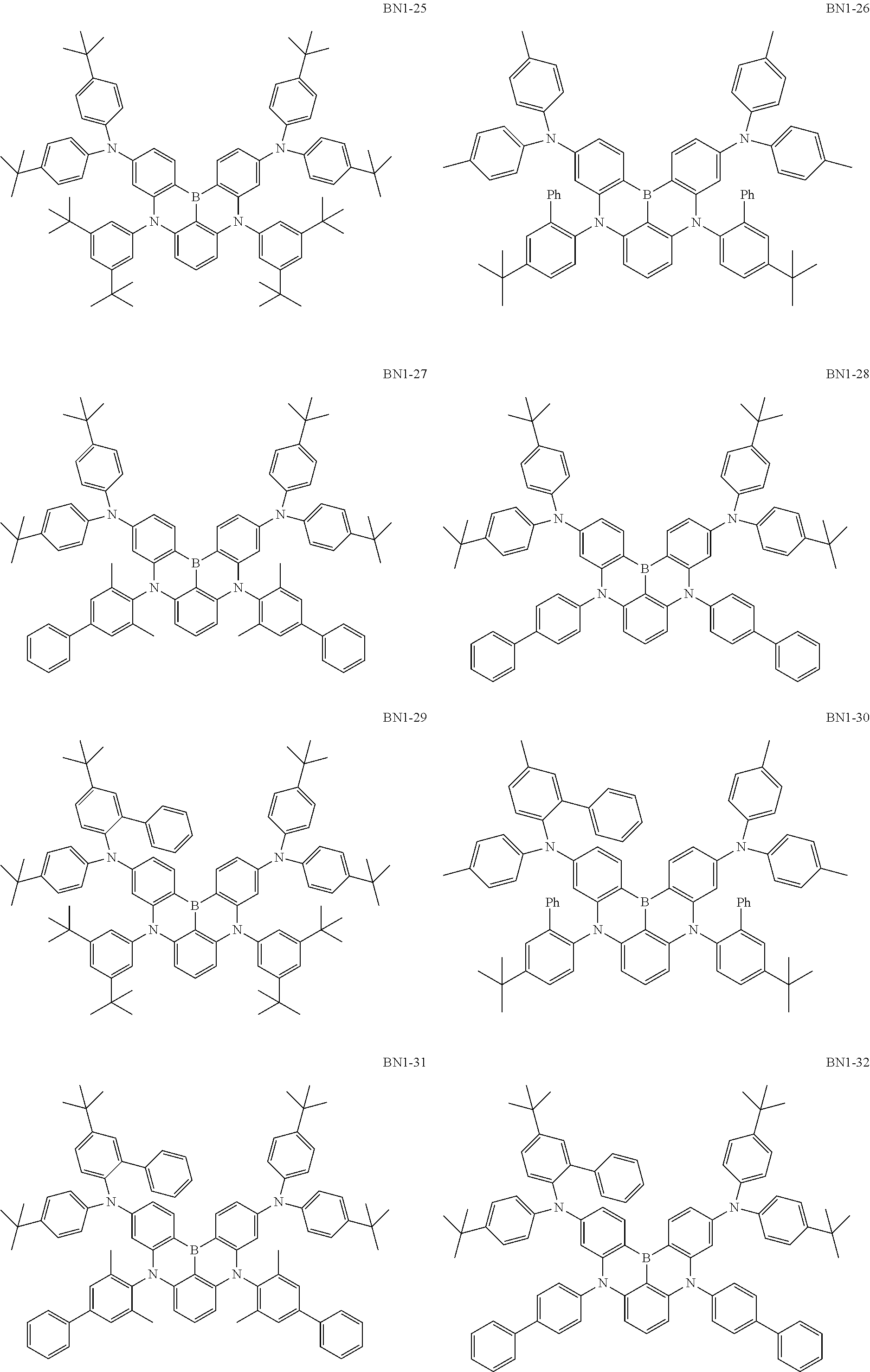

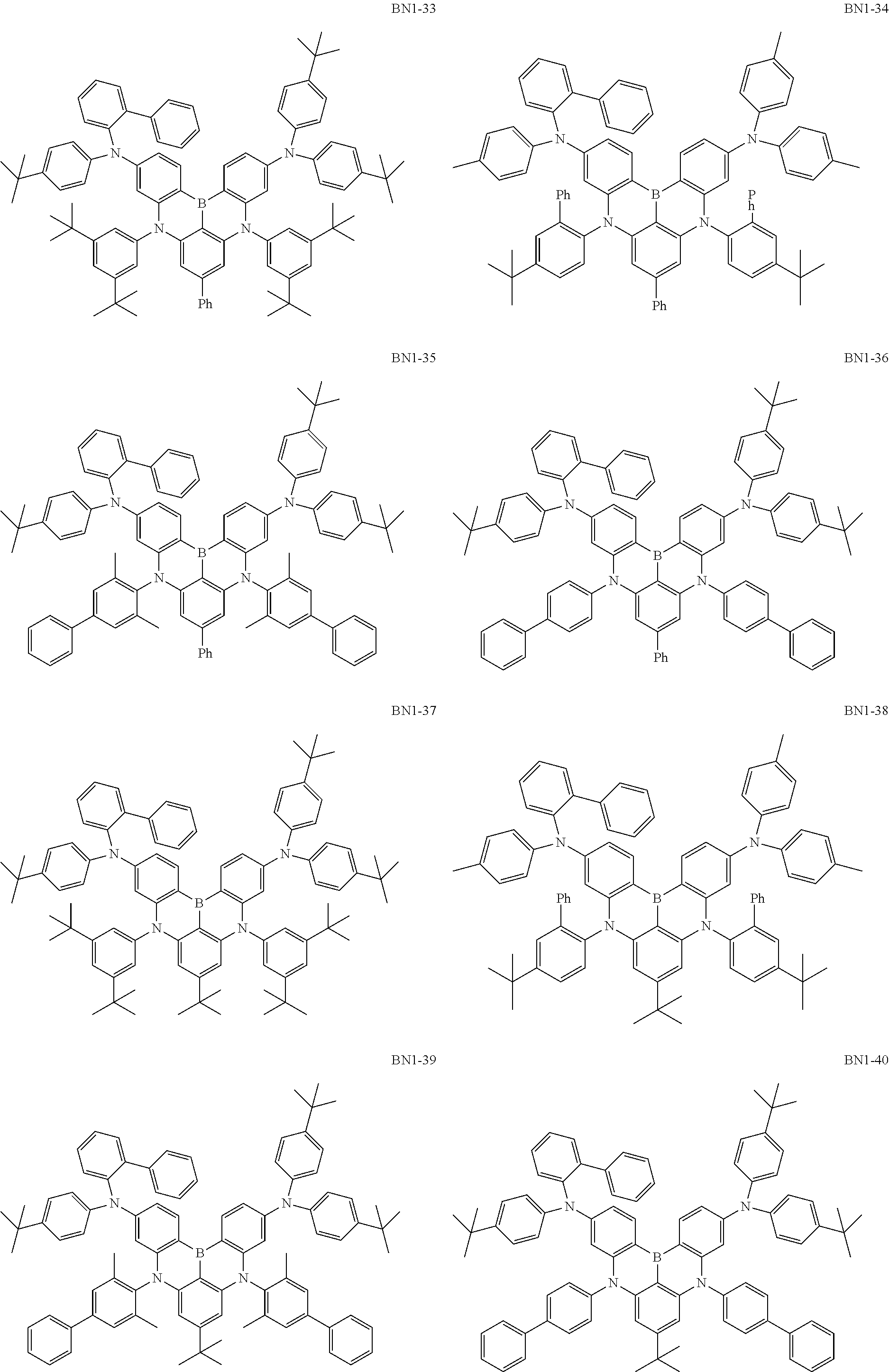

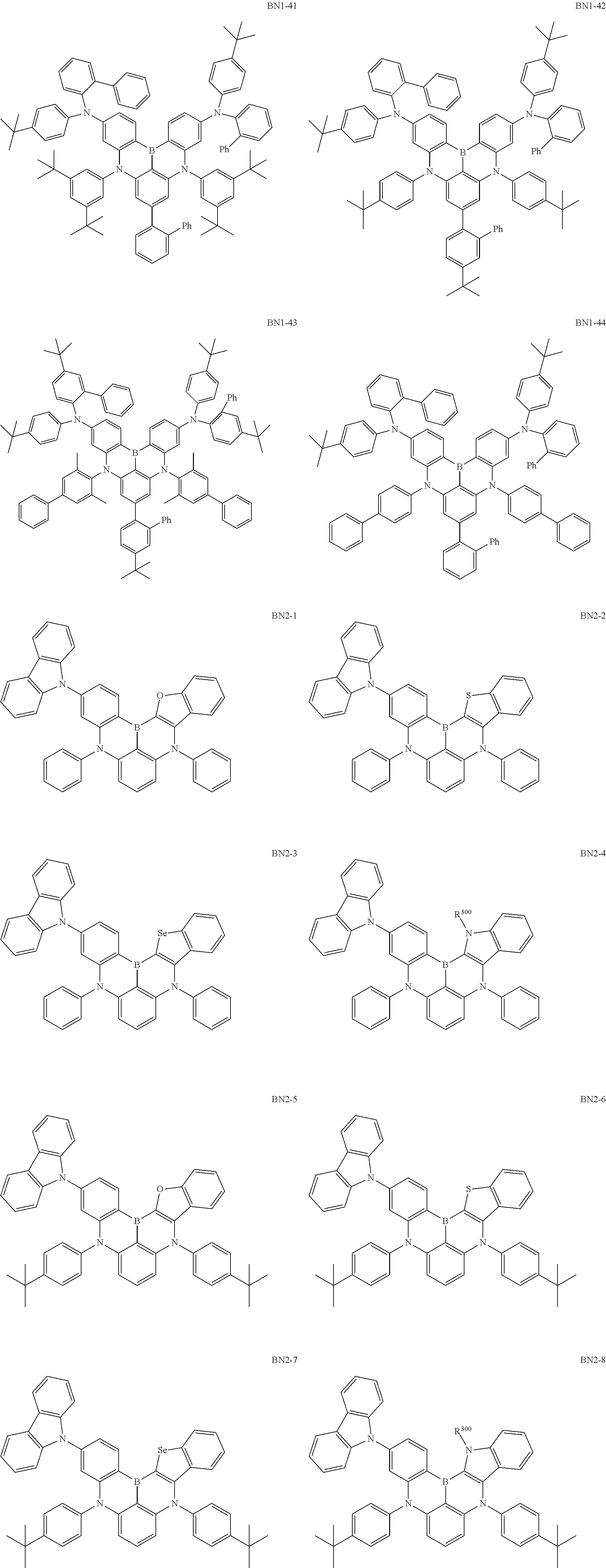

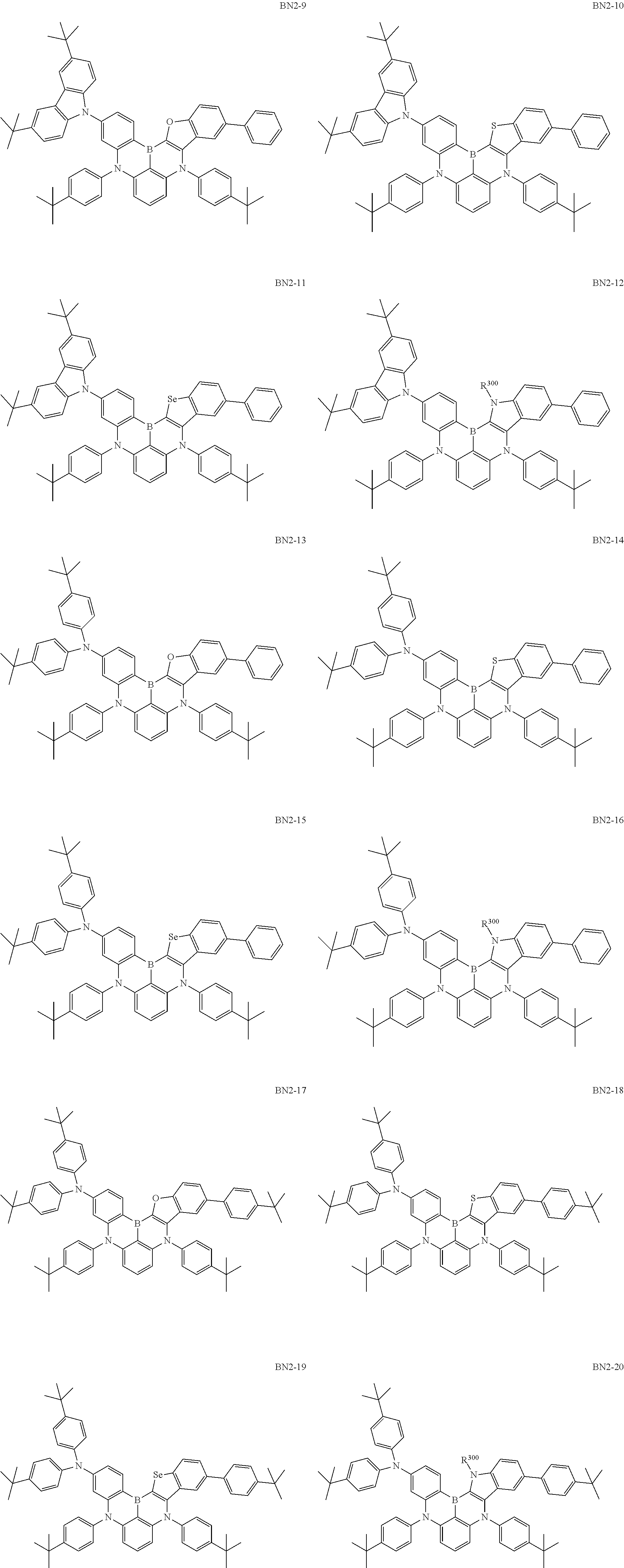

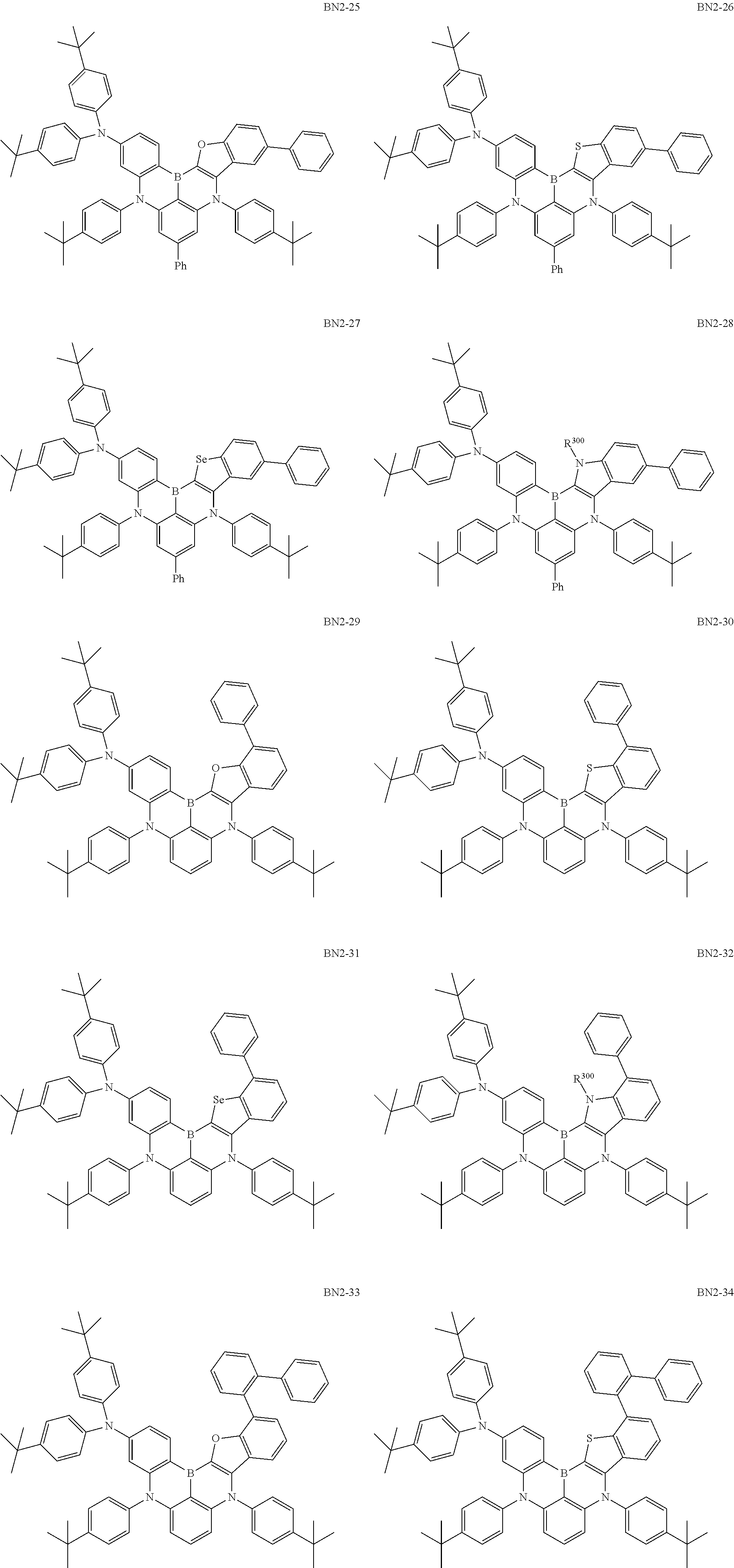

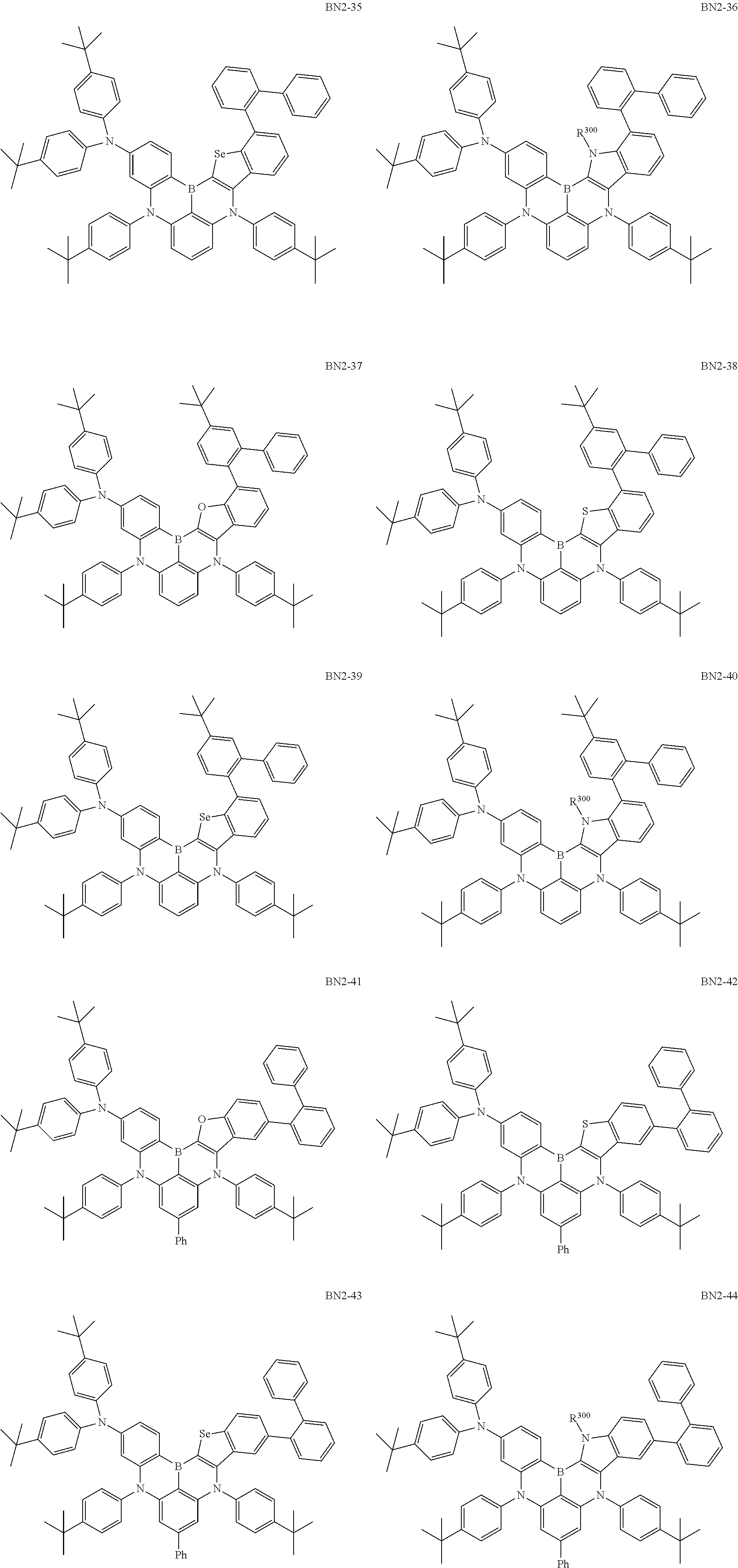

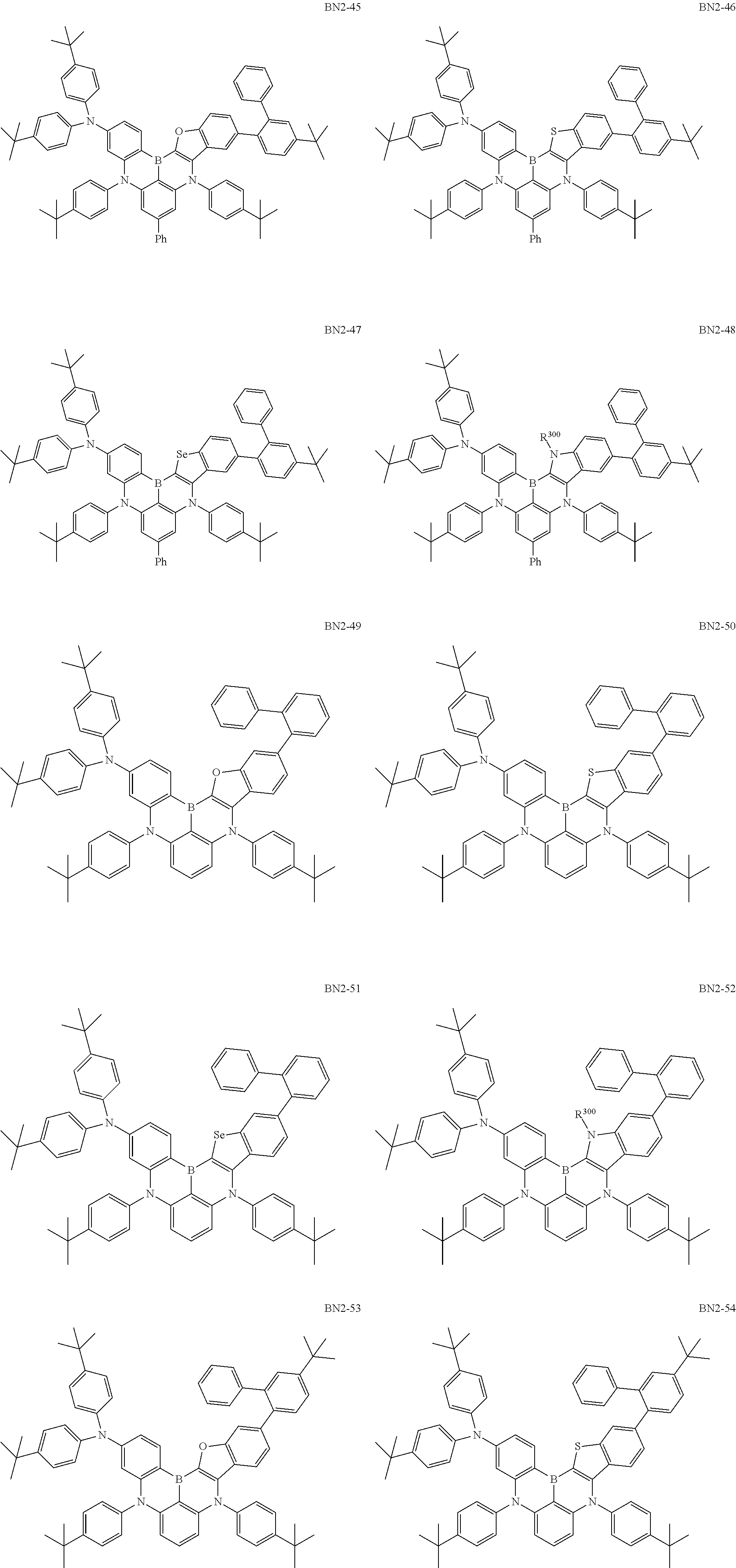

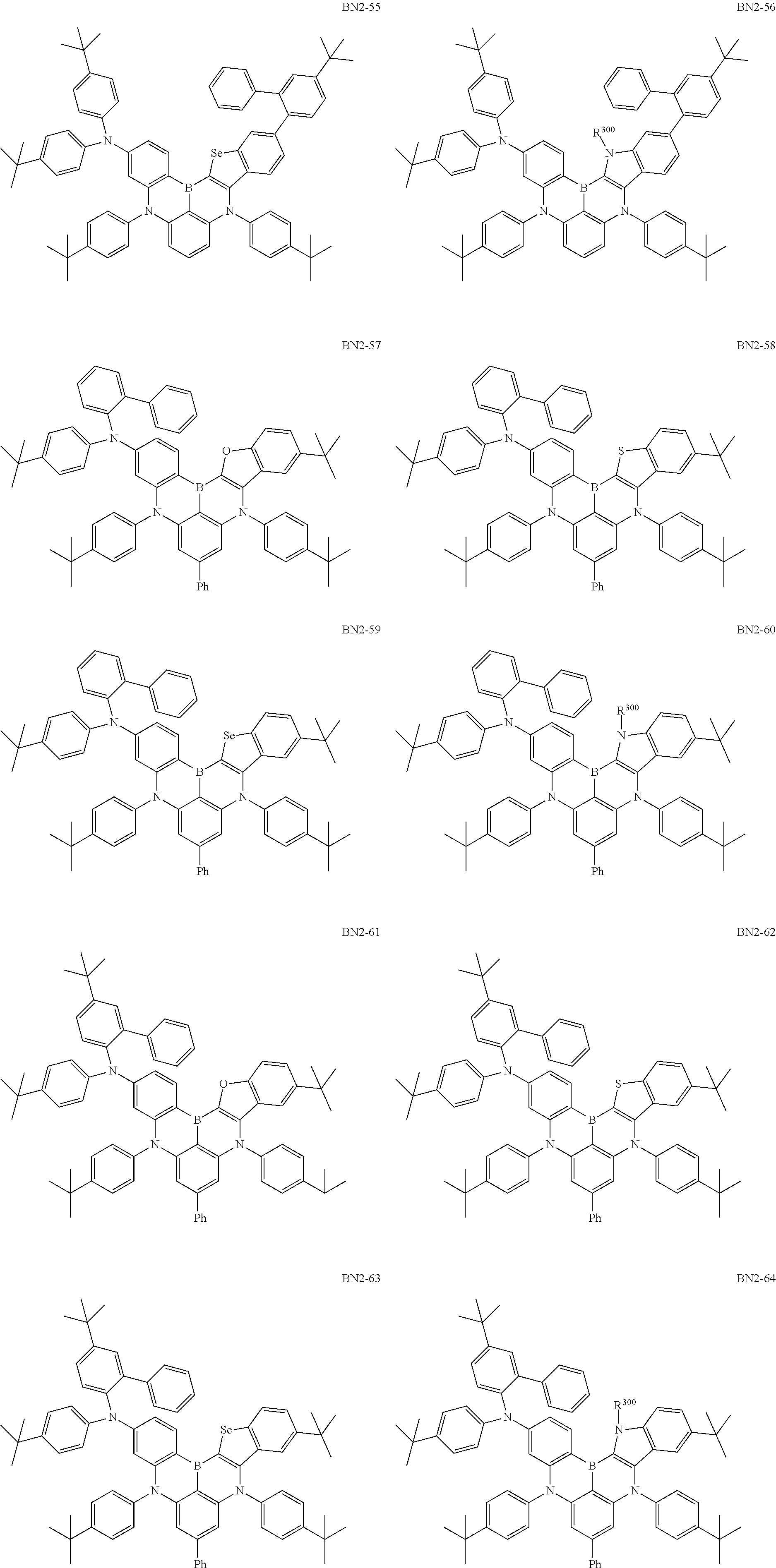

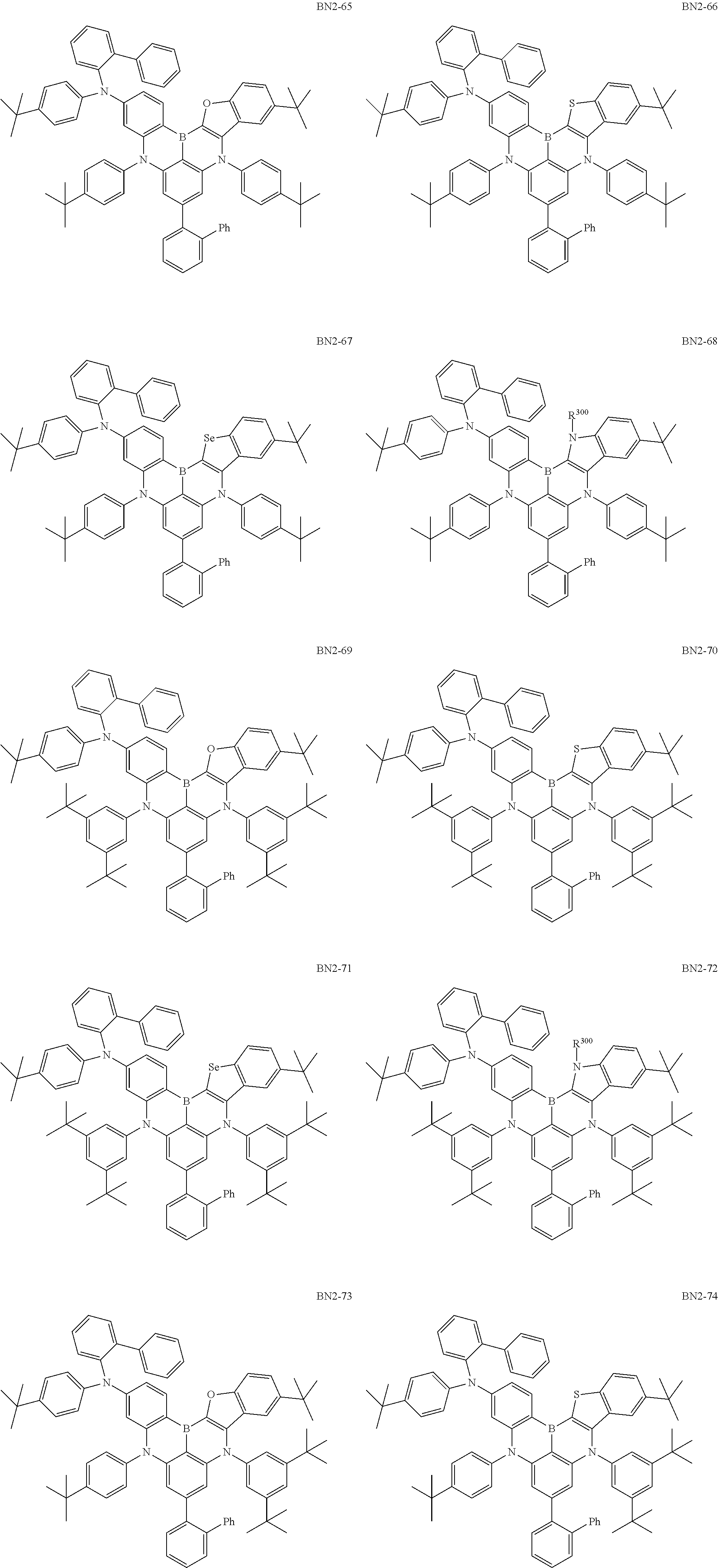

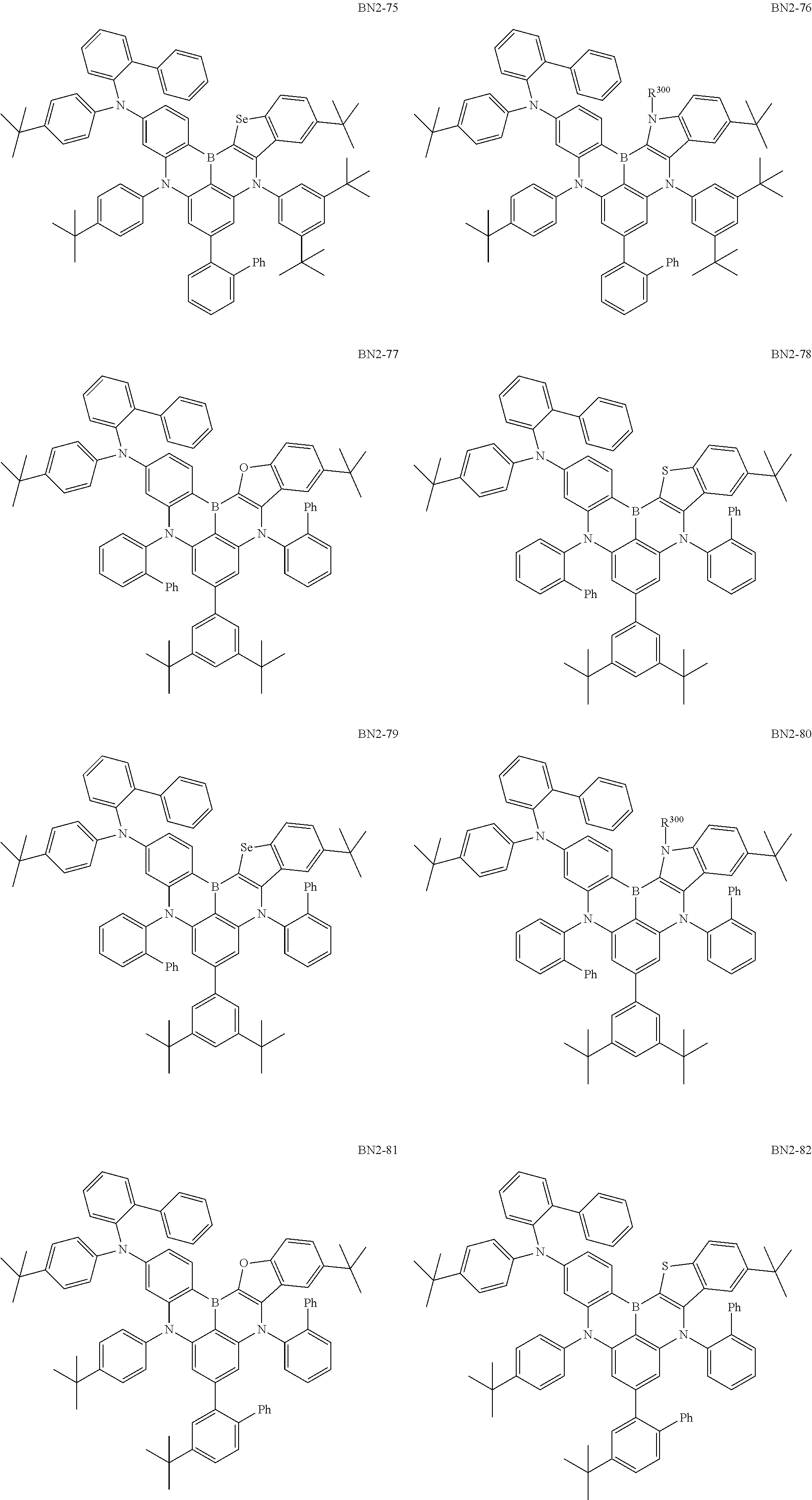

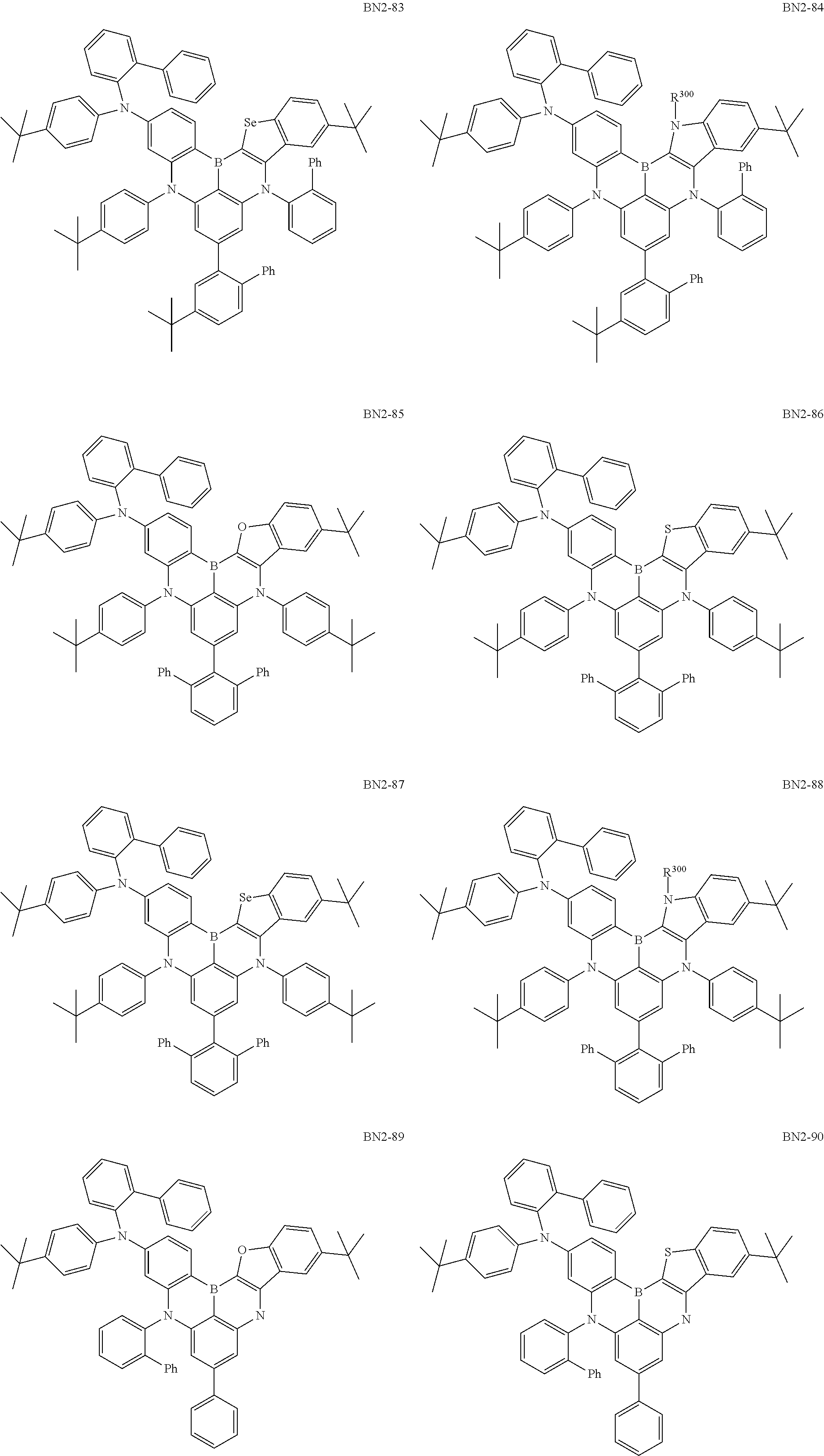

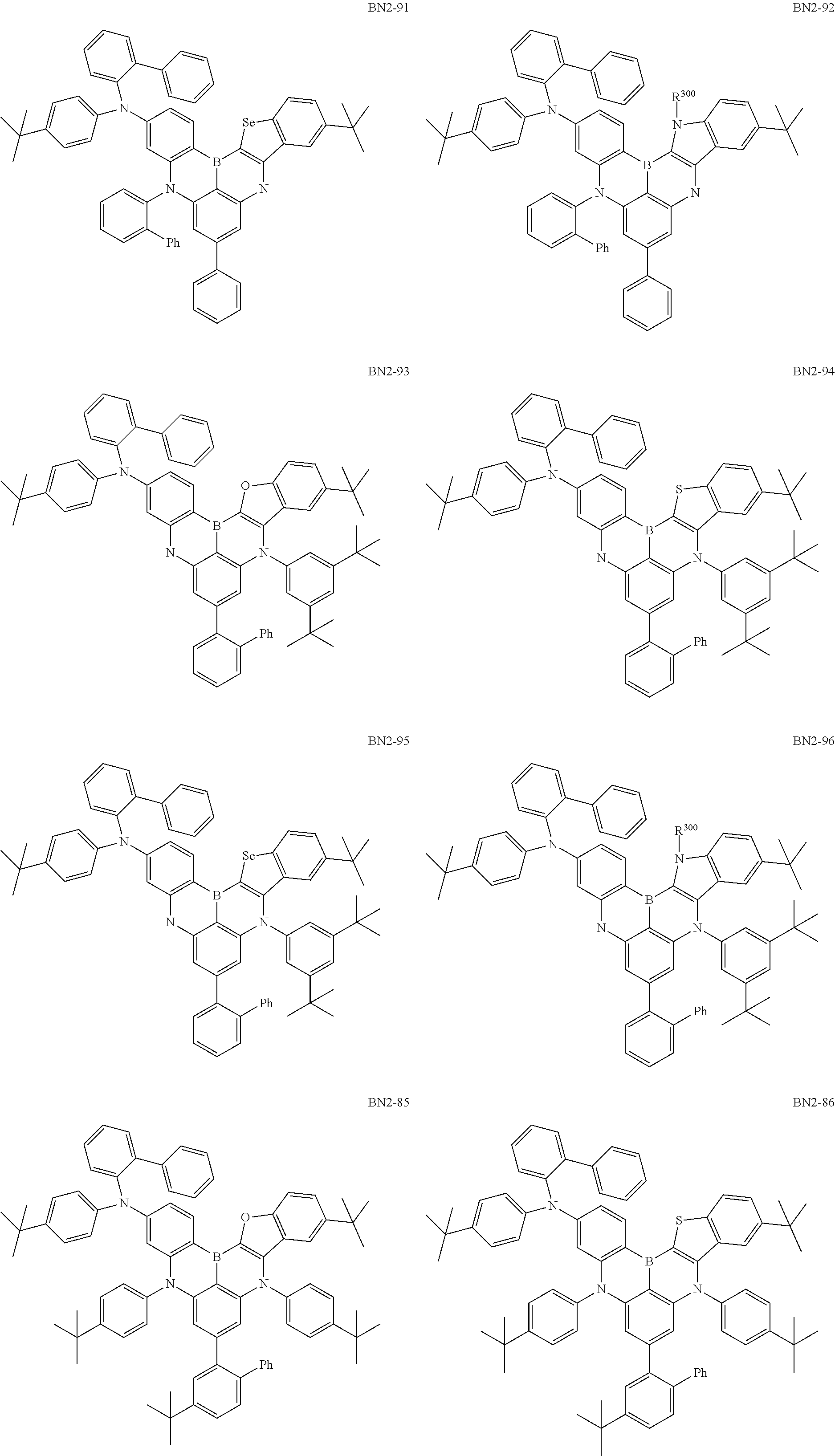

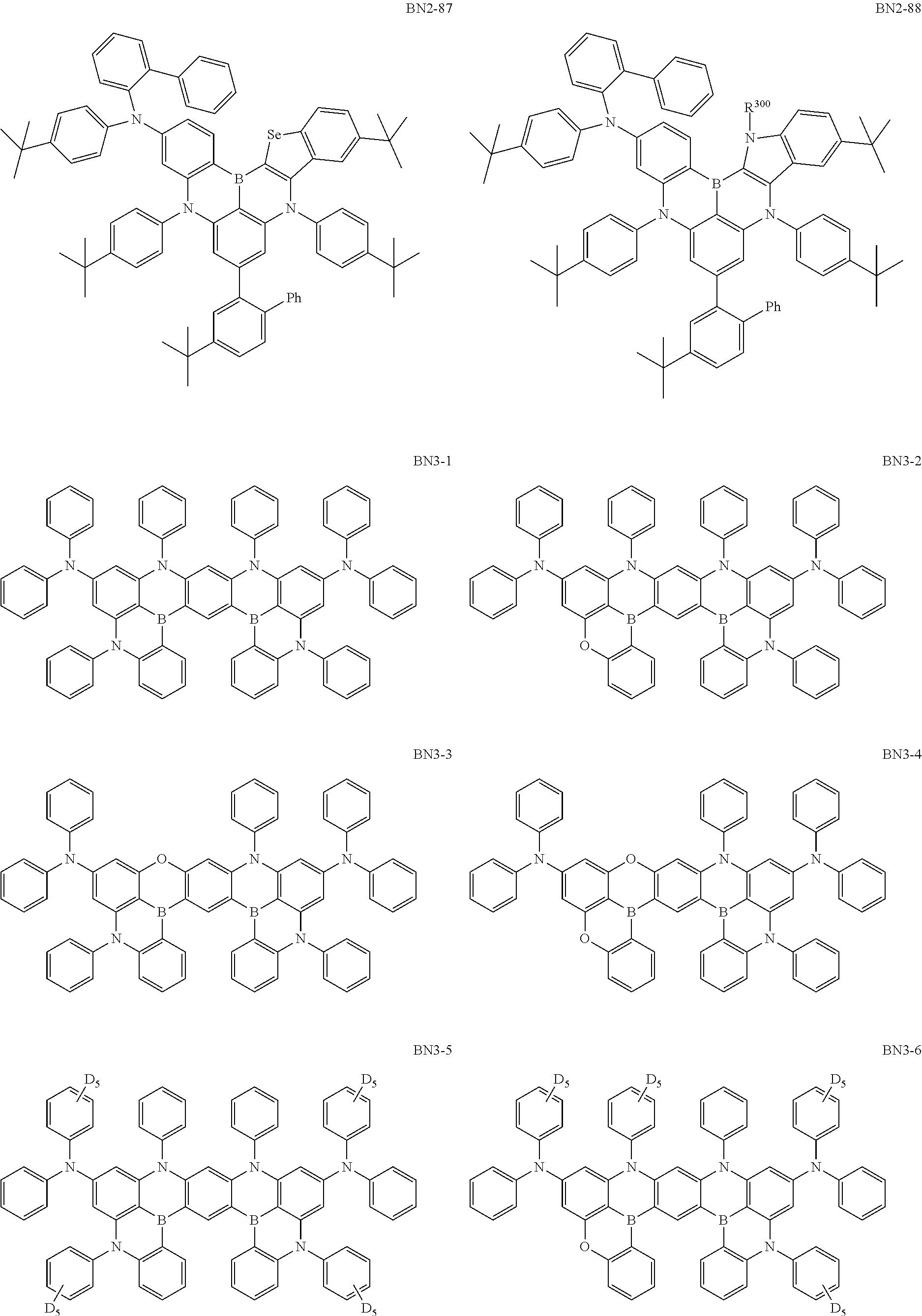

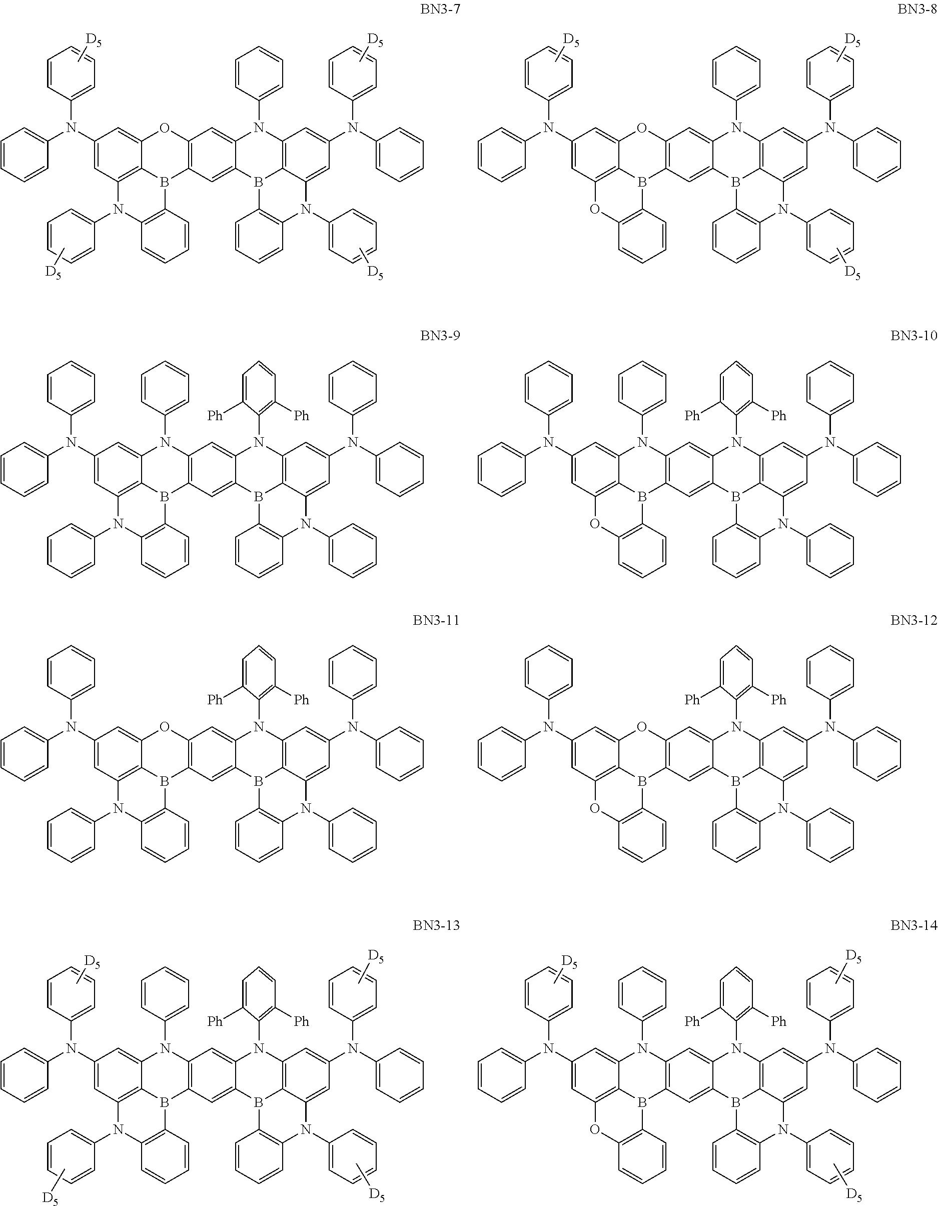

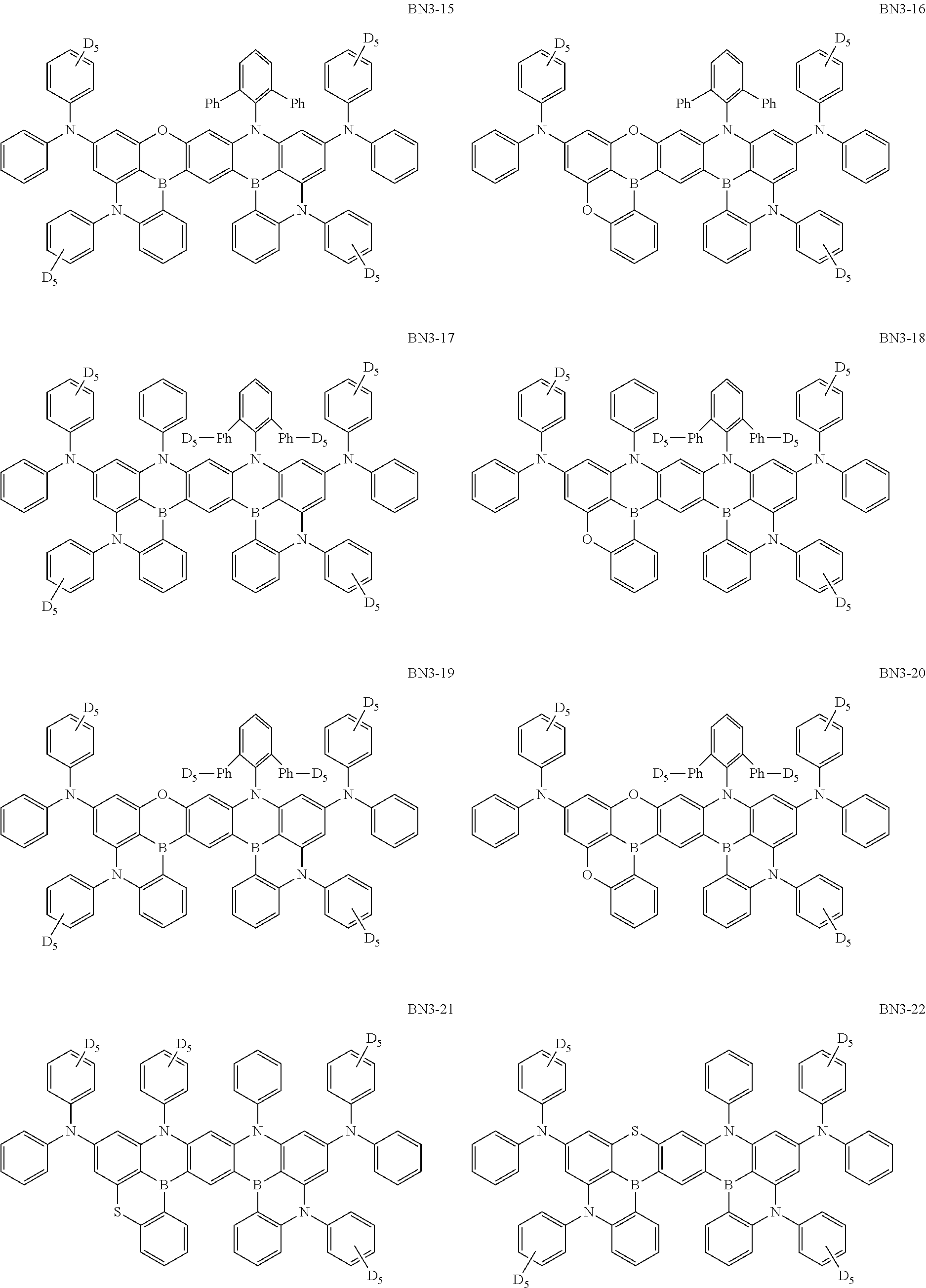

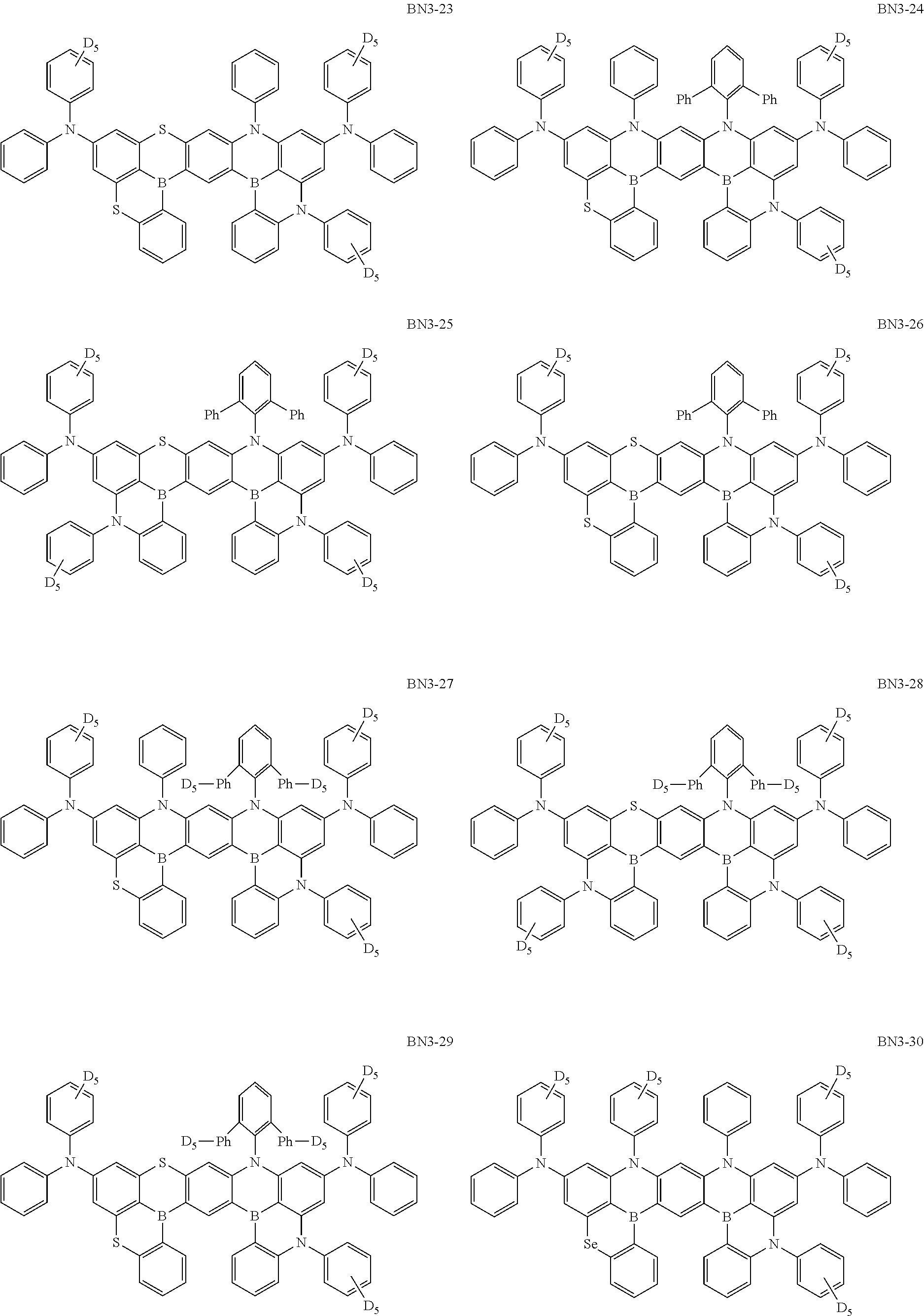

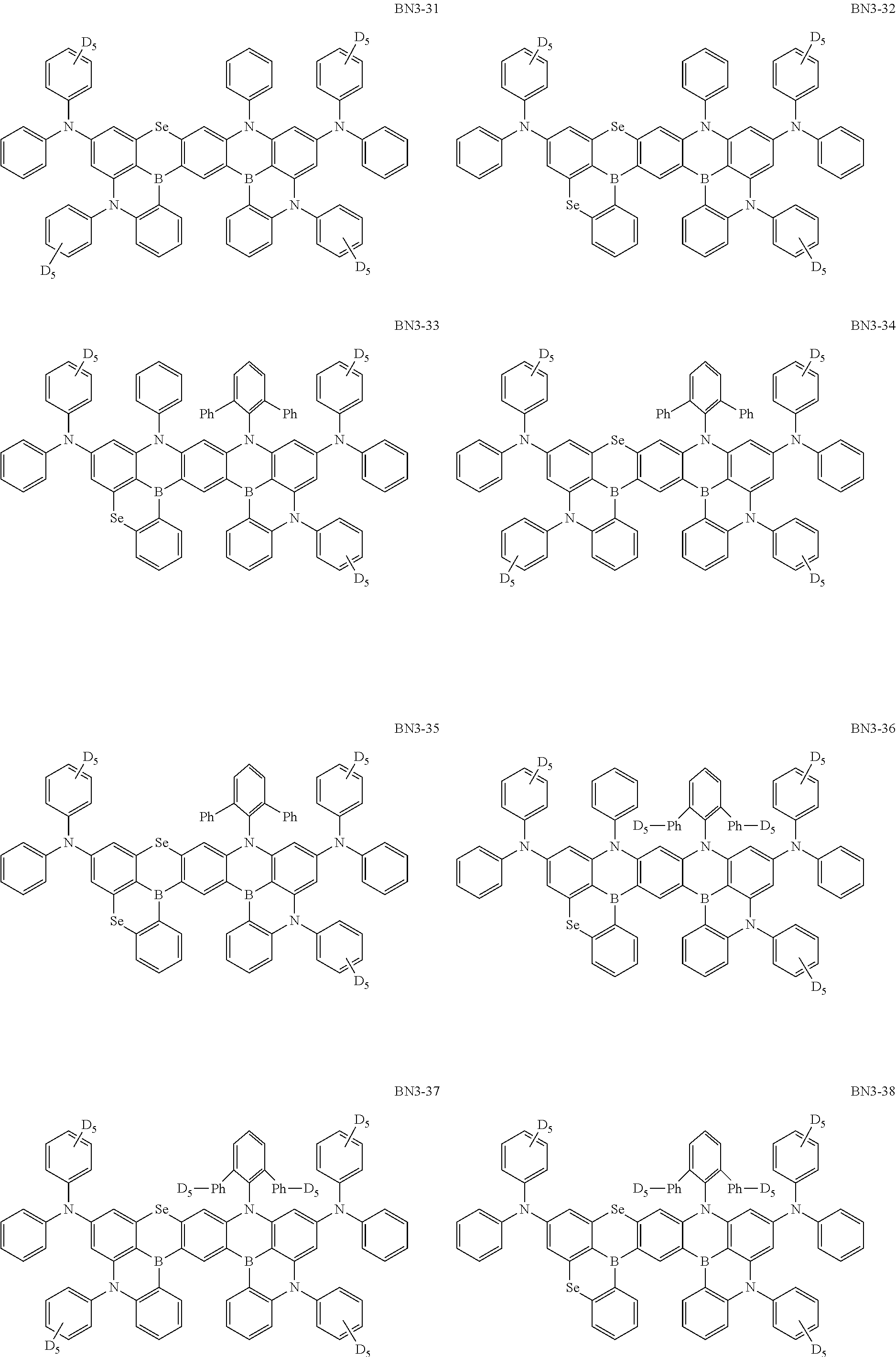

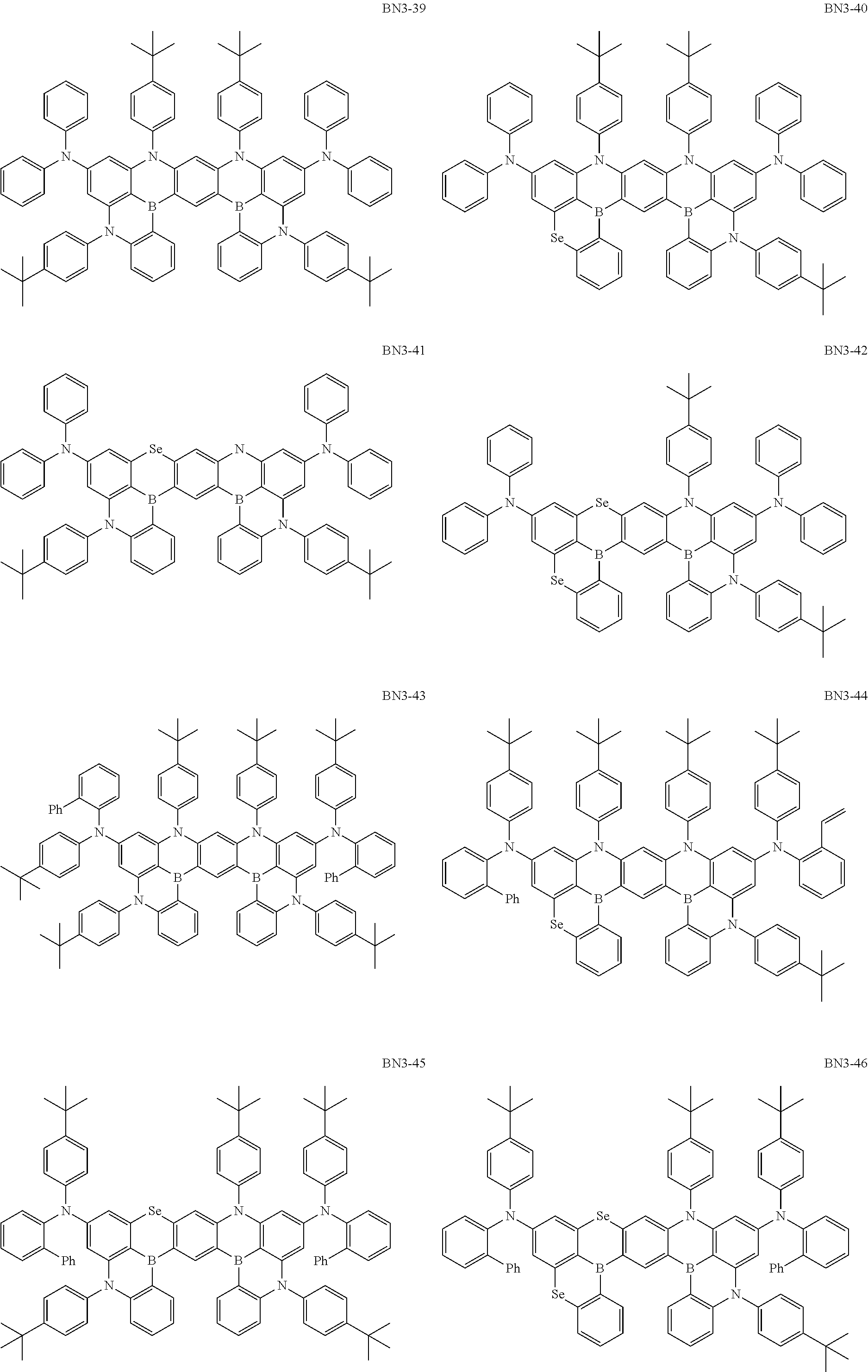

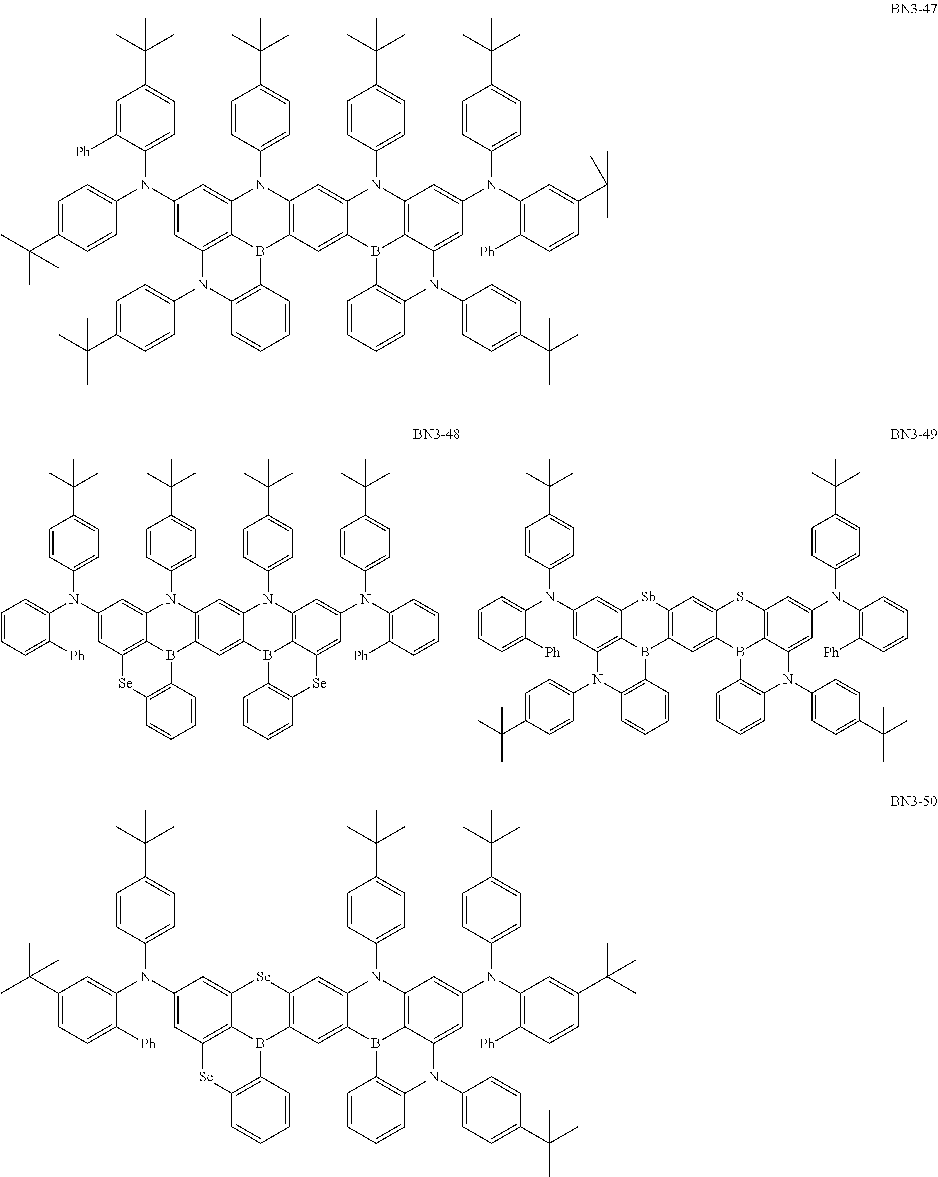

10. An organic photoelectric device, comprising: a substrate layer; a first electrode on the substrate; an organic light-emitting functional layer on the first electrode; a second electrode on the organic light emitting functional layer, wherein the organic light-emitting functional layer comprises the tetradentate cyclometalated platinum (II) complex according to claim 1.

11. The organic photoelectric device according to claim 10, wherein the organic light-emitting functional layer further comprises a fluorescent doping material, the fluorescent doping material being selected from any one or more compound represented by formulas (BN1) to (BN5): 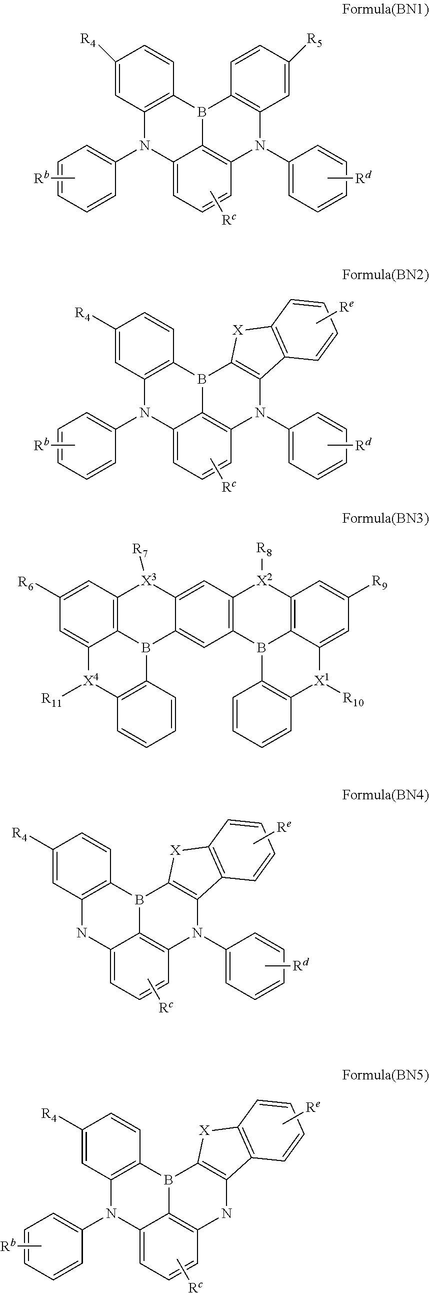
wherein X is O, S, Se or NR³⁰⁰;
X¹, X², X³, X^{4r} each independently represent O, S, Se or N; and
R^{b} to R^{e} are each independently represented as monosubstituted, disubstituted, trisubstituted, tetrasubstituted or unsubstituted; R^{b} to R^{e} are independently selected from a group consisting of hydrogen, deuterium, N, C1-C30 alkyl and C6-C60 aryl; R₄ to R₁₁ are each independently selected from a group consisting of a group consisting of hydrogen, deuterium, n, C1-C30 alkyl and C6-C60 aryl.

12. A composition, comprising the tetradentate cyclometalated platinum (II) complex according to claim 1.

13. A preparation, comprising the tetradentate cyclometalated platinum (II) complex according to claim 1.

14. A display, comprising the organic light-emitting device according to claim 5.

15. A lighting apparatus, comprising the organic light-emitting device according to claim 5.
